(19) United States
(12) Patent Application Publication
(10) Pub. No.: US 2025/0383608 A1
(43) Pub. Date: Dec. 18, 2025

(54) EXPOSURE APPARATUS, DEVICE MANUFACTURING METHOD, AND CONTROL METHOD

(71) Applicant: NIKON CORPORATION, Tokyo (JP)

(72) Inventor: Masaki KATO, Yokohama-shi (JP)

(73) Assignee: NIKON CORPORATION, Tokyo (JP)

(21) Appl. No.: 19/240,486

(22) Filed: Jun. 17, 2025

Related U.S. Application Data
(63) Continuation of application No. PCT/JP2023/039707, filed on Nov. 2, 2023.

(30) Foreign Application Priority Data
Dec. 26, 2022 (JP) 2022-208554

(51) Int. Cl. G03F 7/00

(52) U.S. Cl. CPC G03F 7/70516; G03F 7/70291; G03F 7/7085

(57) ABSTRACT

An exposure apparatus includes: a plurality of modules that include a spatial light modulation element including a plurality of micro mirrors driven to be switched between an ON state and an OFF state based on drawing data, an illumination unit that irradiates the spatial light modulation element with illumination light, and a projection unit that causes reflected light from micro mirrors in the ON state in the spatial light modulation element to be incident on a substrate as an image formation light flux; a control unit that stores correction information which corrects a state of the image formation light flux for each of the modules; and an adjustment mechanism that adjusts a position or an angle of an optical member in the illumination unit or the projection unit or an angle of the spatial light modulation element for each of the modules based on the correction information.

### CROSS-REFERENCE TO RELATED APPLICATION

This is a Continuation application of International Application No. PCT/JP2023/039707, filed on Nov. 2, 2023, which claims priority on Japanese Patent Application No. 2022-208554, filed on Dec. 26, 2022. The contents of the aforementioned applications are incorporated herein by reference.

### BACKGROUND

### Field of the Invention

The present invention relates to an exposure apparatus that exposes a pattern for an electronic device, and a device manufacturing method and a control method that use such an exposure apparatus.

### Background

Conventionally, in a lithography process in which an electronic device (micro device) such as a semiconductor element (integrated circuit or the like) or a display panel using a liquid crystal or an organic EL is manufactured, a projection exposure apparatus of a step-and-repeat type (a so-called stepper), a projection exposure apparatus of a step-and-scan type (a so-called scanning stepper (also called as a scanner)), or the like has been used. This type of exposure apparatus projects and exposes a mask pattern for an electronic device onto a photosensitive layer applied to the surface of an exposed substrate (hereinafter, also simply referred to as a substrate) such as a glass substrate, a semiconductor wafer, a printed wiring board, or a resin film.

Since time and costs are required for manufacturing a mask substrate on which the mask pattern is fixedly formed, an exposure apparatus using a spatial light modulation element (variable mask pattern generator) such as a digital mirror device (DMD) in which a large number of micro mirrors that are finely displaced are regularly aligned instead of the mask substrate is known (for example, refer to Japanese Unexamined Patent Application, First Publication No. 2019-23748). In the exposure apparatus disclosed in Japanese Unexamined Patent Application, First Publication No. 2019-23748, for example, the digital mirror device (DMD) is irradiated with illumination light obtained by mixing light from a laser diode (LD) having a wavelength of 375 nm and light from a LD having a wavelength of 405 nm in a multimode fiber bundle, and reflected light from each of a large number of micro mirrors that are controlled to be inclined is projected and exposed onto a substrate through an imaging optical system and a microlens array.

In a digital system, the inclination angle of each micro mirror of the DMD is set to be, for example, 0° at the time of Off (when the reflected light is not incident on the imaging optical system) and 12° at the time of On (when the reflected light is incident on the imaging optical system). Since the large number of micro mirrors are arranged in a matrix at a constant pitch (for example, 10 μm or less), the micro mirrors also include an action as an optical diffraction grating.

In particular, when a fine pattern for an electronic device is projected and exposed, depending on the wavelength of the illumination light to the DMD and the action (a generation direction of diffraction light and a state of intensity distribution) of the diffraction grating of the DMD, an image formation state of the pattern may be degraded.

### SUMMARY

According to a first aspect of the present invention, an exposure apparatus includes: a plurality of modules that include a spatial light modulation element including a plurality of micro mirrors driven to be switched between an ON state and an OFF state based on drawing data, an illumination unit that irradiates the spatial light modulation element with illumination light, and a projection unit that causes reflected light from micro mirrors in the ON state in the spatial light modulation element to be incident on a substrate as an image formation light flux; a control unit that stores correction information which corrects a state of the image formation light flux for each of the modules; and an adjustment mechanism that adjusts a position or an angle of an optical member in the illumination unit or the projection unit or an angle of the spatial light modulation element for each of the modules based on the correction information.

According to a second aspect of the present invention, a device manufacturing method includes: a step of specifying a telecentric error of the image formation light flux that occurs in accordance with a distribution state of micro mirrors in an ON state of the spatial light modulation element or a light amount variation error of the image formation light flux that occurs due to a drive error of micro mirrors in an ON state; and a step of adjusting an installation state of the spatial light modulation element for each of the modules based on the correction information when the image formation light flux is incident on the substrate by using the exposure apparatus according to the first aspect described above wherein the correction information includes information that corrects a state of the image formation light flux based on the light amount variation error. According to a third aspect of the present invention, a device manufacturing method includes: exposing the substrate by using the exposure apparatus according to the first aspect described above.

According to a fourth aspect of the present invention, a control method is a control method of an exposure apparatus that includes a module including: an illumination unit that irradiates, with illumination light, a spatial light modulation element including a plurality of micro mirrors driven to be switched between an ON state and an OFF state based on drawing data; and a projection unit that causes reflected light from micro mirrors which become the ON state of the spatial light modulation element to be incident on a substrate as an image formation light flux and projects a device pattern corresponding to the drawing data onto the substrate, the control method including: adjusting an angle change of the image formation light flux that occurs based on a distribution of the micro mirrors in the ON state of the spatial light modulation element; and adjusting, by correcting the drawing data, a line width change of the device pattern that occurs by adjusting the angle change.

According to a fifth aspect of the present invention, an exposure apparatus includes: a module that includes a spatial light modulation element including a plurality of micro mirrors driven to be switched between an ON state and an OFF state based on drawing data, an illumination unit that irradiates the spatial light modulation element with illumination light, and a projection unit that projects reflected light from micro mirrors in the ON state in the spatial light modulation element onto a substrate as an image formation light flux; a control unit that stores illumination-related information including an illuminance difference of the image formation light flux generated in accordance with a distribution density of the micro mirrors in the ON state of the spatial light modulation element and an angle error of an inclination angle of the micro mirrors in the ON state; and an adjustment mechanism that adjusts a position or an angle of an optical member in the illumination unit or the projection unit or an angle of the spatial light modulation element in accordance with the illumination-related information when driving the spatial light modulation element based on the drawing data and projecting the image formation light flux onto the substrate.

### BRIEF DESCRIPTION OF THE DRAWINGS

FIG. 1 is a perspective view showing an overview of an external configuration of a pattern exposure apparatus EX according to the present embodiment.

FIG. 2 is a view showing an arrangement example of a projection region IAn of a DMD 10 projected onto a substrate P by a projection unit PLU of each of a plurality of exposure modules MU.

FIG. 3 is a view explaining a state of a joint exposure by each of four specific projection regions IA8, IA9, IA10, and IA27 in FIG. 2.

FIG. 4 is an optical arrangement view of a specific configuration of two exposure modules MU18, MU19 aligned in a X direction (scanning exposure direction) when seen in a XZ plane.

FIG. 5 is a view schematically showing a state in which the DMD 10 and the projection unit PLU are inclined by an angle θk in a XY plane.

FIG. 6 is a view explaining an image formation state of a micro mirror of the DMD 10 by the projection unit PLU in detail.

FIG. 7 is a schematic view in which a MFE lens 108A as an optical integrator 108 is seen from an emission surface side.

FIG. 8 is a view schematically showing an example of an arrangement relationship between a point light source SPF formed on the emission surface side of a lens element EL of the MFE lens 108A of FIG. 7 and an emission end of an optical fiber bundle FBn.

FIG. 9 is a view schematically showing a state of a light source image formed on a pupil Ep in a second lens group 118 of the projection unit PLU shown in FIG. 6.

FIG. 10 is a view schematically showing a behavior of illumination light (image formation light flux) Sa in an optical path from the pupil Ep of the second lens group 118 to a substrate P shown in FIG. 6.

FIG. 11 is an enlarged perspective view of a state of a micro mirror Ms that is part of the DMD 10 in the case where electric power supply to a drive circuit of the DMD 10 is off.

FIG. 12 is an enlarged perspective view of part of a mirror surface of the DMD 10 in the case where the micro mirrors Ms of the DMD 10 becomes an ON state and an OFF state.

FIG. 13 is a view showing part of the mirror surface of the DMD 10 when seen in a X′Y′ plane and showing the case where only micro mirrors Ms in one row aligned in a Y′ direction become the ON state.

FIG. 14 is a view in which an a-a′ arrow part of the mirror surface of the DMD 10 of FIG. 12 is seen in a X′Z plane.

FIG. 15 is a view schematically showing the image formation state by the projection unit PLU of reflected light (image formation light flux) Sa from an isolated micro mirror Msa as shown in FIG. 13 in the X′Z plane.

FIG. 16 is a graph schematically showing a point image intensity distribution lea of a diffraction image in the pupil Ep by a normal reflected light Sa from the isolated micro mirror Msa.

FIG. 17 is a view showing part of the mirror surface of the DMD 10 when seen in the X′Y′ plane and is a view showing the case where a large number of micro mirrors Ms adjacent to each other in a X′ direction simultaneously become the ON state.

FIG. 18 is a view in which an a-a′ arrow part of the mirror surface of the DMD 10 of FIG. 16 is seen in the X′Z plane.

FIG. 19 is a graph showing an example of the distribution of an angle θj of diffraction light Idj generated from the DMD 10 in the state of FIG. 17 and FIG. 18.

FIG. 20 is a view schematically showing the intensity distribution of the image formation light flux at the pupil Ep in the state where the diffraction light as shown in FIG. 19 is generated.

FIG. 21 is a view showing a state of part of the mirror surface of the DMD 10 at the time of projection of a line-and-space pattern when seen in the X′Y′ plane.

FIG. 22 is a view in which an a-a′ arrow part of the mirror surface of the DMD 10 of FIG. 21 is seen in the X′Z plane, which shows a modification example of a distribution part of the present embodiment.

FIG. 23 is a graph showing an example of a distribution of the angle θj of the diffraction light Idj generated from the DMD 10 in the state of FIG. 21 and FIG. 22.

FIG. 24 is a graph showing a result of simulating a contrast of a spatial image of a line-and-space pattern having a line width of 1 μm on an image surface.

FIG. 25 is a graph in which a relationship between a wavelength λ and a telecentric error Δθt is obtained based on Expression (2).

FIG. 26 is a view showing a specific configuration of an optical path to the MFE lens 108A from the optical fiber bundle FBn of the illumination unit ILU shown in FIG. 4 or FIG. 6.

FIG. 27 is a view showing a specific configuration of an optical path to the DMD 10 from the MFE lens 108A of the illumination unit ILU shown in FIG. 4 or FIG. 6.

FIG. 28 is an exaggerated view showing a state of the point light source SPF formed on the emission surface side of the MFE lens 108A when illumination light ILm entering the MFE lens 108A is inclined in the X′Z plane.

FIG. 29 is a view showing a configuration of an example of a beam supply unit that is attached to the exposure apparatus EX shown in FIG. 1 and supplies the illumination light ILm to each module MUn (n=1 to 27).

FIG. 30 is a view schematically showing a wavelength distribution of a beam LBb after beams LB1 to LB7 from seven laser light sources FL1 to FL7 are combined by a beam combination unit 200.

FIG. 31 is a view showing a state of part of the mirror surface of the DMD 10 at the time of exposure of a line-and-space pattern obliquely inclined at 45° on the substrate P.

FIG. 32 is a block diagram showing a schematic example of a portion particularly related to an adjustment control of the telecentric error in an exposure control device that is attached to the exposure apparatus EX of the present embodiment.

FIG. 33 is a view showing an example of an arrangement of a display region DPA for a display panel and peripheral regions PPAx and PPAy exposed on the substrate P by the exposure apparatus EX.

FIG. 34 is a view showing an example of an arrangement state of a pixel PIX in the display region DPA appearing in the projection region IAn (n=1 to 27).

FIG. 35 is a view showing a schematic configuration of an optical measurement unit provided on a calibration reference portion CU that is attached to an end portion on a substrate holder 4B of the exposure apparatus EX shown in FIG. 1.

FIG. 36 is a view showing a schematic configuration of one of drawing modules provided on a pattern exposure apparatus according to a second embodiment.

FIG. 37 is an exaggerated view showing a state of a micro mirror Ms when projecting an isolated pattern having a minimum line width by a DMD 10′ of FIG. 36.

FIG. 38 is a graph schematically showing the point image intensity distribution Iea of the diffraction image in the pupil Ep of the reflected light Sa from the isolated micro mirror Msa in the ON state as shown in FIG. 37.

FIG. 39 is an exaggerated view showing a state of the micro mirror Ms when a large land-like pattern is projected by the DMD 10′ of FIG. 36.

FIG. 40 is a view schematically showing an example of a generation direction of a center ray of zero order diffraction light and ±first order diffraction light included in reflected light Sa′ in the state of FIG. 39.

### DESCRIPTION OF EMBODIMENTS

A pattern exposure apparatus (pattern formation apparatus) according to an aspect of the present invention will be described below in detail with reference to the accompanying drawings while exemplifying suitable embodiments. Aspects of the present invention are not limited to these embodiments and also include those with various changes or improvements. That is, the components described below include those that would likely be assumed by a person skilled in the art and those that are substantially the same, and the components described below can be combined as appropriate. Further, various omissions, substitutions, or changes of the components can be made without departing from the scope of the present invention. Throughout the drawings and the following entire detailed descriptions, the same reference signs are used for members or components that achieve the same or similar functions.

### (Entire Configuration of Pattern Exposure Apparatus)

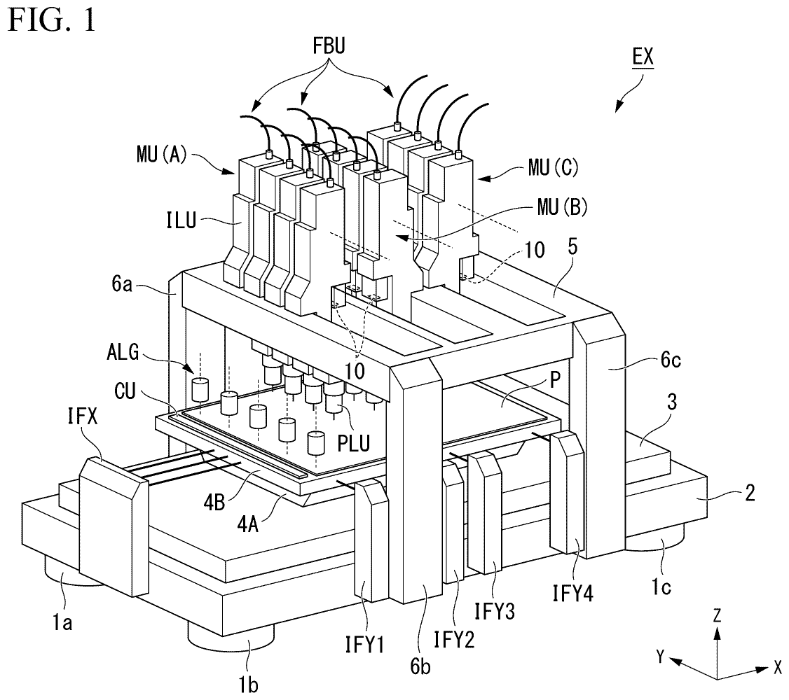

FIG. 1 is a perspective view showing an overview of an external configuration of a pattern exposure apparatus (hereinafter, also simply referred to as an exposure apparatus) EX of the present embodiment. The exposure apparatus EX is an apparatus that projects exposure light in which an intensity distribution in a space is dynamically modulated and forms an image on an exposed substrate using a spatial light modulation element (digital mirror device: DMD). In a specific embodiment, the exposure apparatus EX is a step-and-scan type projection exposure apparatus (scanner) in which a rectangular (square) glass substrate used in a display device (flat panel display) or the like is provided as an exposure object. The glass substrate is a substrate P for a flat panel display in which a length of at least one side or a diagonal length is 500 mm or more and a thickness is 1 mm or less. The exposure apparatus EX exposes a projection image of a pattern generated by the DMD to a photosensitive layer (photoresist) formed with a constant thickness on a surface of the substrate P. The substrate P conveyed from the exposure apparatus EX after exposure is sent to a predetermined process (a film formation process, an etching process, a plating process, or the like) after a development process.

The exposure apparatus EX includes a stage apparatus constituted of a pedestal 2 placed on active vibration proof units 1a, 1b, c, and 1d (1d is not shown), a surface plate 3 placed on the pedestal 2, an XY stage 4A that is two-dimensionally movable on the surface plate 3, a substrate holder 4B that suctions and holds the substrate P on a planar surface on the XY stage 4A, and laser length measurement interferometers (hereinafter, also simply referred to as an interferometer) IFX, IFY1 to IFY4 that measure a two-dimensional movement position of the substrate holder 4B (the substrate P). Such a stage apparatus is disclosed in, for example, U.S. Patent Publication No. 2010/0018950 and U.S. Patent Publication No. 2012/0057140.

In FIG. 1, an XY plane of an orthogonal coordinate system XYZ is set to be parallel to a flat surface of the surface plate 3 of the stage apparatus, and the XY stage 4A is set to be able to move in translation within the XY plane. Further, in the present embodiment, a direction parallel to the X axis of the coordinate system XYZ is set as a scanning movement direction of the substrate P (the XY stage 4A) at the time of scanning exposure. The movement position of the substrate P in a X axis direction is sequentially measured by the interferometer IFX, and a movement position in a Y axis direction is sequentially measured by at least one (preferably two) or more of the four interferometers IFY1 to IFY4. The substrate holder 4B is configured to be finely movable with respect to the XY stage 4A in a Z axis direction perpendicular to the XY plane and finely tiltable with respect to the XY plane in an arbitrary direction, and focus adjustment and leveling (degree of parallelization) adjustment between a surface of the substrate P and an image formation surface of a projected pattern are actively performed. Further, the substrate holder 4B is configured to be finely rotatable (Oz rotation) around an axis line parallel to the Z axis in order to actively adjust an inclination of the substrate P in the XY plane.

The exposure apparatus EX further includes an optical surface plate 5 configured that holds a plurality of exposure (drawing) modules MU(A), MU(B), and MU(C), and main columns 6a, 6b, 6c, and 6d (6d is not shown) that supports the optical surface plate 5 from the pedestal 2. Each of the plurality of exposure modules MU(A), MU(B), and MU(C) has an illumination unit ILU which is attached on a side of the optical surface plate 5 in a +Z direction and on which illumination light from an optical fiber unit FBU is incident, and a projection unit PLU attached to a side of the optical surface plate 5 in a −Z direction and having an optical axis parallel to the Z axis. Further, each of the exposure modules MU(A), MU(B), and MU(C) includes a digital mirror device (DMD) 10 as a light modulation unit that reflects illumination light from the illumination unit ILU in the −Z direction and causes the illumination light to enter the projection unit PLU. A detailed configuration of an exposure module constituted of the illumination unit ILU, the DMD 10 and the projection unit PLU will be described later.

A plurality of alignment systems (microscopes) ALG that detects alignment marks formed at a plurality of predetermined positions on the substrate P are attached to a side of the optical surface plate 5 of the exposure apparatus EX in the −Z direction. In order to perform confirmation (calibration) of a relative position relationship in an XY plane of a detection field of vision of each of the alignment systems ALG, confirmation (calibration) of a base line error between each projection position of a pattern image projected from the projection unit PLU of each of the exposure modules MU(A), MU(B), and MU(C) and a position of a detection field of vision of each of the alignment systems ALG, or confirmation of a position or image quality of a pattern image projected from the projection unit PLU, a calibration reference portion CU is provided on an end portion on the substrate holder 4B in the −X direction. Although a part in FIG. 1 is not shown, in each of the exposure modules MU(A), MU(B), and MU(C), nine modules are aligned at a constant interval in the Y direction as an example in the present embodiment, but the number of modules may be smaller than nine or may be larger than nine.

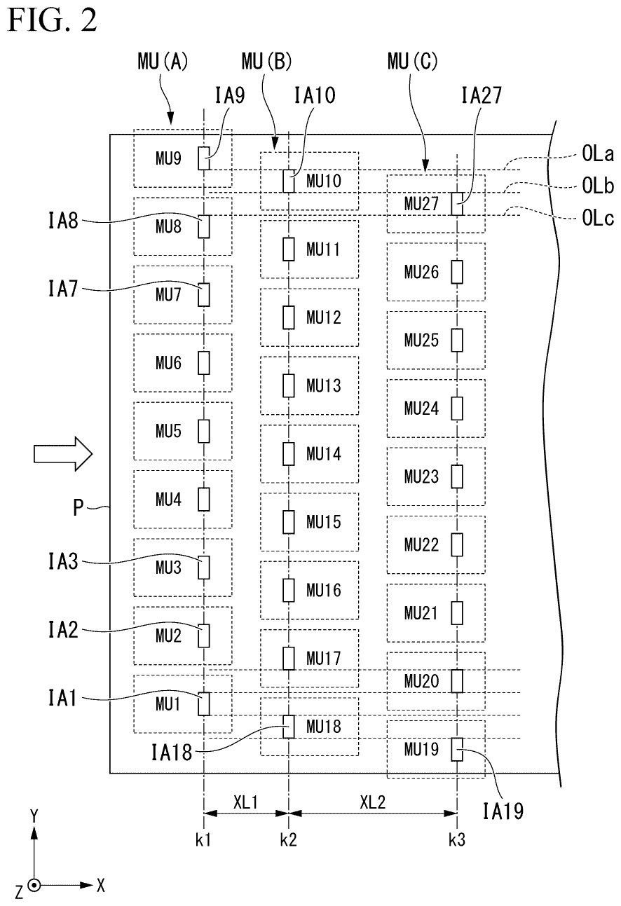

FIG. 2 is a view showing an arrangement example of a projection region IAn of the digital mirror device (DMD) 10 projected onto the substrate P by the projection unit PLU of each of the exposure modules MU(A), MU(B), and MU(C), and the orthogonal coordinate system XYZ is set to be the same as that in FIG. 1. In the present embodiment, each of the exposure module MU(A) of a first row, the exposure module MU(B) of a second row, and the exposure module MU(C) of a third row that are separated from each other in the X direction is constituted of nine modules aligned in the Y direction. The exposure module MU(A) is constituted of nine modules MU1 to MU9 arranged in the +Y direction, the exposure module MU(B) is constituted of nine modules MU10 to MU18 arranged in the −Y direction, and the exposure module MU(C) is constituted of nine modules MU19 to MU27 arranged in the +Y direction. All of the modules MU1 to MU27 have the same configuration, and when the exposure module MU(A) and the exposure module MU(B) are set to have a relationship of facing each other with respect to the X direction, the exposure module MU(B) and the exposure module MU(C) have a back-to-back relationship with respect to the X direction.

In FIG. 2, a shape of each of projection regions IA1, IA2, IA3, . . . , IA27 (may be represented by Ian, n is 1 to 27) by each of the modules MU1 to MU27 has a rectangular shape extending in the Y direction with an aspect ratio of about 1:2 as an example. In the present embodiment, in accordance with scanning movement of the substrate P in the +X direction, joint exposure is performed at an end portion of each of the projection regions IA1 to IA9 of the first row in the −Y direction and an end portion of each of the projection regions IA10 to IA18 of the second row in the +Y direction. Then, the joint exposure on a region on the substrate P that is not exposed by each of the projection regions IA1 to IA18 of the first row and the second row is performed by each of the projection regions IA19 to IA27 of the third row. A center point of each of the projection regions IA1 to IA9 of the first row is located on a line k1 parallel to the Y axis, a center point of each of the projection regions IA10 to IA18 of the second row is located on a line k2 parallel to the Y axis, and a center point of each of the projection regions IA19 to IA27 of the third row is located on a line k3 parallel to the Y axis. An interval between the line k1 and the line k2 in the X direction is set to a distance XL1, and an interval between the line k2 and the line k3 in the X direction is set to a distance XL2.

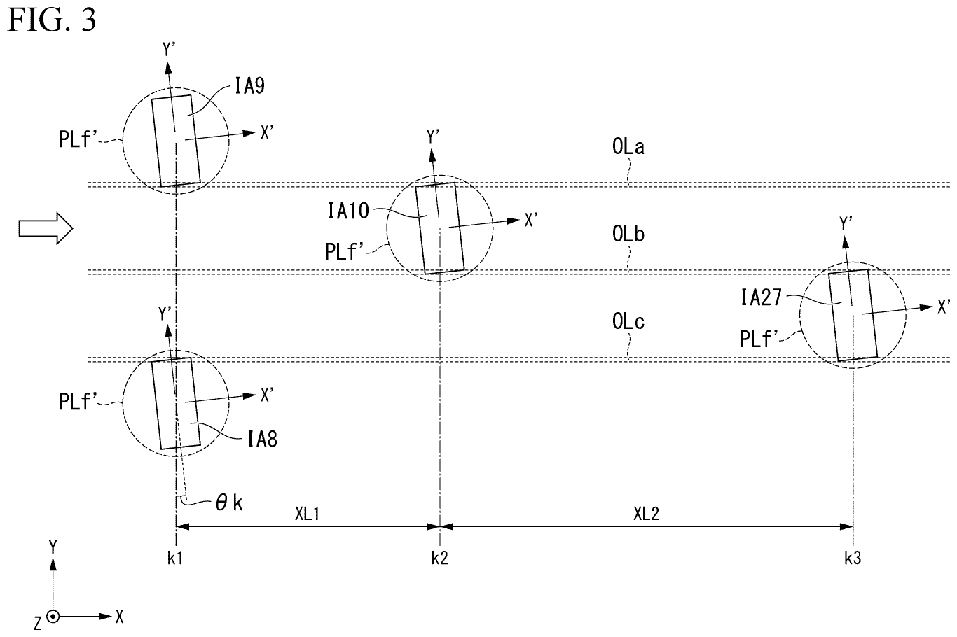

Here, when a joint portion between the end portion of the projection region IA9 in the −Y direction and the end portion of the projection region IA10 in the +Y direction is referred to as OLa, a joint portion between the end portion of the projection region IA10 in the −Y direction and the end portion of the projection region IA27 in the +Y direction is referred to as OLb, and a joint portion between the end portion of the projection region IA8 in the +Y direction and the end portion of the projection region IA27 in the −Y direction is referred to as OLc, a state of the joint exposure is described with reference to FIG. 3. In FIG. 3, the orthogonal coordinate system XYZ is set to be the same as those in FIG. 1 and FIG. 2, and a coordinate system X′Y′ in the projection regions IA8, IA9, IA10, and IA27 (and all the other projection regions IAn) are set to be inclined with respect to an X axis and a Y axis (the lines k1 to k3) of the orthogonal coordinate system XYZ by an angle θk. That is, the entire DMD 10 is inclined in the XY plane by the angle θk such that two-dimensional arrangement of a large number of micro mirrors of the DMD 10 becomes the coordinate system X′Y′.

A circular region containing each of the projection regions IA8, IA9, IA10, and IA27 (and all the other projection regions IAn are also the same) in FIG. 3 represents a circular image field PLf′ of the projection unit PLU. In the joint portion OLa, a projection image of the micro mirror aligned obliquely (the angle θk) of the end portion of the projection region IA9 in the −Y′ direction and a projection image of the micro mirror aligned obliquely (the angle θk) of the end portion of the projection region IA10 in the +Y′ direction are set to overlap each other.

Further, in the joint portion OLb, a projection image of the micro mirror aligned obliquely (the angle θk) of the end portion of the projection region IA10 in the −Y′ direction and a projection image of the micro mirror aligned obliquely (the angle θk) of the end portion of the projection region IA27 in the +Y′ direction are set to overlap each other. Similarly, in the joint portion OLc, a projection image of the micro mirror aligned obliquely (the angle θk) of the end portion of the projection region IA8 in the +Y′ direction and a projection image of the micro mirror aligned obliquely (the angle θk) of the end portion of the projection region IA27 in the −Y′ direction are set to overlap each other.

### (Configuration of Illumination Unit)

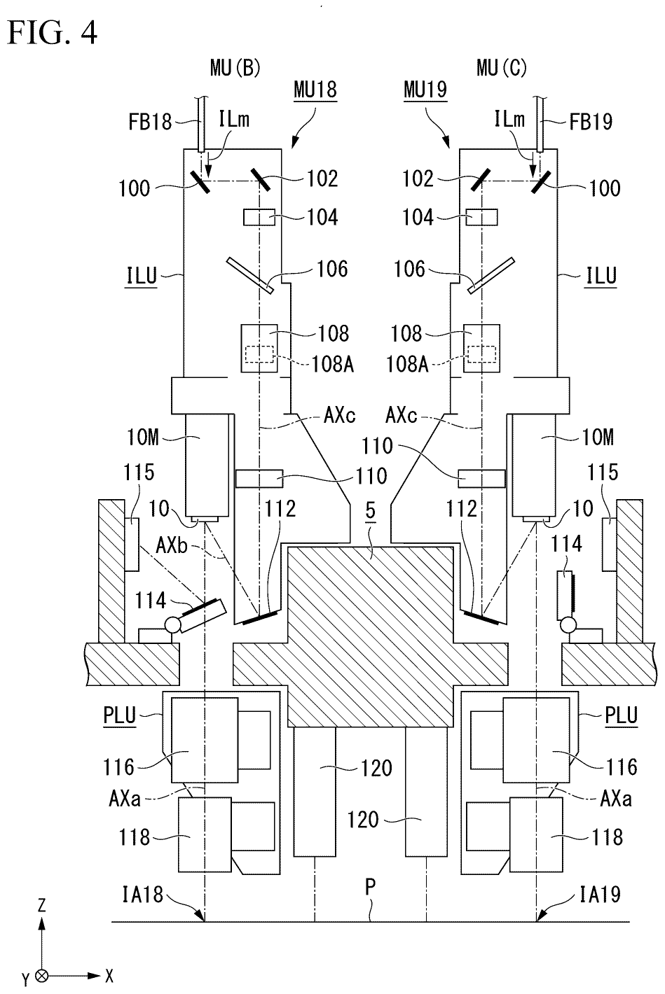

FIG. 4 is an optical arrangement view of a specific configuration of the module MU18 in the exposure module MU(B) and the module MU19 in the exposure module MU(C) shown in FIG. 1 and FIG. 2 when seen in the XZ plane. The orthogonal coordinate system XYZ of FIG. 4 is set to the same as the orthogonal coordinate system XYZ of FIG. 1 to FIG. 3. Further, as clearly recognized from the arrangement of each module in the XY plane shown in FIG. 2, the module MU18 is deviated from the module MU19 by a constant interval in the +Y direction, and the module 18 and the module 19 are installed to have a back-to-back relationship. Since each of the optical members in the module MU18 and each of the optical members in the module MU19 are formed of the same material and have the same configuration, the optical configuration of the module MU18 is mainly described in detail herein. The optical fiber unit FBU shown in FIG. 1 is constituted of 27 optical fiber bundles FB1 to FB27 to correspond to the 27 modules MU1 to MU27 shown in FIG. 2, respectively.

The illumination unit ILU of the module MU18 is constituted of a mirror 100 that reflects illumination light ILm that advances from an emission end of the optical fiber bundle FB18 in the −Z direction, a mirror 102 that reflects the illumination light ILm from the mirror 100 in the −Z direction, an input lens system 104 serving as a collimator lens, an optical integrator 108 including an illuminance adjustment filter 106, a micro fly eye (MFE) lens, a field lens, or the like, a condenser lens system 110, and an inclination mirror 112 that reflects the illumination light ILm from the condenser lens system 110 toward the DMD 10. The mirror 102, the input lens system 104, the optical integrator 108, the condenser lens system 110, and the inclination mirror 112 are arranged along an optical axis AXc parallel to the Z axis.

The optical fiber bundle FB18 is constituted of a single optical fiber wire or a bundle of a plurality of optical fiber wires. The illumination light ILm irradiated from an emission end of the optical fiber bundle FB18 (each of the optical fiber wires) is set to a numerical aperture (NA, also referred to as a spread angle) that allows incidence of the light without being cut off by the input lens system 104 in the subsequent stage. A position of a front focal point of the input lens system 104 is set to the same as the position of the emission end of the optical fiber bundle FB18 by design. Further, the position of the rear focal point of the input lens system 104 is set such that illumination light ILm from a single point light source or a plurality of point light sources formed on the emission end of the optical fiber bundle FB18 overlaps an incidence surface side of a MFE lens 108A of the optical integrator 108. Accordingly, an incidence surface of the MFE lens 108A is illuminated by Kohler illumination by the illumination light ILm from the emission end of the optical fiber bundle FB18. In an initial state, a geometrical center point of the emission end of the optical fiber bundle FB18 in the XY plane is located on the optical axis AXc, and a principal ray (center line) of the illumination light ILm from the point light source of the emission end of the optical fiber wire is parallel to (or coaxial with) the optical axis AXc.

The illumination light ILm from the input lens system 104 enters the condenser lens system 110 through the optical integrator 108 (the MFE lens 108A, the field lens, or the like) after reduction in illuminance with an arbitrary value of a range of 0% to 90% by the illuminance adjustment filter 106. The MFE lens 108A is constituted of a large number of rectangular micro lens having a size of several tens μm square in a two-dimensional array, and the entire shape in the XY plane is set to be almost similar to the entire shape of the mirror surface of the DMD 10 (an aspect ratio is about 1:2). Further, a position of the front focal point of the condenser lens system 110 is set to substantially the same as the position of the emission surface of the MFE lens 108A. Therefore, the illumination light from each of the point light sources formed on each emission side of the large number of micro lenses of the MFE lens 108A is converted to a substantially parallel light flux by the condenser lens system 110, reflected by the inclination mirror 112, and then, overlaps on the DMD 10 to be distributed with a uniform illuminance distribution. Since a surface light source in which a large number of point light sources (condensing points) are two-dimensionally densely aligned is generated on the emission surface of the MFE lens 108A, the emission surface functions as a surface light source member.

In the module MU18 shown in FIG. 4, the optical axis AXc parallel to the Z axis passing through the condenser lens system 110 is bent by the inclination mirror 112 and reaches the DMD 10, but an optical axis between the inclination mirror 112 and the DMD 10 becomes an optical axis AXb. In the present embodiment, a neutral plane including a center point of each of the large number of micro mirrors of the DMD 10 is set to be parallel to the XY plane. Accordingly, an angle formed between a normal line (parallel to the Z axis) of the neutral plane and the optical axis AXb becomes an incidence angle θα of the illumination light ILm with respect to the DMD 10. The DMD 10 is attached to a lower side of a mount portion 10M fixed to a support column of the illumination unit ILU. For example, a micro-motion stage in which a parallel link mechanism and a stretchable piezo element are assembled as disclosed in PCT International Publication No. 2006/120927 is provided on the mount portion 10M in order to finely adjust a position or a posture of the DMD 10.

The illumination light ILm irradiated to the micro mirror in an ON state among the micro mirrors of the DMD 10 is reflected in the X direction in the XZ plane so as to be directed toward the projection unit PLU. On the other hand, the illumination light ILm irradiated to the micro mirror in an OFF state among the micro mirrors of the DMD 10 is reflected in the Y direction in the YZ plane so as not to be directed toward the projection unit PLU. While described later in detail, the DMD 10 in the present embodiment is a roll and pitch drive type in which the ON state and the OFF state are switched by inclination in a roll direction and inclination in a pitch direction of the micro mirror.

A movable shutter 114 for shielding the reflected light from the DMD 10 in a non-exposure period is detachably provided in an optical path between the projection unit PLU and the DMD 10. The movable shutter 114 is pivoted to an angle position where the movable shutter 114 retreats from the optical path in an exposure period as shown on the side of the module MU19 and pivoted to an angle position where the movable shutter 114 is obliquely inserted into the optical path in the non-exposure period as shown in the side of the module MU18. A reflection surface is formed in the movable shutter 114 on the side of the DMD 10, and light from the DMD 10 reflected thereon is irradiated to a light absorption body 115. The light absorption body 115 absorbs light energy in an ultraviolet wavelength region (a wavelength of 400 nm or less) without re-reflection and converts the light energy into thermal energy. Therefore, a heat radiation mechanism (a heat radiation fin or a cooling mechanism) is also provided in the light absorption body 115. While not shown in FIG. 4, the reflected light from the micro mirror of the DMD 10 in the OFF state during the exposure period is absorbed by a similar light absorption body (not shown in FIG. 4) installed with respect to the optical path between the DMD 10 and the projection unit PLU in the Y direction (a direction perpendicular to the drawing of FIG. 4).

### (Configuration of Projection Unit)

The projection unit PLU attached to a lower side of the optical surface plate 5 is constituted as a bilateral telecentric image formation projection lens system constituted of a first lens group 116 and a second lens group 118 arranged along an optical axis AXa parallel to the Z axis. Each of the first lens group 116 and the second lens group 118 is configured to be translated with respect to a support column fixed to a lower side of the optical surface plate 5 by a micro-motion actuator in a direction along the Z axis (the optical axis AXa). A projection magnification Mp of the image formation projection lens system by the first lens group 116 and the second lens group 118 is determined by a relationship between an arrangement pitch Pd of the micro mirrors on the DMD 10 and a minimum line width (minimum pixel dimension) Pg of a pattern projected into the projection region IAn (n=1 to 27) on the substrate P.

As an example, when the required minimum line width (minimum pixel dimension) Pg is 1 μm and the arrangement pitch Pd of the micro mirrors is 5.4 μm, the projection magnification Mp is set to about ⅙ in consideration of an inclination angle θk in the XY plane of the projection region IAn (the DMD 10) described in FIG. 3. The image formation projection lens system by the lens groups 116 and 118 inverts or reverses a reduction image of the entire mirror surface of the DMD 10 and forms an image in the projection region IA18 (IAn) on the substrate P.

The first lens group 116 of the projection unit PLU is finely movable in an optical axis AXa direction by an actuator in order to perform fine adjustment (about ±several tens ppm) of the projection magnification Mp, and the second lens group 118 is finely movable in the optical axis AXa direction by an actuator in order to perform high speed adjustment of the focus. Further, in order to measure a position change of a surface of the substrate P in the Z axis direction with accuracy of sub-micron or less, a plurality of oblique incident light type focus sensors 120 are provided below the optical surface plate 5. The plurality of focus sensors 120 measure a position change of the entire substrate P in the Z axis direction, a position change of a partial region on the substrate P in the Z axis direction corresponding to each of the projection regions IAn (n=1 to 27), a partial inclination change of the substrate P, or the like.

In the illumination unit ILU and the projection unit PLU as described above, since the projection region IAn needs to be inclined by the angle θk in the XY plane as described for FIG. 3, the DMD 10 and the illumination unit ILU (at least an optical path portion of the mirror 102 to the mirror 112 along the optical axis AXc) in FIG. 4 are arranged to be inclined by the angle θk in the XY plane as a whole.

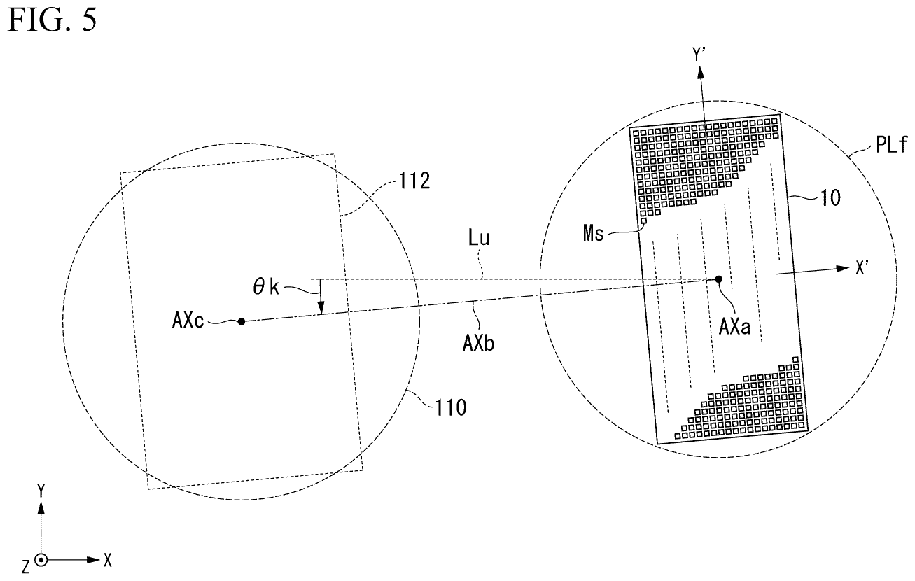

FIG. 5 is a view schematically showing a state in the XY plane in which the DMD 10 and the projection unit PLU are inclined by the angle θk in the XY plane. In FIG. 5, the orthogonal coordinate system XYZ is the same as the coordinate system XYZ of each of FIG. 1 to FIG. 4, and an arrangement coordinate system X′Y′ of the micro mirrors Ms of the DMD 10 is the same as the coordinate system X′Y′ shown in FIG. 3. A circle that contains the DMD 10 is an image field PLf on an object surface side of the projection unit PLU, and the optical axis AXa is located on a center thereof. On the other hand, the optical axis AXb where the optical axis AXc passing through the condenser lens system 110 of the illumination unit ILU is folded by the inclination mirror 112 is arranged to be inclined by the angle θk from a line Lu parallel to the X axis when seen in the XY plane.

### (Image Formation Optical Path by DMD)

Next, an image formation state of the micro mirrors Ms of the DMD 10 by the projection unit PLU (image formation projection lens system) is described in detail with reference to FIG. 6. An orthogonal coordinate system X′Y′Z of FIG. 6 is the same as the coordinate system X′Y′Z shown in FIG. 3 and FIG. 5, and FIG. 6 shows an optical path from the condenser lens system 110 of the illumination unit ILU to the substrate P. The illumination light ILm from the condenser lens system 110 advances along the optical axis AXc, is totally reflected by the inclination mirror 112, and reaches the mirror surface of the DMD 10 along the optical axis AXb. Here, the micro mirror Ms located at a center of the DMD 10 is referred to as Msc, the micro mirror Ms located therearound is referred to as Msa, and the micro mirrors Msc and Msa are in an ON state.

When an inclination angle of the micro mirror Ms in an ON state is, for example, 17.5° as a standard value with respect to the X′Y′ plane (XY plane), in order to cause each principal ray of reflected light Sc and Sa from the micro mirrors Msc and Msa to be parallel to the optical axis AXa of the projection unit PLU, an incidence angle (an angle from the optical axis AXa of the optical axis AXb) Oa of the illumination light ILm irradiated to the DMD 10 is set to 35.0°. Accordingly, in this case, the reflection surface of the inclination mirror 112 is also arranged to be inclined by 17.5° (=θα/2) with respect to the X′Y′ plane (XY plane). A principal ray Lc of the reflected light Sc from the micro mirror Msc is coaxial with the optical axis AXa, a principal ray La of the reflected light Sa from the micro mirror Msa is parallel to the optical axis AXa, and the reflected light Sc and Sa enter the projection unit PLU with a predetermined numerical aperture (NA).

A reduction image ic of the micro mirror Msc reduced by the projection magnification Mp of the projection unit PLU is formed on the substrate P by the reflected light Sc at a position of the optical axis AXa in a telecentric state. Similarly, a reduction image ia of the micro mirror Msa reduced by the projection magnification Mp of the projection unit PLU is formed on the substrate P by the reflected light Sa at a position away from the reduction image ic in the +X′ direction in a telecentric state. As an example, the first lens group 116 of the projection unit PLU is constituted of two lens groups G1 and G2, and the second lens group 118 is constituted of three lens groups G3, G4, and G5. An exit pupil (also simply referred to as a pupil) Ep is set between the lens group G3 and the lens group G4 of the second lens group 118. A light source image (an aggregate of a large number of point light sources formed on an emission surface side of the MFE lens 108A) of the illumination light ILm is formed at a position of the pupil Ep and forms a configuration of Kohler illumination. The pupil Ep is also referred to as an aperture of the projection unit PLU, and a size (diameter) of the aperture is one factor that defines resolving power of the projection unit PLU.

Regular reflected light from the micro mirror Ms in an ON state of the DMD 10 is set to pass without being blocked by the maximum diameter (diameter) of the pupil Ep, and a numerical aperture NAi on an image side (the side of the substrate P) in an equation representing resolution R which is R=k1·(λ/NAi) is determined by the maximum diameter of the pupil Ep and a distance of a rear (image side) focal point of the projection unit PLU (the lens groups G1 to G5 as the image formation projection lens system). Further, a numerical aperture NAo on the side of the object surface (the DMD 10) of the projection unit PLU (the lens groups G1 to G5) is expressed by a product of the projection magnification Mp and the numerical aperture NAi, and when the projection magnification Mp is ⅙, the numerical aperture NAo is obtained by NAo=NAi/6.

In the configuration of the illumination unit ILU and the projection unit PLU shown in FIG. 6 and FIG. 4 described above, an emission end of the optical fiber bundle FBn (n=1 to 27) connected to each module MUn (n=1 to 27) is set to an optically conjugate relation with an emission end side of the MFE lens 108A of the optical integrator 108 by the input lens system 104, and an incidence end side of the MFE lens 108A is set to an optically conjugate relation with a middle of the mirror surface (neutral plane) of the DMD 10 by the condenser lens system 110. Thereby, the illumination light ILm irradiated to the entire mirror surface of the DMD 10 becomes a uniform illuminance distribution (for example, intensity irregularity within ±1%) due to an action of the optical integrator 108. Further, an emission end side of the MFE lens 108A and a surface of the pupil Ep of the projection unit PLU are set to an optically conjugate relation by the condenser lens system 110 and the lens groups G1 to G3 of the projection unit PLU.

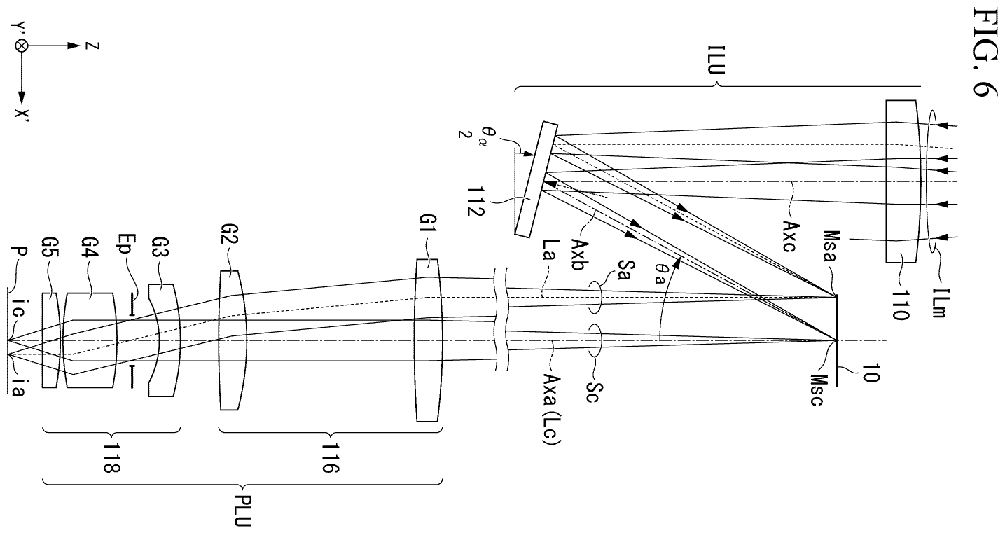

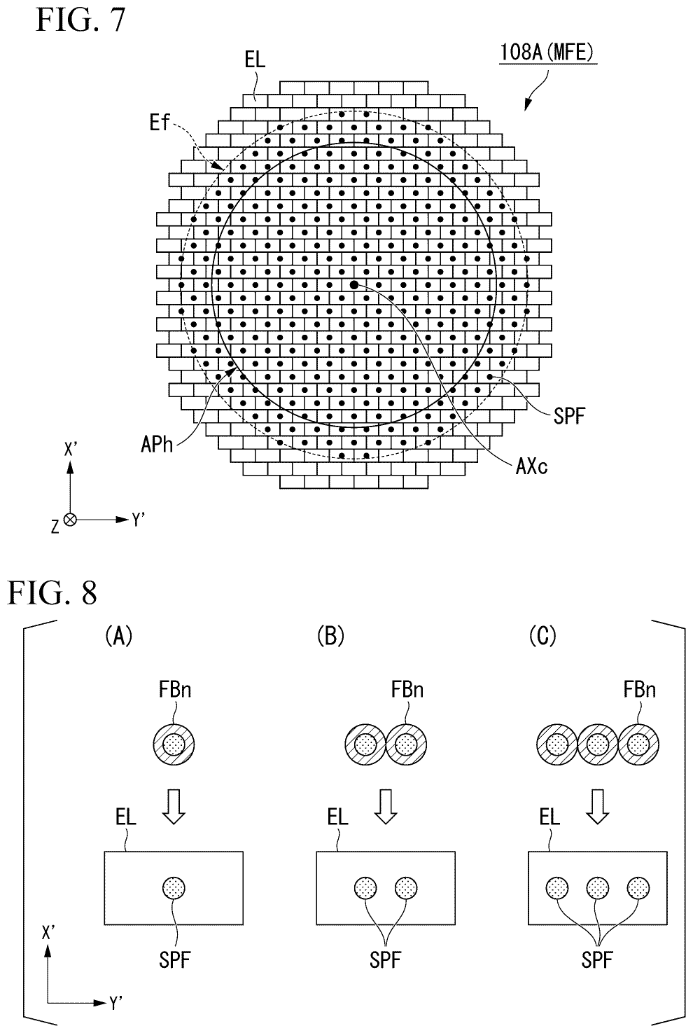

FIG. 7 is a schematic view in which the MFE lens 108A of the optical integrator 108 is seen from an emission surface side. The MFE lens 108A has a cross-sectional shape similar to the shape of the entire mirror surface (image formation region) of the DMD 10 and is constituted by densely aligning, in the X′ direction and the Y′ direction, a large number of lens elements EL having a rectangular cross section extending in the Y′ direction in the X′Y′ plane. The illumination light ILm from the input lens system 104 shown in FIG. 4 is irradiated as a substantially circular irradiation region Ef on an incidence surface side of the MFE lens 108A. The irradiation region Ef is a circular region using the optical axis AXc as a center by design with a shape similar to each emission end of a single or a plurality of optical fiber wires of the optical fiber bundle FB18 (FBn) in FIG. 4.

Point light sources SPF generated by the illumination light ILm from the emission end of the optical fiber bundle FB18 (FBn) are densely distributed in a substantially circular region on the emission surface side of each of the lens elements EL located in the irradiation region Ef among the large number of lens elements EL of the MFE lens 108A. Further, a circular region APh in FIG. 7 represents an opening range when a variable aperture diaphragm is provided on an emission surface side of the MFE lens 108A. The actual illumination light ILm is generated by the large number of point light sources SPF scattered in the circular region APh, and light from the point light sources SPF outside the circular region APh is blocked.

FIGS. 8(A), 8(B), and 8(C) are views schematically showing an example of an arrangement relationship between the point light source SPF formed on the emission surface side of the lens element EL of the MFE lens 108A of FIG. 7 and the emission end of the optical fiber bundle FBn. The coordinate system X′Y′ of each of FIGS. 8(A), 8(B), and 8(C) are the same as the coordinate system X′Y′ set in FIG. 7. FIG. 8(A) represents a case in which the optical fiber bundle FBn is a single optical fiber wire, FIG. 8(B) represents a case in which two optical fiber wires are aligned in the X′ direction as the optical fiber bundle FBn, and FIG. 8(C) represents a case in which three optical fiber wires are aligned in the X′ direction as the optical fiber bundle FBn.

Since the emission end of the optical fiber bundle FBn and the emission surface of the MFE lens 108A (the lens elements EL) are set to an optically conjugate relation (image formation relation), when the optical fiber bundle FBn is the single optical fiber wire, as shown in FIG. 8(A), the single point light source SPF is formed at a center position on the emission surface side of the lens elements EL. When the two optical fiber wires are bundled in the X′ direction as the optical fiber bundle FBn, as shown in FIG. 8(B), a geometrical center of the two point light sources SPF is formed to become a center position on the emission surface side of the lens elements EL. Similarly, when the three optical fiber wires are bundled in the X′ direction as the optical fiber bundle FBn, as shown in FIG. 8(C), a geometrical center of the three point light sources SPF is formed to become a center position on the emission surface side of the lens elements EL.

When power of the illumination light ILm from the optical fiber bundle FBn is large and the point light sources SPF are condensed to the emission surface of each of the lens elements EL of the MFE lens 108A as the surface light source member or the optical integrator, damage (cloudiness, burning, or the like) may be applied to each of the lens elements EL. In that case, the condensing position of the point light sources SPF may be set in a space slightly deviated outward from the emission surface (the emission surface of the lens elements EL) of the MFE lens 108A. A configuration in which a position of a point light source (focusing point) is deviated to the outside of the lens element in an illumination system using a fly eye lens in this way is disclosed in, for example, U.S. Pat. No. 4,939,630.

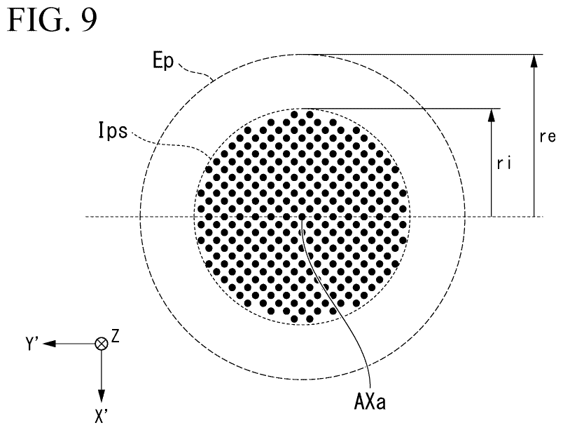

FIG. 9 is a view schematically showing a state of a light source image Ips formed on the pupil Ep in the second lens group 118 of the projection unit PL of FIG. 6 when it is assumed that the entire mirror surface of the DMD 10 is used as a single planar mirror, and the planar mirror is inclined by an angle θα/2 to be parallel to the inclination mirror 112 in FIG. 6. The light source image Ips shown in FIG. 9 is an image obtained by forming the large number of point light sources SPF (becoming a surface light source aggregated in a substantially circular shape) formed on the emission surface side of the MFE lens 108A again. In this case, diffraction light or scattered light is not generated from the single planar mirror arranged instead of the DMD 10, and only the light source image Ips by only the regular reflected light (zero order light) is generated at the center in the pupil Ep coaxially with the optical axis AXa.

In FIG. 9, when a radius corresponding to the maximum diameter of the pupil Ep is referred to as re and a radius corresponding to an effective diameter of the light source image Ips as the surface light source is referred to as ri, a σ value representing a size (area) of the light source image Ips with respect to the size (area) of the pupil Ep becomes σ=ri/re. The σ value may be appropriately changed in order to improve a line width, a concentration degree, or a depth of focus (DOF) of the projected and exposed pattern. The σ value can be changed by providing a variable aperture diaphragm (the circular region APh in FIG. 7) at a position on the emission surface side of the MFE lens 108A or a position of the pupil Ep in the second lens group 118.

In this type of exposure apparatus EX, since the pupil Ep in the second lens group 118 is often used while maintaining the maximum diameter, change of the σ value is mainly performed by the variable aperture diaphragm provided on the emission surface side of the MFE lens 108A. In that case, the radius ri of the light source image Ips is defined by a radius of the circular region APh in FIG. 7. Of course, the σ value or the depth of focus (DOF) may be adjusted by providing the variable aperture diaphragm on the pupil Ep of the projection unit PLU.

### (Telecentric Error at Time of Projection Exposure)

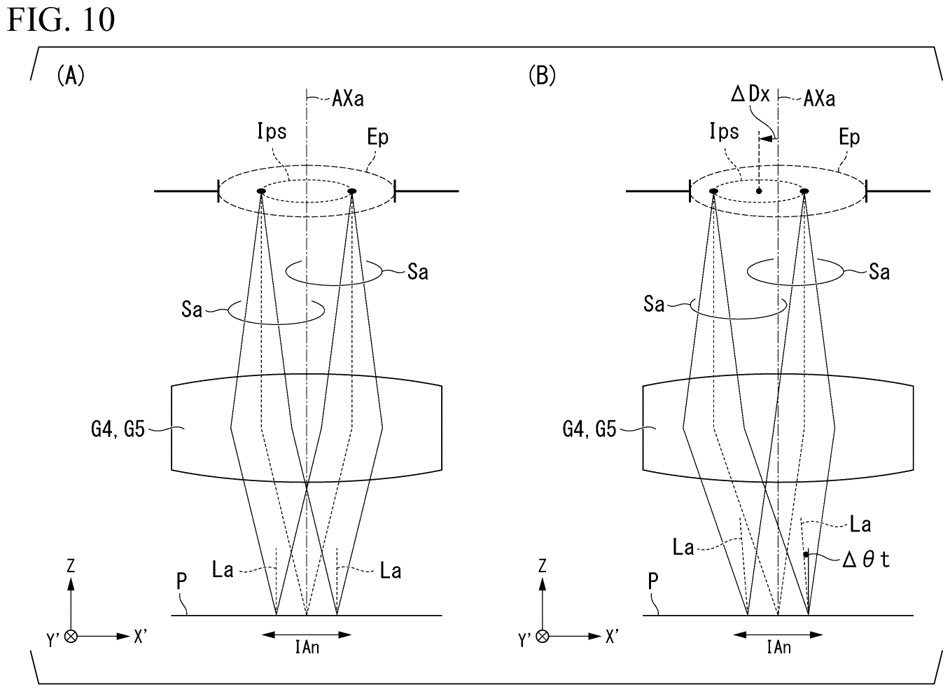

Next, a telecentric error that may occur in the case of the exposure apparatus EX using the DMD 10 as in the present embodiment will be described, but one of generation factors of the telecentric error is simply described with reference to FIG. 10 in advance. FIG. 10(A) and FIG. 10(B) are views schematically showing a behavior of the illumination light (image formation light flux) Sa of the optical path from the pupil Ep of the second lens group 118 to the substrate P shown in FIG. 6. The orthogonal coordinate system X′Y′Z in FIG. 10(A) and FIG. 10(B) is the same as the coordinate system X′Y′Z of FIG. 6. In order to simplify the explanation, here, a case is assumed in which the entire mirror surface of the DMD 10 is a single planar mirror and is inclined by the angle θα/2 to be parallel to the inclination mirror 112 in FIG. 6. In FIG. 10(A) and FIG. 10(B), the lens groups G4 and G5 are arranged along the optical axis AXa between the pupil Ep and the substrate P, and a circular light source image (surface light source image) Ips is formed in the pupil Ep as shown in FIG. 9. A principal ray of the reflected light (image formation light flux) Sa that enters the lens groups G4 and G5 passing through one point of a circumferential portion of the light source image (surface light source image) Ips in the X′ direction is La.

FIG. 10(A) shows a behavior of the reflected light (image formation light flux) Sa when the light source image (surface light source image) Ips is accurately located at the center of the pupil Ep, all the principal ray La of the reflected light (image formation light flux) Sa toward one point in the projection region IAn on the substrate Pis parallel to the optical axis AXa, and the image formation light flux projected to the projection region IAn is in a telecentric state, that is, a state in which the telecentric error is zero. On the other hand, FIG. 10(B) shows a behavior of the reflected light (image formation light flux) Sa when the light source image (surface light source image) Ips is laterally shifted by ΔDx in the X′ direction from the center of the pupil Ep. In this case, all the principal ray La of the reflected light (image formation light flux) Sa directed toward one point in the projection region IAn on the substrate P is inclined by Δθt with respect to the optical axis AXa. The inclination amount Δθt is the telecentric error, and the image formation state of the pattern image projected to the projection region IAn is decreased as the inclination amount Δθt (that is, a lateral shift amount ΔDx) is increased to be larger than a predetermined acceptable value.

### (Configuration of DMD)

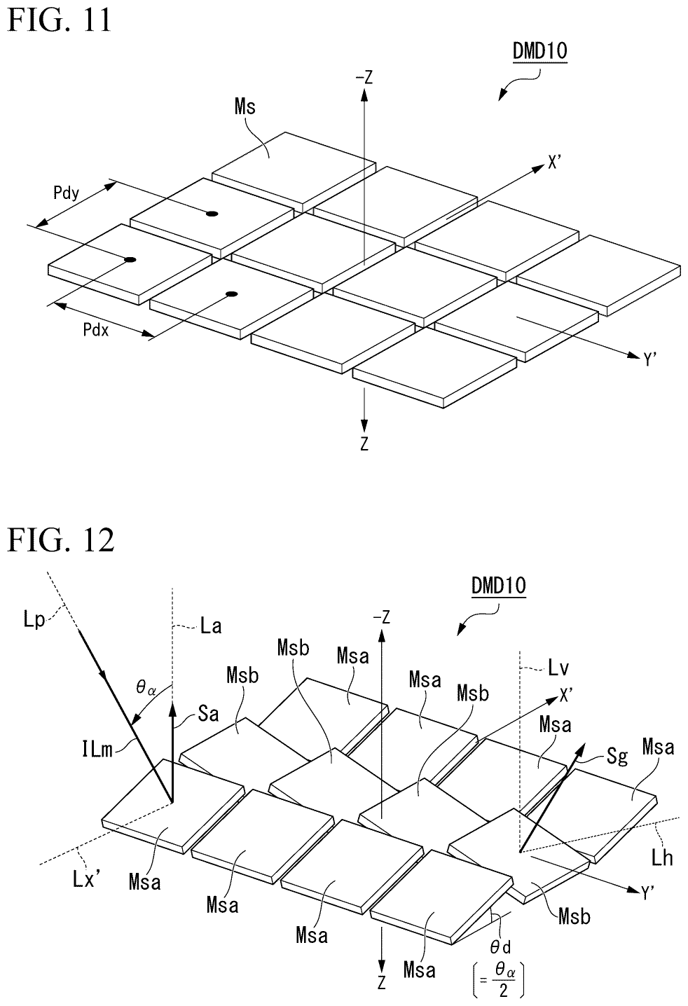

As described above, the DMD 10 used in the present embodiment is a roll and pitch drive type, but a specific configuration thereof is described with reference to FIG. 11 and FIG. 12. FIG. 11 and FIG. 12 are a perspective view in which part of the mirror surface of the DMD 10 is enlarged. Here, the orthogonal coordinate system X′Y′Z is also the same as the coordinate system X′Y′Z in FIG. 6. FIG. 11 shows a state when electric power supply to a drive circuit provided on a lower layer of each micro mirror Ms of the DMD 10 is off. When the electric power supply is in an OFF state, the reflection surface of each micro mirror Ms is set to be parallel to the X′Y′ plane.

Here, an arrangement pitch of the micro mirrors Ms in the X′ direction is Pdx (μm), an arrangement pitch in the Y′ direction is Pdy (μm), and the arrangement pitches are practically set as Pdx=Pdy.

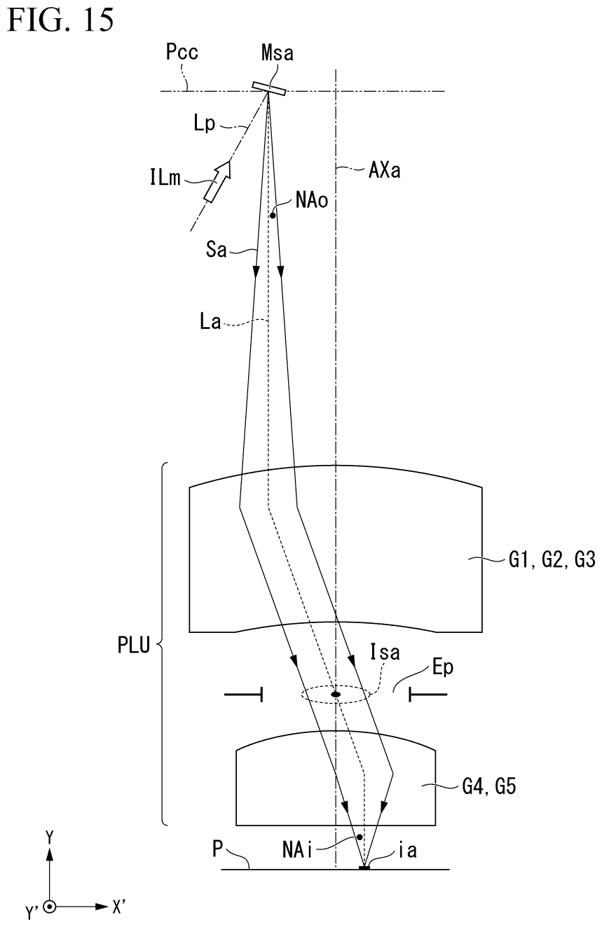

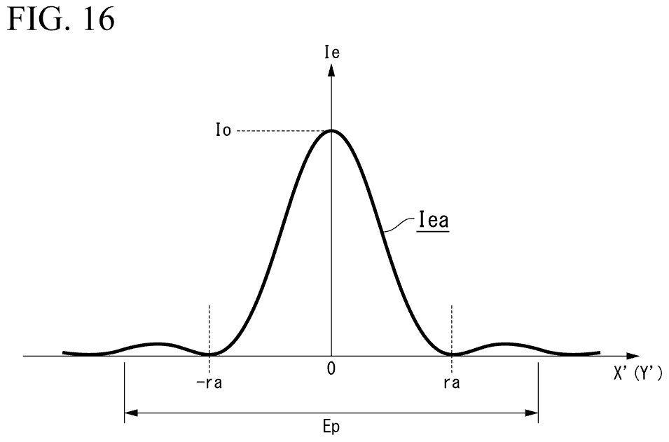

FIG. 12 shows a state in which electric power supply to the drive circuit is turned on, and the micro mirror Msa in an ON state and the micro mirror Msb in an OFF state are mixed. In the present embodiment, the micro mirror Msa in the ON state is driven to be inclined by the angle θd (=θα/2) from the X′Y′ plane around a line parallel to the Y′ axis, and the micro mirror Msb in the OFF state is driven to be inclined by the angle θd (=θα/2) from the X′Y′ plane around a line parallel to the X′ axis. The illumination light ILm is irradiated to each of the micro mirrors Msa and Msb along a principal ray Lp (parallel to the optical axis AXb shown in FIG. 6) parallel to the X′Z plane. A line Lx′ in FIG. 15 is obtained by projecting the principal ray Lp to the X′Y′ plane and is parallel to the X′ axis.

The incidence angle θα of the illumination light ILm to the DMD 10 is an inclination angle with respect to the Z axis in the X′Z plane, and the reflected light (image formation light flux) Sa that advances substantially parallel to the Z axis in the −Z direction is generated from the micro mirror Msa in the ON state inclined by the angle θα/2 in the X′ direction from a geometrical optical point of view. On the other hand, the reflected light Sg reflected by the micro mirror Msb in the OFF state is generated in the −Z direction in a non-parallel state to the Z axis since the micro mirror Msb is inclined in the Y′ direction. In FIG. 12, when a line Lv is a line parallel to the Z axis (the optical axis AXa), and a line Lh is a projection of the principal ray of the reflected light Sg to the X′Y′ plane, the reflected light Sg advances in a direction inclined in a plane including the line Lv and the line Lh.

### (Image Formation State by DMD)

In the projection exposure using the DMD 10, while switching each of the large number of micro mirrors between the inclination in the ON state and the inclination in the OFF state based on the pattern data (drawing data) at a high speed by the operation shown in FIG. 12, the substrate P is scanned and moved in the X direction at a speed corresponding to the switching speed, and a pattern exposure is performed. However, the telecentric state (telecentricity) of the image formation light flux projected from the projection unit PLU (the first lens group 116 and the second lens group 118) to the substrate P may be changed depending on the fineness, the concentration degree, or the periodicity of the projected pattern. This is because the mirror surface of the DMD 10 acts as a reflection-type diffraction grating (blazed diffraction grating) depending on the inclination state in accordance with the pattern of the large number of micro mirrors Ms of the DMD 10.

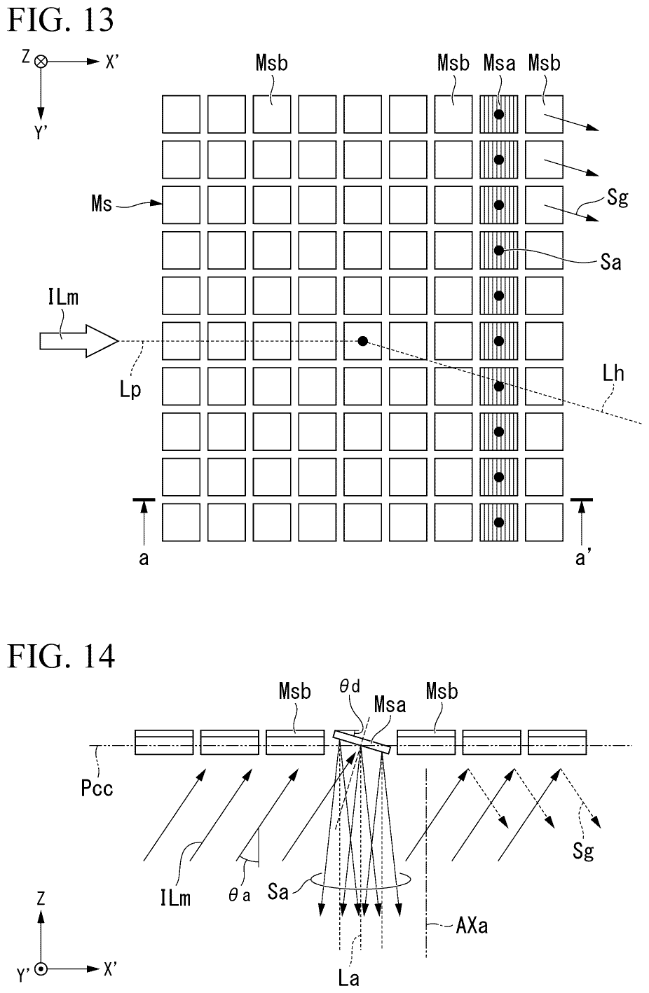

FIG. 13 is a view showing part of the mirror surface of the DMD 10 when seen in the X′Y′ plane, and FIG. 14 is a view in which an a-a′ arrow part of the mirror surface of the DMD 10 of FIG. 13 is seen in a X′Z plane. In FIG. 13, among the large number of micro mirrors Ms, only the micro mirrors Ms in a row aligned in the Y′ direction are the micro mirrors Msa in the ON state, and the other micro mirrors Ms are the micro mirrors Msb in the OFF state. The inclination state of the micro mirrors Ms shown in FIG. 13 appears when an isolated line pattern having a line width (for example, about 1 μm) of the resolution limit is projected. In the X′Y′ plane, the reflected light (image formation light flux) Sa from the micro mirrors Msa in the ON state is generated to be parallel to the Z axis in the −Z direction, and the reflected light Sg from the micro mirrors Msb in the OFF state is generated in the −Z direction but inclined in a direction along the line Lh in FIG. 11.

In this case, as shown in FIG. 14, only one of the large number of micro mirrors Ms aligned in the X′ direction is a micro mirror Msa in the ON state inclined by the angle θd (=θα/2) around a line parallel to the Y′ axis with respect to the neutral plane Pcc (a plane parallel to the X′Y′ plane including the center point of all the micro mirrors Ms). Accordingly, when seen in the X′Z plane, the reflected light (image formation light flux) Sa generated from the micro mirror Msa in the ON state becomes a simple regular reflected light that does not include diffraction light of one order or more, and the principal ray La becomes parallel to the optical axis AXa and enters the projection unit PLU.

The reflected light Sg from the other micro mirrors Msb in the OFF state does not enter the projection unit PLU. When the micro mirror Msa in the ON state is one isolated micro mirror with respect to the X′ direction (or a row aligned in the Y′ direction), the principal ray La of the reflected light (image formation light flux) Sa becomes parallel to the optical axis AXa regardless of a wavelength λ of the illumination light ILm.

FIG. 15 is a view schematically showing an image formation state by the projection unit PLU of the reflected light (image formation light flux) Sa from the isolated micro mirror Msa as shown in FIG. 14 in the X′Z plane. In FIG. 15, the member having the same function as the member described in FIG. 6 is designated by the same reference sign. Since the projection unit PLU (the lens groups G1 to G5) is a bilateral telecentric reduction projection system, if the principal ray La of the reflected light (image formation light flux) Sa from the isolated micro mirror Msa is parallel to the optical axis AXa, the principal ray La of the reflected light (image formation light flux) Sa formed as the reduction image ia is also parallel to a line (the optical axis AXa) perpendicular to the surface of the substrate P, and a telecentric error does not occur. The numerical aperture NAo of the reflected light (image formation light flux) Sa on the object surface (the DMD 10) side of the projection unit PLU shown in FIG. 15 is equal to the numerical aperture of the illumination light ILm.

As described in FIG. 9 and FIG. 10(A) above, when the DMD 10 is inclined by the angle θα/2 as a single large planar mirror, a center position of the circular light source image (surface light source image) Ips formed on the pupil Ep of the projection unit PLU passes through the optical axis AXa. Similarly, when only the regular reflected light Sa from the isolated micro mirror Msa in the mirror surface of the DMD 10 enters the projection unit PLU, the point image intensity distribution of the light flux Isa at the position (Fourier transform surface) of the pupil Ep of the regular reflected light Sa is a rectangular shape (square shape) in which the reflection surface of the micro mirror Ms is fine and is therefore represented by a sinc2 function (a point image intensity distribution of a square opening) using the optical axis AXa as a center.

FIG. 16 is a graph schematically showing a theoretical point image intensity distribution Iea (distribution generated by the light flux from the one point light source SPF shown in FIG. 7 and FIG. 8) of the light flux (here, zero order diffraction light) Isa in the pupil Ep by the reflected light Sa from the row of (or single) micro mirrors Msa isolated in the X′ direction. In the graph of FIG. 16, a lateral axis represents a coordinate position in the X′ (or Y′) direction with respect to the position of the optical axis AXa, and a vertical axis represents a light intensity Ie. The point image intensity distribution Iea is expressed by the following Equation (1).

$$\begin{matrix}[ Equation 1 ] & \\ Ie = Io \cdot {sinc}^{2} ( {X}^{′} ) = Io \cdot {sin}^{2} ( {X}^{′} ) / {( {X}^{′} )}^{2} & ( 1 )\end{matrix}$$

In Equation (1), Io represents a peak value of the light intensity Ie, and a position of the peak value Io by the reflected light Sa from the row of (or single) isolated micro mirrors Msa coincides with an origin 0 in the X′ (or Y′) direction, that is, a position of the optical axis AXa. Further, a position±ra in the X′ (or Y′) direction of a first dark line at which the light intensity Ie of the point image intensity distribution Iea initially becomes a minimum value (0) from the origin 0 corresponds to a position of the radius ri of the light source image Ips described in FIG. 9. The actual intensity distribution at the pupil Ep is obtained by convolution integration (convolution calculation) of the point image intensity distribution lea throughout a spread range (σ value) of the light source image Ips shown in FIG. 9 and becomes an approximately uniform intensity.

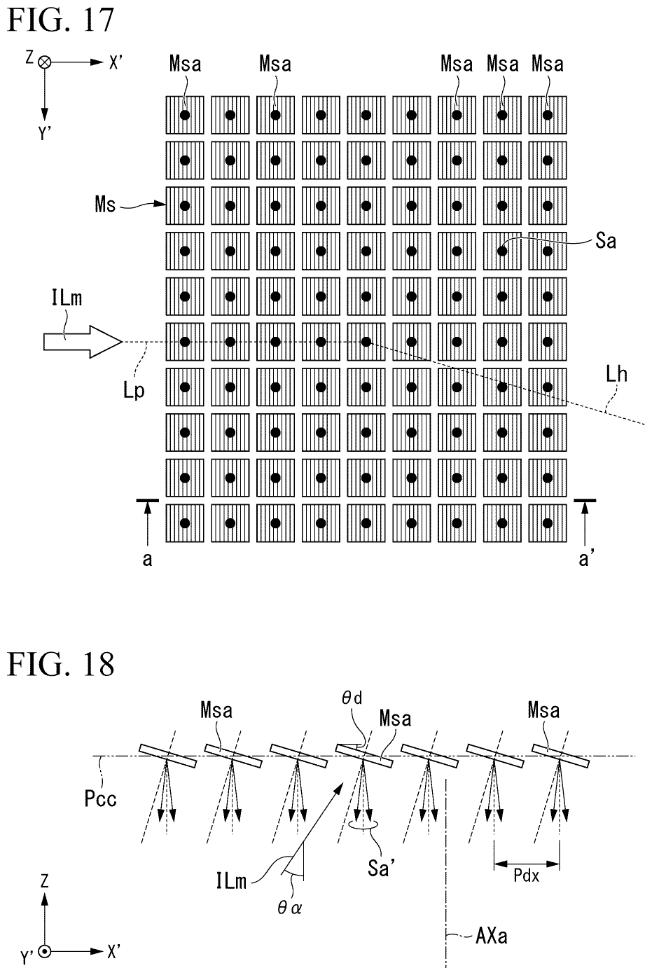

Next, a case in which a width of the projected pattern in the X′ direction (X direction) is sufficiently large is described with reference to FIG. 17 and FIG. 18. FIG. 17 is a view showing part of the mirror surface of the DMD 10 when seen in the X′Y′ plane, and FIG. 18 is a view in which an a-a′ arrow part of the mirror surface of the DMD 10 of FIG. 17 is seen in the X′Z plane. FIG. 17 shows a case in which all of the large number of micro mirrors Ms shown in FIG. 13 become the micro mirrors Msa in the ON state. In FIG. 17, only an arrangement in which the number of the micro mirrors Ms is nine in the X′ direction and the number of the micro mirrors Ms is ten in the Y′ direction is shown, but the adjacent micro mirrors Ms of the number described above or more (or all of the micro mirrors Ms on the DMD 10) may be in the ON state.

As shown in FIG. 17 and FIG. 18, the reflected light Sa′ is generated from the large number of micro mirrors Msa in the ON state aligned adjacent to each other in the X′ direction by a diffraction action in a state of being slightly inclined from the optical axis AXa. When the mirror surface of the DMD 10 in the state of FIG. 18 is considered as a diffraction grating aligned at a pitch Pdx in the X′ direction along the neutral plane Pcc, a generation angle θj of the diffraction light is expressed as in the following Equation (2) where j is an order (j=0, 1, 2, 3, . . . ), λ is a wavelength, and the incidence angle of the illumination light ILm is θα.

$$\begin{matrix}[ Equation 2 ] & \\ sin θ j = j ( λ / Pdx ) - sin θα & ( 2 )\end{matrix}$$

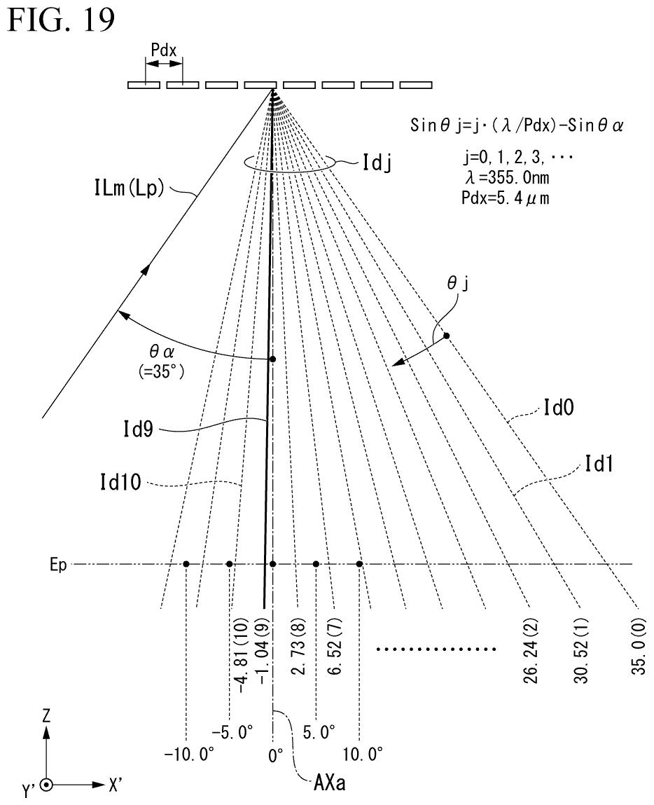

FIG. 19 is a graph showing a distribution of an angle θj of diffraction light Idj calculated, for example, when the incidence angle θα (an inclination angle of the principal ray Lp of the illumination light ILm with respect to the optical axis AXa) of the illumination light ILm is 35.0°, the inclination angle θd of the micro mirror Msa in the ON state is 17.5°, the pitch Pdx of the micro mirror Msa is 5.4 μm, and a wavelength λ is 355.0 nm. As shown in FIG. 19, since the incidence angle θα of the illumination light ILm is 35°, zero order diffraction light Id0 (j=0) is inclined at +35° with respect to the optical axis AXa, and as the diffraction order increases, the angle θj with respect to the zero order diffraction light Id0 increases. The numerical value shown in a lower portion of FIG. 19 represents an order j in a parenthesis and the inclination angle from the optical axis AXa of the diffraction light Idj of each order.

In the case of a numerical condition of FIG. 19, the inclination angle of ninth order diffraction light Id9 from the optical axis AXa is the smallest and is approximately −1.04°. Accordingly, when the micro mirrors Ms of the DMD 10 are densely arranged and become the ON state as shown in FIG. 17 and FIG. 18, the center of the intensity distribution of the image formation light flux (Sa′) in the pupil EP of the projection unit PLU is eccentric to a position which is laterally shifted by an amount (corresponding to the lateral shift amount ΔDx shown in FIG. 10(B) above) corresponding to the angle of −1.04° from the position of the optical axis AXa. The distribution of the actual image formation light flux in the pupil Ep is obtained by the convolution integration (convolution calculation) of the diffraction light distribution represented by Equation (2) using the sinc2 function represented by Equation (1).

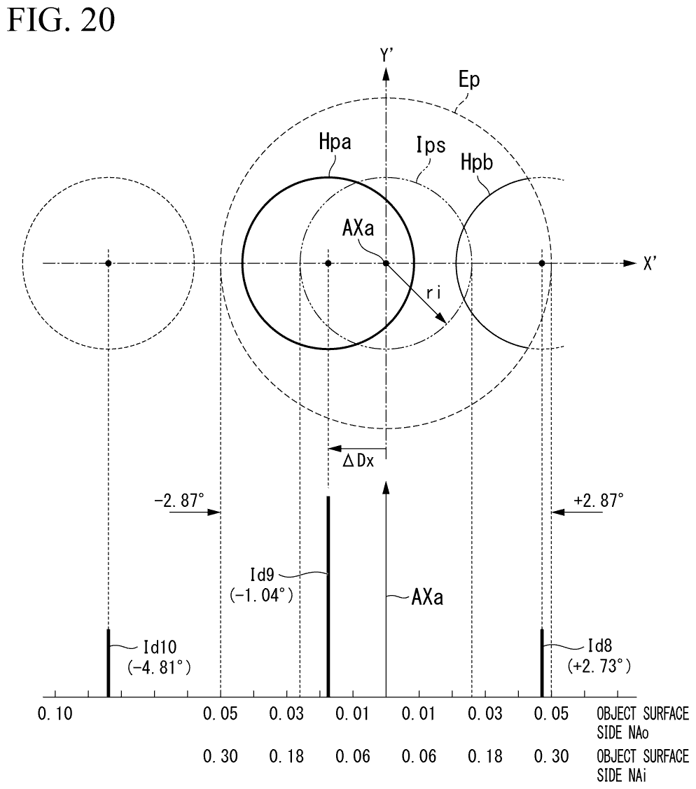

FIG. 20 is a view schematically showing an intensity distribution of the image formation light flux (Sa′) at the pupil Ep in the state where the diffraction light as shown in FIG. 19 is generated. The lateral axis in FIG. 20 represents a value obtained by converting the angle θj of the diffraction light Idj into the numerical aperture NAo on the side of the object surface (the DMD 10) and the numerical aperture NAi on the side of the image surface (the substrate P) when the projection magnification Mp of the projection unit PLU is ⅙. Further, the numerical aperture NAi on the image surface side of the projection unit PLU is assumed as 0.3 (the numerical aperture NAo on the object surface side=0.05). In this case, the resolving power (minimum resolution line width) Rs is represented by Rs=k1 (ANAi) using a process constant k1 (0<k1≤1).

Accordingly, the resolving power Rs is about 0.83 μm at the time of a wavelength λ=355.0 nm and k1=0.7. The pitch Pdx (Pdy) of the micro mirror Ms is reduced by the projection magnification Mp=⅙ on the side of the image surface (the substrate P) and becomes 0.9 μm. Accordingly, if the projection unit PLU has the numerical aperture NAi on the image surface side of 0.3 (the numerical aperture NAo on the object surface side is 0.05) or more, one projection image of the micro mirror Msa in the ON state can be formed with high contrast.

In FIG. 20, an angle θe from the optical axis AXa in the X′ direction of the numerical aperture NAo=0.05 on the object surface side which is the maximum diameter of the pupil Ep of the projection unit PLU becomes θe≈±2.87° from NAo=sin θe. As shown in FIG. 19, the inclination angle of −1.04° (accurately, −1.037°) of the ninth order diffraction light Id9 is about 0.018 when being converted into the numerical aperture NAo on the object surface side, and an intensity distribution Hpa of the image formation light flux Sa′ (regular reflected light component) in the pupil Ep is displaced by a shift amount ΔDx in the X′ direction from the original position of the light source image Ips (radius ri). Part of an intensity distribution Hpb by eighth order diffraction light Id8 also appears at a circumference in the +X′ direction in the pupil Ep, but the peak intensity is low. Further, since an inclination angle of tenth order diffraction light Id10 on the object surface side from the optical axis AXa is 4.81° which is a large value, the intensity distribution is distributed outside the pupil Ep and does not pass through the projection unit PLU.

As described also in FIG. 10(B) above, a telecentric error 40t on the image surface side that occurs due to the shift amount ΔDx of the center of the intensity distribution Hpa becomes Δθt=−6.22° (=−1.037°/the projection magnification Mp) in the case of a condition shown in FIG. 19 and FIG. 20. In this way, at the time of exposure of a large pattern in which many of the large number of micro mirrors Ms of the DMD 10 are densely in the ON state, the principal ray of the image formation light flux (Sa′) to the substrate P is inclined by 6° or more with respect to the optical axis AXa. Such a telecentric error Δθt may also become a contributory factor and reduce the image formation quality (contrast characteristics, distortion characteristics, symmetric properties, or the like) of the projection image.

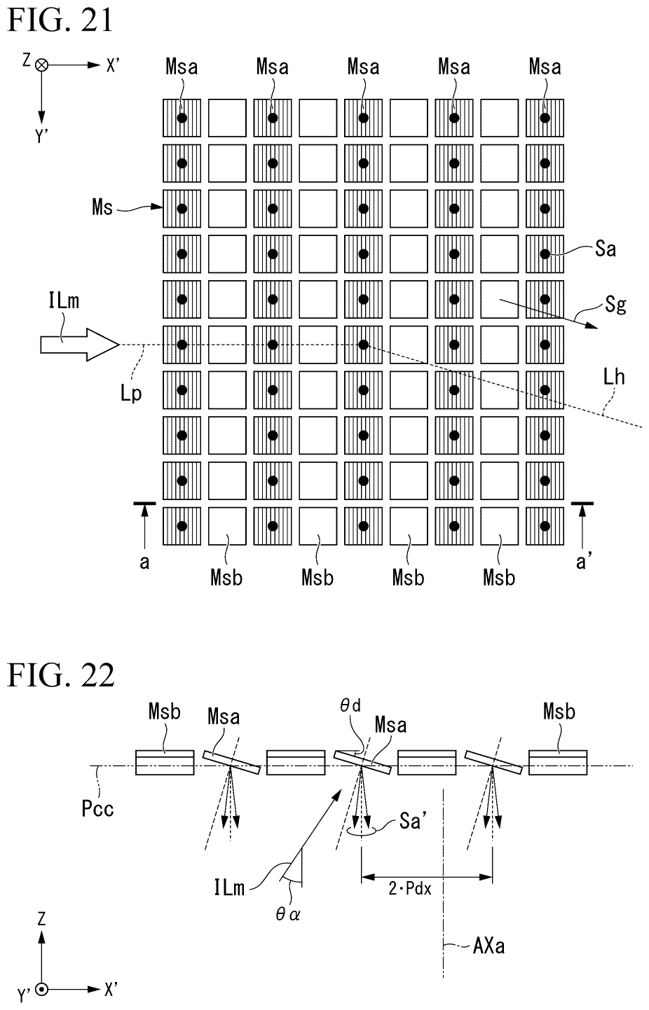

Next, a case of a line-and-space pattern in which a projected pattern has a constant pitch in the X′ direction (X direction) is described with reference to FIG. 21 and FIG. 22. FIG. 21 is a view showing part of the mirror surface of the DMD 10 when seen in the X′Y′ plane, and FIG. 22 is a view in which an a-a′ arrow part of the mirror surface of the DMD 10 of FIG. 21 is seen in the X′Z plane. FIG. 21 shows a case in which among the large number of micro mirrors Ms shown in FIG. 13, the micro mirrors Ms of odd numbers aligned in the X′ direction are the micro mirrors Msa in the ON state, and the micro mirrors Ms of even numbers are the micro mirrors Msb in the OFF state. It is assumed that the micro mirrors Ms of the odd numbers in the X′ direction are all in the ON state for one row aligned in the Y′ direction, and the micro mirrors Ms of the even numbers are all in the OFF state for one row aligned in the Y′ direction.

As shown in FIG. 22, when the micro mirrors Msa in the ON state are alternately arranged with respect to the X′ direction, the generation angle θj of the diffraction light generated from the DMD 10 is represented by the following Equation (3) similar to Equation (2) above by considering the mirror surface of the DMD 10 as the diffraction grating aligned at a pitch 2·Pdx along the neutral plane Pcc in the X′ direction.

$$\begin{matrix}[ Equation 3 ] & \\ sin θ j = j ( λ / 2 Pdx ) - sin θα & ( 3 )\end{matrix}$$

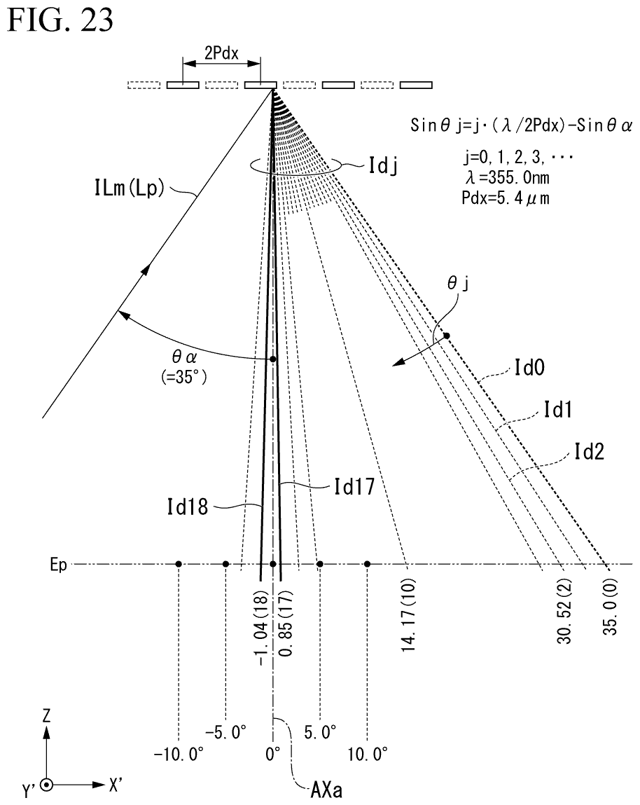

Similarly to the case of FIG. 19, FIG. 23 is a graph showing a distribution of the angle θj of the diffraction light Idj calculated when the incidence angle θα (an inclination angle of the principal ray Lp of the illumination light ILm with respect to the optical axis AXa) of the illumination light ILm is 35.0°, the inclination angle θd of the micro mirror Msa in the ON state is 17.5°, a pitch 2Pdx of the micro mirror Msa is 10.8 μm, and a wavelength λ is 355.0 nm.

As shown in FIG. 23, since the incidence angle θα of the illumination light ILm is 35°, the zero order diffraction light Id0 (j=0) is inclined at +35° with respect to the optical axis AXa, and as the diffraction order increases, the angle θj with respect to the zero order diffraction light Id0 increases. The numerical value shown in a lower portion of FIG. 23 represents an order j in a parenthesis and the inclination angle from the optical axis AXa of the diffraction light Idj of each order.

In the case of a numerical condition of FIG. 23, an inclination angle of seventeenth order diffraction light Id17 from the optical axis AXa is the smallest and is approximately 0.85°. Further, eighteenth order diffraction light Id18 having an inclination angle of −1.04° from the optical axis AXa is also generated. Accordingly, as shown in FIG. 21 and FIG. 22, when the micro mirrors Ms of the DMD 10 becomes the ON state in the finest line-and-space shape, a center of the intensity distribution of the image formation light flux (Sa′) in the pupil EP of the projection unit PLU is eccentric to a position which is laterally shifted by an amount corresponding to an angle of 0.85° or −1.04° from the position of the optical axis AXa. The distribution of the actual image formation light flux (Sa′) in the pupil Ep is obtained by the convolution integration (convolution calculation) of the diffraction light distribution represented by Equation (3) using a sinc2 function represented by Equation (1).

Similarly to FIG. 20, also in the case of FIG. 23, the intensity distribution Hpa of the image formation light flux (regular reflected light component) in the pupil Ep appears to be displaced in the X′ direction from the original position of the light source image Ips (radius ri) so as to correspond to each of the inclination angle of 0.85° of the seventeenth order diffraction light Id17 and the inclination angle of −1.04° of the eighteenth order diffraction light Id18. In the case of the diffraction light distribution as shown in FIG. 23, since the intensity of one of the intensity distribution Hpa formed in the direction of the seventeenth order diffraction light Id17 and the intensity distribution Hpa formed in the direction of the eighteenth order diffraction light Id18 is large and the intensity of the other is small, the telecentric error Δθt on the image surface side that occurs due to the shift of the intensity distribution Hpa is substantially within a range between Δθt=5.1° and Δθt=−6.22°.

This range is slightly different from the telecentric error Δθt=−6.22° in the generation direction of the ninth order diffraction light Id9 (refer to FIG. 19) when the large number of micro mirrors Ms are adjacent to each other and become the micro mirrors Msa in the ON state as shown in FIG. 17 and FIG. 18. Further, this is significantly different compared to the telecentric error Δθt=0° when a row (or a single) of the large number of micro mirrors Ms as shown in FIG. 13 and FIG. 14 become isolated micro mirrors Msa in the ON state. The actual pattern image projected onto the substrate P by the projection unit PLU is formed by the interference of the reflected light Sa′ including the diffraction light from the DMD 10 introduced in the projection unit PLU. Equation (3) can specify the generation state of the diffraction light in the line-and-space pattern in which an arrangement pitch or a line width is n times the Pdx (5.4 μm) using the following Equation (4) in which n is a real number.

$$\begin{matrix}[ Equation 4 ] & \\ sin θ j = j ( λ / ( n \cdot Pdx ) ) - sin θα & ( 4 )\end{matrix}$$

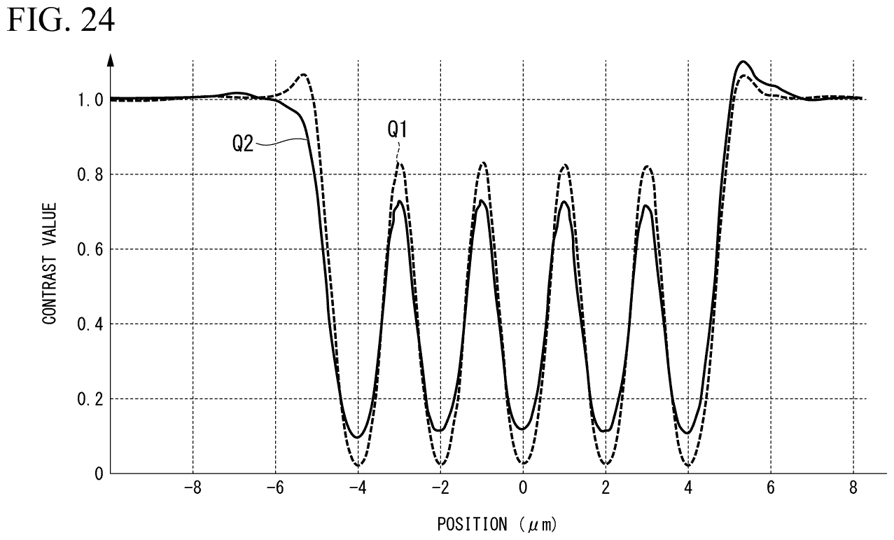

In this way, even when many of the large number of micro mirrors Ms of the DMD 10 become an ON state in the line-and-space shape, the principal ray of the image formation light flux to the substrate P may be largely inclined with respect to the optical axis AXa, and the image formation quality (contrast characteristics, distortion characteristics, or the like) of the projection image may be significantly degraded. Therefore, an example of a change in the image formation quality due to generation of the telecentric error Δθt is described with reference to FIG. 24. FIG. 24 is a graph showing a result of simulating a spatial image of a line-and-space pattern in which a line width on an image surface is 1 μm and a pitch in the X′ direction is 2 μm. The lateral axis of FIG. 24 represents a position (μm) on the image surface in the X′ direction, and a vertical axis represents a relative intensity value in which the intensity of the illumination light (incidence light) is normalized to 1.

In the graph of FIG. 24, the simulation was performed assuming that the numerical aperture NAi on the image side of the projection unit PLU is 0.25, a σ value of the illumination light ILm is 0.6, the image formation light flux (Sa′) in the pupil Ep of the projection unit PLU is eccentric in the X′ direction with respect to the optical axis AXa, and the telecentric error Δθt on the image surface side becomes 50 mrad (≈2.865°). In the graph of FIG. 24, a characteristic Q1 indicated by a broken line is a contrast characteristic in the best focus plane (best image formation plane) of the projection unit PLU, and a characteristic Q2 indicated by a solid line is a contrast characteristics in a surface defocused by 3 μm from the best focus plane in a direction of the optical axis AXa. In FIG. 28, a dark line having a line width of 1 μm is formed at five places of positions 0, +2 μm, and +4 μm.

It is typical that the contrast (intensity amplitude) of the characteristic Q2 is lower than the characteristic Q1 due to defocus, but it is found that a symmetry property between the characteristic in the vicinity of +5 μm and the characteristic in the vicinity of −5 μm is degraded due to the influence of the telecentric error Δθt. From this, in the case of the pattern in which the telecentric error Δθt on the image surface side exceeds an acceptable range (for example, ±2°), that is, when the micro mirrors Msa in the ON state among the large number of micro mirrors Ms of the DMD 10 are densely arranged in a wide range or aligned with periodicity, the accuracy of an edge position of a resist image corresponding to an edge portion of the exposed pattern is damaged, and as a result, errors occur in the line width or the size of the pattern. That is, as the intensity distribution (distribution of the diffraction light) formed on the pupil Ep of the projection unit PLU by the reflected light (image formation light flux) Sa′ from the DMD 10 is deviated from an isotropic state centered on the optical axis AXa or a symmetrical state, an asymmetry property of the projected pattern image is increased.

### (Wavelength Dependency of Telecentric Error)

The telecentric error Δθt described above changes depending on the wavelength λ as clearly recognized from Equation (2) to Equation (5) above. For example, in the case of the state of FIG. 17 and FIG. 18 represented by Equation (2), in order to cause the telecentric error Δθt on the image surface side to be zero, a wavelength λ that sets the inclination angle of −1.04° (accurately, −1.037) from the optical axis AXa of the ninth order diffraction light Id9 shown in FIG. 19 and FIG. 20 to be zero may be used.

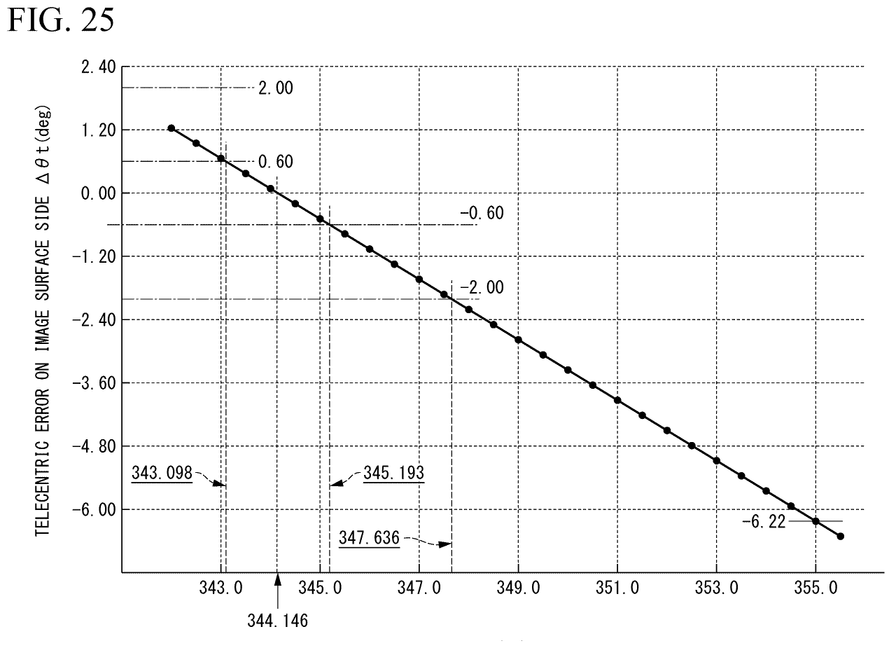

FIG. 25 is a graph in which a relationship between a center wavelength λ and a telecentric error Δθt is obtained based on Equation (2) above, a lateral axis represents the center wavelength λ (nm), and a vertical axis represents the telecentric error Δθt (deg) on the image surface side. When the pitch Pdx (Pdy) of the micro mirrors Ms of the DMD 10 is 5.4 μm, the inclination angle θd of the micro mirrors Ms is 17.5°, the incidence angle θα of the illumination light ILm is 35°, and the micro mirrors Ms are densely in the ON state as shown in FIG. 17 and FIG. 18, the telecentric error Δθt theoretically becomes zero when the center wavelength λ is approximately 344.146 nm. The telecentric error Δθt on the image surface side is preferably set to zero as much as possible but can have an acceptable range in accordance with the minimum line width (or the resolving power Rs) or the like of the pattern to be projected.

For example, when the acceptable range of the telecentric error Δθt on the image surface side is set to within +0.6° (approximately 10 mrad) as shown in FIG. 25, the center wavelength λ may be in the range of 343.098 nm to 345.193 nm (2.095 nm at a width). Further, when the acceptable range of the telecentric error Δθt on the image surface side is set to within ±2.0°, the center wavelength λ may be in the range of 340.655 nm to 347.636 nm (6.98 nm at a width).

In this way, the telecentric error Δθt that occurs due to the arrangement (periodicity) or a concentration degree, that is, the size of the distribution density of the micro mirrors Msa in the ON state of the DMD 10 also has wavelength dependency. In general, since specifications of the pitch Pdx (Pdy), the inclination angle θd, or the like of the micro mirrors Ms of the DMD 10 are uniquely set for a ready-made product (for example, a DMD compatible with ultraviolet ray manufactured by Texas Instrument), the wavelength λ of the illumination light ILm is set to match the specifications. In the DMD 10 of the present embodiment, since the pitch Pdx (Pdy) of the micro mirrors Ms is 5.4 μm and the inclination angle θd is 17.5°, a fiber amplifier laser light source that generates high brightness ultraviolet pulse light may be used as a light source that supplies the illumination light ILm to each of the optical fiber bundles FBn (n=1 to 27).

The fiber amplifier laser light source is constituted of, for example, as disclosed in Japanese Patent No. 6428675, a semiconductor laser element that generates seed light in an infrared wavelength region, a high speed switching element (electric optical element or the like) of the seed light, an optical fiber that amplifies the switched seed light using pump light, a wavelength conversion element that converts the amplified light in the infrared wavelength region into pulse light of a high frequency (ultraviolet wavelength region), and the like. In the case of such a fiber amplifier laser light source, a peak wavelength of the ultraviolet ray that can increase generation efficiency (conversion efficiency) by the combination of a semiconductor laser element, an optical fiber, and a wavelength conversion element that are available is 343.333 nm. In the case of the peak wavelength, the maximum telecentric error Δθt on the image surface side (the inclination angle on the image surface side of the ninth order diffraction light Id9 in FIG. 19 and FIG. 20) that can be generated in the state of FIG. 17 is about 0.466° (about 8.13 mrad).

As described above, when two light (350 nm and 400 nm) having a peak wavelength that is greatly separated from each other are combined as the illumination light ILm as disclosed in Japanese Unexamined Patent Application, First Publication No. 2019-23748 of the related art, the telecentric error Δθt can significantly vary depending on the form (an isolated pattern, a line-and-space pattern, or a large land-like pattern) of the pattern to be projected. In the present embodiment, as the illumination light ILm supplied to each of the modules MUn (n=1 to 27), light obtained by combining light from a plurality of fiber amplifier laser light sources in which the peak wavelength is slightly shifted from each other within a range where the wavelength-dependent telecentric error Δθt is accepted is used. In this way, by using the illumination light ILm obtained by combining the plurality of light having a slightly shifted peak wavelength, the contrast of speckles (or interference fringes) generated on the micro mirrors Ms (and on the substrate P) of the DMD 10 can be reduced by the coherence of the illumination light ILm. The details thereof will be described later.

### (Telecentric Adjustment Mechanism)

As described above, when the micro mirrors Msa that become the ON state in accordance with the pattern to be exposed to the substrate P among the large number of micro mirrors Ms of the DMD 10 are densely aligned in the X′ direction and the Y′ direction or are aligned with periodicity in the X′ direction (or the Y′ direction), the telecentric error (angular variation) Δθt occurs, although degrees may vary, in the image formation light flux (Sa, Sa′) projected from the projection unit PLU. Since each of the large number of micro mirrors Ms of the DMD 10 is switched between the ON state and the OFF state at a response speed of about 10 KHz, the pattern image generated by the DMD 10 also changes at a high speed in accordance with the drawing data. Therefore, during scanning exposure of a pattern of a display panel or the like, the pattern image projected from each of the modules MUn (n=1 to 27) instantaneously changes in a shape to an isolated line pattern, a dot pattern, a line-and-space pattern, a large land-like pattern, or the like.

A general display panel for a television (a liquid crystal type, an organic EL type) is constituted of an image display region aligned in a matrix such that a pixel portion of about 200 to 300 μm square has a predetermined aspect ratio such as 2:1 or 16:9 on the substrate P, and a peripheral circuit portion (an extraction wiring, a connection pad, or the like) arranged at a periphery thereof. A thin film transistor (TFT) for switching or for current driving is formed in each pixel portion, but a size (line width) of a pattern (a pattern of a gate layer, a drain/source layer, a semiconductor layer, or the like) for TFT, a gate wiring, or a drive wiring is sufficiently small compared to the arrangement pitch (200 to 300 μm) of the pixel portion. Therefore, when the pattern in the image display region is exposed, since the pattern image projected from the DMD 10 is almost isolated, the telecentric error Δθt does not occur.

However, depending on the configuration of the lighting drive circuit (TFT circuit) of each pixel portion, line-and-space wirings aligned in the X direction or the Y direction may be formed at a pitch smaller than the arrangement pitch of the pixel portion. In that case, when the pattern in the image display region is exposed, the pattern image projected from the DMD 10 has periodicity. Therefore, the telecentric error Δθt occurs depending on the degree of the periodicity. Further, at the time of exposure of the image display region, a rectangular pattern having substantially the same size as that of the pixel portion or having a half size or more of the area of the pixel portion may be uniformly exposed. In that case, half or more of the large number of micro mirrors Ms of the DMD 10 during exposure of the image display region becomes the ON state in an almost dense state. Therefore, a relatively large telecentric error Δθt may occur.

The generation state of the telecentric error Δθt can be estimated before exposure on the basis of the drawing data of the pattern for a display panel exposed by each of the plurality of modules MUn (n=1 to 27). In the present embodiment, a position or a posture of each of several optical members in the module MUn is finely adjustable, and by selecting an adjustable optical member from the optical members in accordance with the estimated magnitude of the telecentric error Δθt, it is possible to correct the telecentric error Δθt.

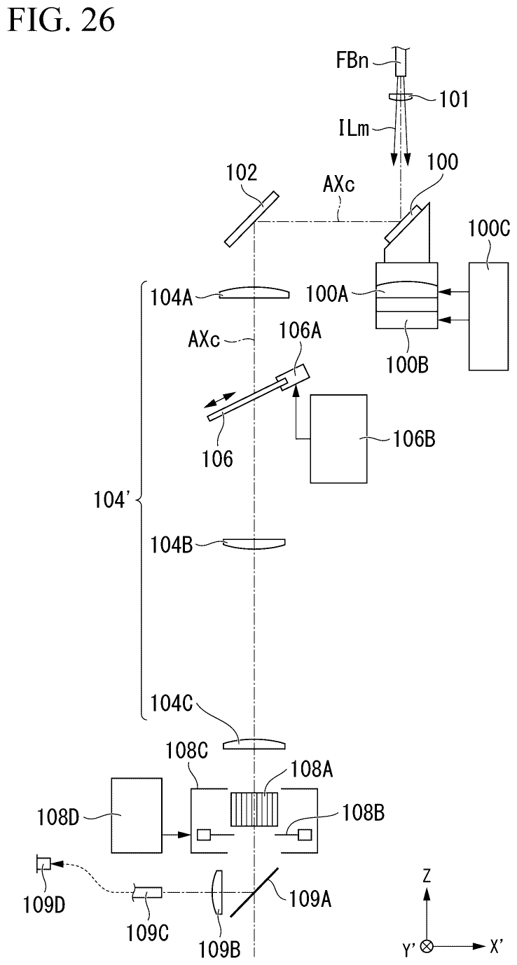

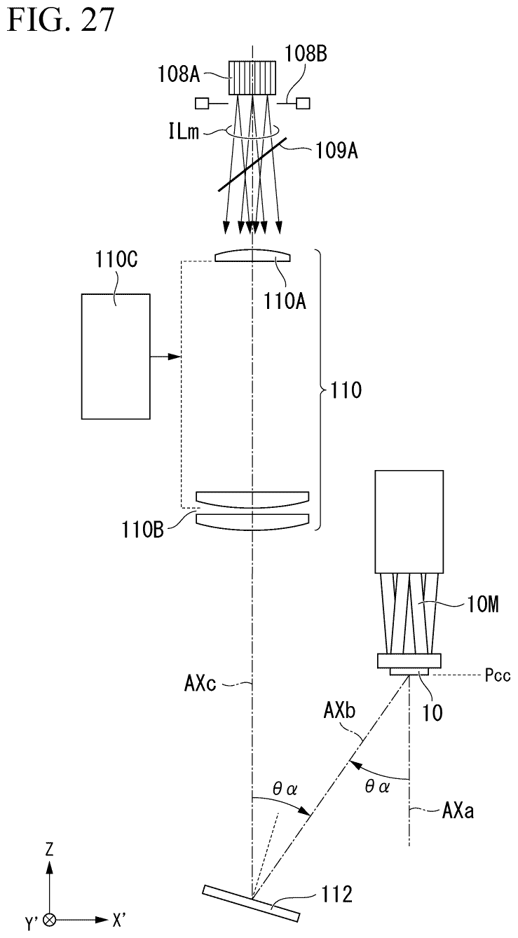

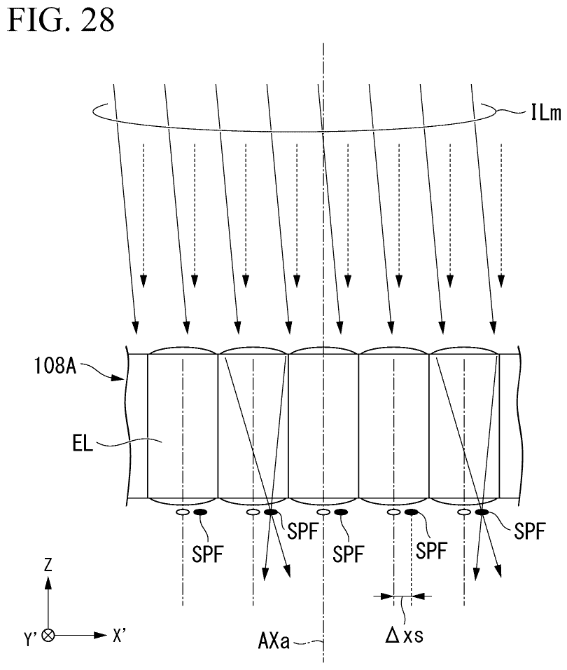

FIG. 26 shows a specific configuration of an optical path from the optical fiber bundle FBn to the MFE lens 108A in the illumination unit ILU of the module MUn shown in FIG. 4 or FIG. 6, and FIG. 27 shows a specific configuration of an optical path from the MFE lens 108A to the DMD 10 in the illumination unit ILU. In FIG. 26 and FIG. 27, the orthogonal coordinate system X′Y′Z is set to be the same as the coordinate system X′Y′Z of FIG. 4 (FIG. 6), and the members having the same function as the members shown in FIG. 4 are designated by the same reference signs.

Although not shown in FIG. 4, in FIG. 26, a collector lens 101 is arranged immediately behind the emission end of the optical fiber bundle FBn, and the spread of the illumination light ILm from the emission end is reduced. The optical axis of the collector lens 101 is set to be parallel to the Z axis, and the illumination light ILm that advances from the optical fiber bundle FBn with a predetermined numerical aperture is reflected by the mirror 100, advances in parallel with the X′ axis, and is reflected in the −Z direction by the mirror 102. A condenser lens system 104′ arranged in the optical path from the mirror 102 to the MFE lens 108A is constituted of three lens groups 104A, 104B, and 104C that are spaced apart from each other along the optical axis AXc.

The illuminance adjustment filter 106 is supported by a holding member 106A translated by a drive mechanism 106B and is arranged between the lens group 104A and the lens group 104B. For example, as disclosed in Japanese Unexamined Patent Application, First Publication No. 11-195587, an example of the illuminance adjustment filter 106 is one in which a fine light-blocking dot pattern is formed by gradually changing the density on a transmission plate such as a quartz or one in which a plurality of rows of elongated light-blocking wedge-shaped patterns are formed, and transmissivity of the illumination light ILm can be changed continuously within a predetermined range by moving a quartz plate in parallel.

The first telecentric adjustment mechanism is constituted of an inclination mechanism 100A that finely adjusts a two-dimensional inclination (a rotation angle around the X′ axis and the Y′ axis) of the mirror 100 which reflects the illumination light ILm from the optical fiber bundle FBn, a translation mechanism 100B that finely moves the mirror 100 two-dimensionally in the X′Y′ plane perpendicular to the optical axis AXc, and a drive unit 100C by a micro head, a piezo actuator, or the like that individually drives each of the inclination mechanism 100A and the translation mechanism 100B.

By adjusting the inclination of the mirror 100, the center ray (principal ray) of the illumination light ILm entering the condenser lens system 104′ can be adjusted to a state coaxial with the optical axis AXc.

Further, since the emission end of the fiber bundle FBn is arranged at a position of a front focal point of the condenser lens system 104′, when the mirror 100 is finely moved in the X′ direction, the center ray (principal ray) of the illumination light ILm entering the condenser lens system 104′ is shifted in parallel with respect to the optical axis AXc in the X′ direction. Thereby, the center ray (principal ray) of the illumination light ILm emitting from the condenser lens system 104′ advances while slightly inclining with respect to the optical axis AXc. Accordingly, the illumination light ILm entering the MFE lens 108A is slightly inclined in whole in the X′Z plane.

FIG. 28 is an exaggerated view showing a state of the point light source SPF formed on the emission surface side of the MFE lens 108A when the illumination light ILm entering the MFE lens 108A is inclined in the X′Z plane. When the center ray (principal ray) of the illumination light ILm is parallel to the optical axis AXc, the point light sources SPF condense on the emission surface side of each of the lens elements EL of the MFE lens 108A are located at a middle with respect to the X′ direction as indicated by a white circle in FIG. 28. When the illumination light ILm is inclined with respect to the optical axis AXc in the X′Z plane, the point light sources SPF condensed on the emission surface side of each of the lens elements EL is eccentric by Axs in the X′ direction from a middle position as indicated by a black circle in FIG. 28. In this case, as described in FIG. 7 to FIG. 9, the surface light source by the aggregate of the large number of point light sources SPF formed on the emission surface side of the MFE lens 108A is laterally shifted by Δxs in the X′ direction as a whole. Since a cross-sectional size in the X′Y′ plane of each lens element EL of the MFE lens 108A is small, an eccentricity amount Δxs in the X′ direction as the surface light source is also small.

As shown in FIG. 26, a variable aperture diaphragm (adjustment diaphragm of a σ value) 108B is provided on the emission surface side of the MFE lens 108A, and the MFE lens 108A and the variable aperture diaphragm 108B are integrally attached to a holding portion 108C. The holding portion 108C (the MFE 108A) is provided such that a position in the X′Y′ plane can be finely adjusted by a micro-motion mechanism 108D by a micro head, a piezo motor, or the like. In the present embodiment, the micro-motion mechanism 108D that finely moves the MFE lens 108A two-dimensionally in the X′Y′ plane functions as a second telecentric adjustment mechanism.

A plate type beam splitter 109A inclined about 45° with respect to the optical axis AXc is provided immediately behind the MFE lens 108A. The beam splitter 109A allows most of a light amount of the illumination light ILm from the MFE lens 108A to pass therethrough and reflects the remaining light amount (for example, about several %) toward a condensing lens 109B. Part of the illumination light ILm condensed by the condensing lens 109B is guided to a photoelectric element 109D by an optical fiber bundle 109C. The photoelectric element 109D is used as an integration sensor (integration monitor) that monitors the intensity of the illumination light ILm and measures an exposure amount of the image formation light flux projected to the substrate P.

As shown in FIG. 27, the illumination light ILm from the surface light source (the aggregate of the point light sources SPF) on the emission surface side of the MFE lens 108A transmit through the beam splitter 109A and enters the condenser lens system 110. The condenser lens system 110 is constituted of a front group lens system 110A and a rear group lens system 110B which are arranged to be spaced apart from each other, and a two-dimensional position in the X′Y′ plane can be finely adjusted by a micro-motion mechanism 110C by a micro head, a piezo motor, or the like. That is, eccentricity adjustment of the condenser lens system 110 can be performed by the micro-motion mechanism 110C. In the present embodiment, the micro-motion mechanism 110C that finely moves the condenser lens system 110 two-dimensionally in the X′Y′ plane functions as a third telecentric adjustment mechanism. All of the first telecentric adjustment mechanism, the second telecentric adjustment mechanism, and the third telecentric adjustment mechanism adjust a relative position relationship with respect to an eccentricity direction between the surface light source (or the surface light source restricted in a circular opening of the variable aperture diaphragm 108B) generated on the emission surface side of the MFE lens 108A and the condenser lens system 110.

The front focal point of the condenser lens system 110 is set to a position of the surface light source (the aggregate of the point light sources SPF) on the emission surface side of the MFE lens 108A, and the illumination light ILm that advances in a telecentric state from the condenser lens system 110 via the inclination mirror 112 illuminates the DMD 10 by Kohler illumination. As described in FIG. 28, when the surface light source by the aggregate of the large number of point light sources SPF formed on the emission surface side of the MFE lens 108A is laterally shifted by Δxs in the X′ direction as a whole, the principal ray (center ray) of the illumination light ILm irradiated to the DMD 10 becomes a state of being slightly inclined with respect to the optical axis AXb in FIG. 27. That is, by intentionally applying the telecentric error to the illumination light ILm by the first telecentric adjustment mechanism, the incidence angle θα of the illumination light ILm described in FIG. 6, FIG. 14, FIG. 18, and FIG. 22 can be slightly changed from an initial set angle (35.0°) in the X′Z plane.

Further, when the MFE lens 108A and the variable aperture diaphragm 108B are integrally displaced in the X′Y′ plane in the X′ direction by the micro-motion mechanism 108D as the second telecentric adjustment mechanism shown in FIG. 26, the circular opening (the circular region APh in FIG. 7) of the variable aperture diaphragm 108B is eccentric with respect to the optical axis AXc. Thereby, the surface light source formed in the circular opening (circular region APh) is also shifted in the X′ direction as a whole. Even in this case, the principal ray (center ray) of the illumination light ILm irradiated to the DMD 10 can be inclined with respect to the optical axis AXb in the X′Z plane in FIG. 27, that is, the incidence angle θα of the illumination light ILm to the DMD 10 can be changed from an initial set angle (35.0°) in the X′Z plane. The incidence angle θα can be similarly changed by using a configuration in which only the variable aperture diaphragm 108B is finely moved alone in the X′Y′ plane by the micro-motion mechanism 108D.

In this way, in order to relatively largely displace the MFE lens 108A and the variable aperture diaphragm 108B integrally, it is necessary to expand a light flux width (a diameter of an irradiation range) of the illumination light ILm irradiated from the condenser lens system 104′ to the MFE lens 108A. Further, it is also effective to provide a shift mechanism that laterally shifts the illumination light ILm irradiated to the MFE lens 108A in the X′Y′ plane in conjunction with an amount of the displacement. The shift mechanism can be constituted of a mechanism that inclines a direction of the emission end of the optical fiber bundle FBn, a mechanism that inclines a parallel planar plate (quartz plate) arranged in front of the MFE lens 108A, or the like.

Although both of the first telecentric adjustment mechanism (the drive unit 100C or the like) and the second telecentric adjustment mechanism (the micro-motion mechanism 108D or the like) can adjust the incidence angle θα of the illumination light ILm to the DMD 10, regarding the adjustment amount, the first telecentric adjustment mechanism can be used for fine adjustment, and the second telecentric adjustment mechanism can be used for rough adjustment. At the time of actual adjustment, whether to use both the first telecentric adjustment mechanism and the second telecentric adjustment mechanism or to use either one can be selected as appropriate depending on the form (the amount of the telecentric error Δθt or a correction amount) of the pattern to be projected and exposed.

Further, the micro-motion mechanism 110C as the third telecentric adjustment mechanism that causes the condenser lens system 110 to be eccentric in the X′Y′ plane has an effect similar to the case in which the position of the surface light source defined by the MFE lens 108A and the variable aperture diaphragm 108B is caused to be relatively eccentric by the second telecentric adjustment mechanism. However, when the condenser lens system 110 is eccentric in the X′ direction (or the Y′ direction), since an irradiation region of the illumination light ILm projected to the DMD 10 is also shifted laterally, the irradiation region is set to be larger than the size of the entire mirror surface of the DMD 10 while taking into account the lateral shift. The third telecentric adjustment mechanism by the micro-motion mechanism 110C can also be used for rough adjustment similarly to the second telecentric adjustment mechanism.

### (Other Telecentric Adjustment Mechanisms)

The adjustment (correction) of the telecentric error can be also achieved by laterally shifting a position in the X′Y′ plane of the emission end of each of the optical fiber bundles FBn (n=1 to 27) shown in FIG. 4 and FIG. 26 by a micro-motion mechanism. In this case, similarly to the above first telecentric adjustment mechanism (drive mechanism 100C or the like), the position of the surface light source (the aggregate of the large number of point light sources SPF) formed on the emission surface side of the MFE lens 108A can be finely adjusted.

The correction of the telecentric error can be also achieved by adjusting the original angle of the inclination mirror 112 shown in FIG. 4, FIG. 6, and FIG. 27 by a micro-motion mechanism such as a micro head or a piezo actuator and finely adjusting the incidence angle θα (for example, 35.0° by design) of the illumination light ILm to the DMD 10.

Alternatively, the inclination of the mirror surface (the neutral plane Pcc) of the DMD 10 may be finely adjusted by a micro-motion stage obtained by combining a parallel link mechanism of the mount portion 10M and a piezo element shown in FIG. 4 and FIG. 27, and the telecentric error may also be corrected. However, the adjustment of the angle of the inclination mirror 112 or the DMD 10 is used for rough adjustment since the reflected light is inclined at a double angle of the adjustment angle. Further, in angle adjustment of the DMD 10, an image surface inclination in which a conjugate plane (best focus plane) of the neutral plane Pcc projected onto the substrate P is inclined in a direction (the X′ direction or the X direction) of the scanning exposure with respect to the plane perpendicular to the optical axis AXa occurs.

When the direction of the image surface inclination is the direction of the scanning exposure, since the scanning exposure is performed at an average image surface position of the inclined image surface, a decrease in contrast of the exposed pattern image is minor. Accordingly, a function of inclining the DMD 10 in the scanning exposure direction (the X′ direction or the X direction) and correcting the telecentric error Δθt can also be utilized within a range in which a contrast decrease of the exposed pattern image is negligible. When the DMD 10 is inclined to such an extent that the contrast decrease is not negligible, some kind of image surface inclination correction systems (two wedge-shaped declination prisms or the like) is provided in the projection unit PLU. Alternatively, in order to correct the telecentric error Δθt, a mechanism that causes a specific lens group or a lens in the projection unit PLU to be eccentric with respect to the optical axis AXa may be provided. The inclination correction system (two wedge-shaped declination prisms or the like) may be provided on the illumination unit ILU.

### (Beam Supply Unit)

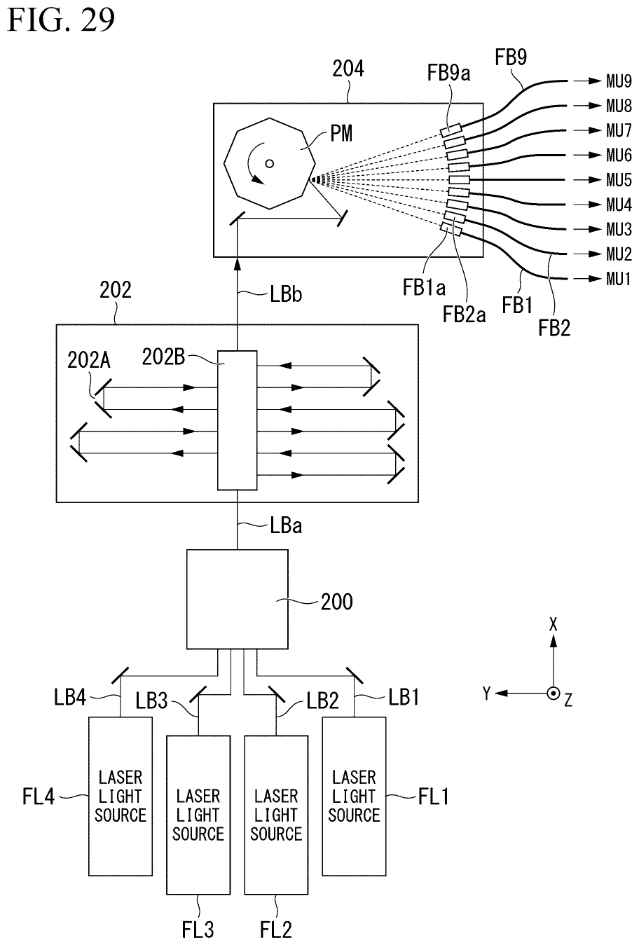

Next, an example of a beam supply unit that is attached to the exposure apparatus EX shown in FIG. 1 and supplies the illumination light ILm to each module MUn (n=1 to 27) is described with reference to FIG. 29. The orthogonal coordinate system XYZ in FIG. 29 is set to be the same as the coordinate system XYZ in FIG. 1 for convenience. In the beam supply unit of FIG. 29, beams LB1 to LB4 (having a beam diameter of 1 mm or less) from four laser light sources (fiber amplifier laser light sources) FL1 to FL4 are combined into a bundle of beams LBa by a beam combination unit 200. Each of the laser light sources FL1 to FL4 emits pulse light having a light emission duration time of several tens picoseconds at a peak wavelength (a spectral width is about 0.05 nm) which is different from each other by a predetermined wavelength with a basic peak wavelength of 343.333 nm.

Each of the four laser light sources FL1 to FL4 synchronously oscillates and emits pulse light at a predetermined timing in response to a clock pulse of a common clock signal (for example, a frequency of 200 kHz). The timings of the pulse oscillation of each of the four laser light sources FL1 to FL4 may be completely the same in synchronization with the clock signal, or sequential oscillation may be performed with a time difference (delay) of about the light emission duration time. By providing a time difference (delay) in the light emission timing in this way, it is also possible to reduce the coherence of the illumination light ILm irradiated to the DMD 10.

The beam LBa combined by the beam combination unit 200 is divided into a plurality of optical paths having a different beam optical path length and is circulated, and then enters the retarder unit 202 that performs combination. The retarder unit 202 generates a plurality of beams in which a beam wave front is temporally delayed and then emits a combined beam LBb in order to reduce the generation of a speckle due to the high coherency (temporal and spatial coherency) of the original beams LB1 to LB4. Therefore, the retarder unit 202 has a plurality of delay optical path sections 202A that are set to have a different optical path length from each other and a division combination section 202B that performs division of the incident beam LBa to each delay optical path section 202A and combination of a return beam from each delay optical path section 202A. A principle configuration of such a retarder unit 202 is disclosed in, for example, Japanese Unexamined Patent Application, First Publication No. 2007-227973.

The beam LBb in which the temporal coherency is reduced by the retarder unit 202 enters the beam switching unit 204. A rotation polygon mirror PM that rotates at a high speed is provided on the beam switching unit 204, and the beam LBb is deflected in a fan shape by each reflection surface of the rotation polygon mirror PM. At a position of a substantially equal distance from an incidence position of the beam LBb on the reflection surface of the rotation polygon mirror PM, incidence ends FB1a to FB9a of the nine optical fiber bundles FB1 to FB9 are aligned in an arc shape at a constant angle in a direction in which the beam LBb is incident.

Each of the optical fiber bundles FB1 to FB9 is a single optical fiber wire or a bundle of a plurality of optical fiber wires as described in FIG. 8. Although not shown in FIG. 29, an f-θ lens (non-telecentric) that covers the deflection range having a fan shape of the beam LBb is provided immediately behind the rotation polygon mirror PM, and a small lens that condenses the beam LBb from the rotation polygon mirror PM to a small spot is provided in front of each of the incidence ends FB1a to FB9a of the optical fiber bundles FB1 to FB9. Further, the beam LBb is performing pulse oscillation in response to a clock signal common to each of the laser light sources FL1 to FL4, and a synchronous control between a cycle of the clock signal and a rotation speed (angular phase) of the rotation polygon mirror PM is performed such that the beam LBb enters the incidence ends FB1a to FB9a of the optical fiber bundles FB1 to FB9 in turns at each one pulse light.

In the present embodiment, two other sets of beam supply units having the same configuration as that of FIG. 29 are provided, one of the two sets switches and supplies the beam LBb to the optical fiber bundles FB10 to FB18 of the modules MU10 to MU18, and the other of the two sets switches and supplies the beam LBb to the optical fiber bundles FB19 to FB27 of the modules MU19 to MU27. Further, in the beam supply unit of FIG. 29, four laser light sources FL1 to FL4 are used; however, three or less laser light sources may be used, or more laser light sources may be provided and five or more beams may be combined by the beam combination unit 200.

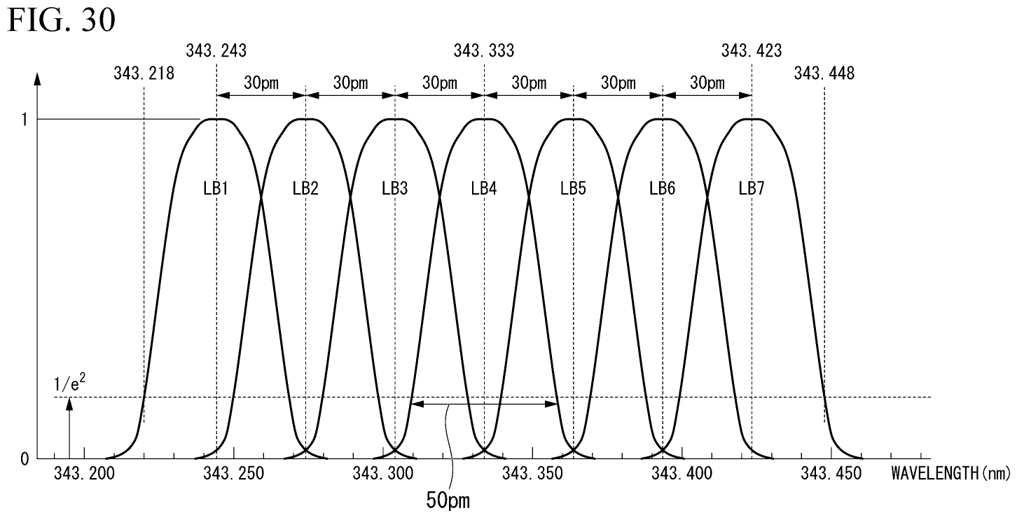

Further, as described above, the peak wavelengths of the beams LBn (n=1, 2, 3 . . . ) from the plurality of laser light sources FLn (n=1, 2, 3 . . . ) may be made different from each other by a certain wavelength for speckle reduction. FIG. 30 is a view schematically showing, as an example, a wavelength distribution of the beam LBb after the beams LB1 to LB7 from seven laser light sources FL1 to FL7 are combined by the beam combination unit 200. In FIG. 30, the horizontal axis represents wavelength (nm), and the vertical axis represents a value obtained by normalizing the peak intensity of the beams LB1 to LB7 to 1. The seven laser light sources FL1 to FL7 have substantially the same configuration, but the wavelengths of seed lights thereof are differentiated from each other by a certain value, and the peak wavelengths (center wavelengths) of the beams LB1 to LB7 to be finally output are set to be shifted by about 30 pm (0.03 nm).

Since this type of fiber amplifier laser light source in the ultraviolet wavelength region uses a wavelength conversion element, a spectral width of the oscillation wavelength is also narrow, and for example, as shown in FIG. 30, the spectral width is about 50 pm (0.05 nm) at an intensity of 1/e2 of the peak intensity. In the case of FIG. 30, the center wavelength of the beam LB4 from the laser light source FL4 is set to 343.333 nm, the center wavelength of the beam LB3 from the laser light source FL3 is set to 343.303 nm, the center wavelength of the beam LB2 from the laser light source FL2 is set to 343.273 nm, and the center wavelength of the beam LB1 from the laser light source FL1 is set to 343.243 nm. Further, the center wavelength of the beam LB5 from the laser light source FL5 is set to 343.363 nm, the center wavelength of the beam LB6 from the laser light source FL6 is set to 343.393 nm, and the center wavelength of the beam LB7 from the laser light source FL7 is set to 343.423 nm.

Accordingly, the wavelength spectrum width of the beam LBb obtained by combining the beams LB1 to LB7 becomes about 180 pm (0.18 nm) when seen by the interval of the peak wavelength, and becomes about 230 pm (0.23 nm) when seen by the interval (343.218 nm to 343.448 nm) at the intensity of 1/e2. In this way, when the speckle is reduced by widening the spectral width of the beam LBb, that is, the illumination light ILm of the DMD 10, a corresponding telecentric error Δθt also occurs, but the spectral width is set such that the influence thereof is within an acceptable range. In the example of the spectral width described above, the peak wavelength of 343.243 nm and the peak wavelength of 343.423 nm are included in the illumination light ILm, and the case as shown in FIG. 17 and FIG. 18 described above in which a large telecentric error Δθt may occur is preliminarily calculated by Equation (2) described in FIG. 19.

Even in the preliminary calculation, when the incidence angle θα of the illumination light ILm is 35.0°, the inclination angle θd of the micro mirror Msa in the ON state is 17.5°, and the projection magnification Mp is ⅙, the telecentric error on the object surface side (DMD 10 side) of the ninth order diffraction light Id9 that occurs when the peak wavelength of the illumination light ILm is 343.243 nm becomes about 0.086° (image surface side telecentric error Δθt≈0.517°). Similarly, the telecentric error on the object surface side (DMD 10 side) of the ninth order diffraction light Id9 that occurs when the peak wavelength of the illumination light ILm is 343.423 nm becomes about 0.069° (image surface side telecentric error Δθt≈0.414°). Accordingly, when the spectral width of the illumination light ILm is between the peak wavelengths of 343.243 nm and 343.423 nm, the telecentric error Δθt on the image surface side that may occur by the spread of the wavelength spectral width is reduced, for example, within the acceptable range±2° (within a more desirable acceptable range±1°) described in FIG. 25.

When the illumination light ILm is caused to have a spectral width (to be broadband) for speckle reduction, limits of a short wavelength value and a long wavelength value may be set in consideration of the acceptable range (for example, within ±2°) of the telecentric error Δθt on the image surface side that occurs due to the difference in wavelength. Accordingly, the number of laser light sources FLn is not limited to seven, and the degree of shift of the center wavelength of the beam LBn from each laser light source is not limited to 30 pm.

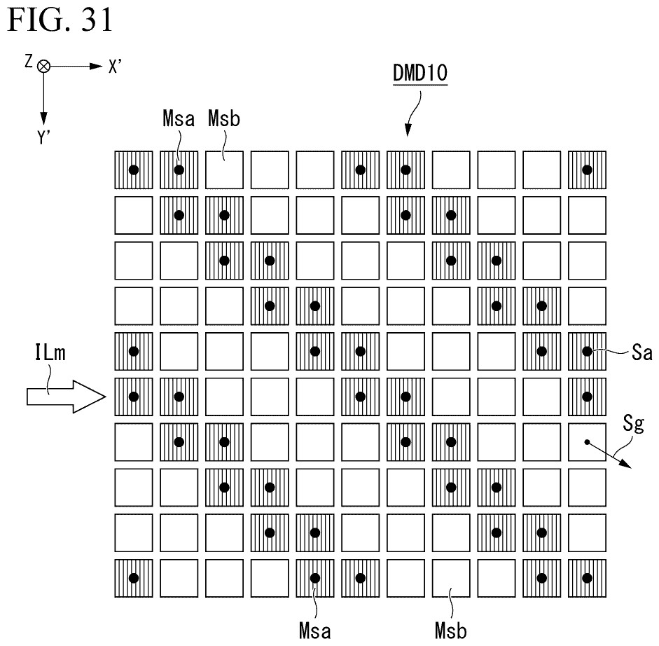

FIG. 31 is a view showing a state of part of the mirror surface of the DMD 10 at the time of exposure of a line-and-space pattern obliquely inclined at 45° on the substrate P. In FIG. 31, similarly to FIG. 13, FIG. 17, and FIG. 21, the reflected light Sa from each of the micro mirrors Msa in the ON state is reflected in the −Z direction, and the reflected light Sg from each of the micro mirrors Msb in the OFF state is reflected in an oblique direction in the X′Y′ plane. The micro mirrors Msa in the ON state are arranged such that the micro mirrors that are adjacent to each other in the oblique 45° direction are aligned in a row, and the row forms a diffraction grating. Therefore, a telecentric error Δθt occurs at the reflected light (image formation light flux) Sa′ generated from all of the micro mirrors Msa in the ON state due to the influence of the diffraction phenomenon.

In the case of the line-and-space pattern shown in FIG. 21, the telecentric error Δθt occurs only in the X′ direction, but in the case of the line-and-space pattern shown in FIG. 31, the telecentric error Δθt occurs in the X′ direction and the Y′ direction. Accordingly, even in the case of the line-and-space pattern inclined at an oblique angle of 45° or 30° to 60° as shown in FIG. 31, when the telecentric error Δθt that may occur exceeds an acceptable range in either the X′ direction or the Y′ direction, the telecentric error can be corrected by some adjustment mechanisms of the telecentric error described in FIG. 26 and FIG. 27.

### (Control System of Telecentric Error Correction)

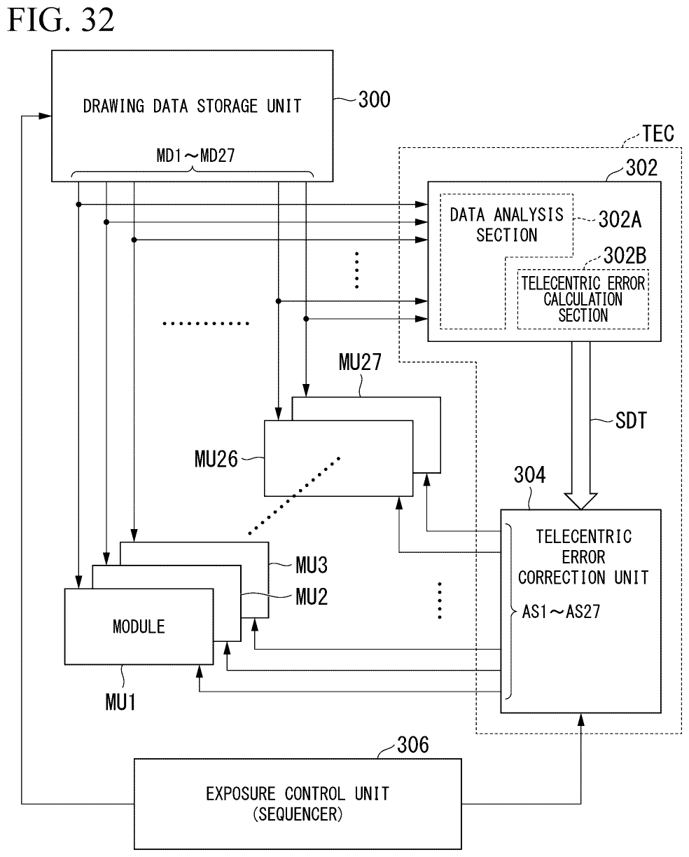

FIG. 32 is a block diagram showing a schematic example of a portion particularly related to an adjustment control of the telecentric error in an exposure control device that is attached to the exposure apparatus EX of the present embodiment. An adjustment control system TEC of the telecentric error shown in FIG. 32 is applied to the case where all or at least one of the first telecentric adjustment mechanism (the drive unit 100C or the like), the second telecentric adjustment mechanism (the micro-motion mechanism 108D or the like), and the third telecentric adjustment mechanism (the micro-motion mechanism 110C or the like) described in FIG. 26 and FIG. 27 can be electrically driven by an actuator such as a motor.

In FIG. 32, a drawing data storage unit (hereinafter, also simply referred to as a storage unit) 300 that transmits drawing data MD1 to MD27 for pattern exposure is provided on the DMD 10 of each of the 27 modules MU1 to MU27 shown in FIG. 2. Each of the drawing data MD1 to MD27 is sent to an angle change specifying unit (hereinafter, also referred to as a telecentric error specifying unit) 302 before the exposure operation.

The telecentric error specifying unit 302 includes: a data analysis section 302A that analyzes the form (isolated, line-and-space, pad, or the like) of a pattern exposed in each of the projection regions IA1 to IA27 (refer to FIG. 2 and FIG. 3) on the substrate P and a position on the substrate P based on each of the drawing data MD1 to MD27; and a telecentric error calculation section 302B that calculates information SDT relating to the telecentric error Δθt in accordance with the form of the analyzed pattern.

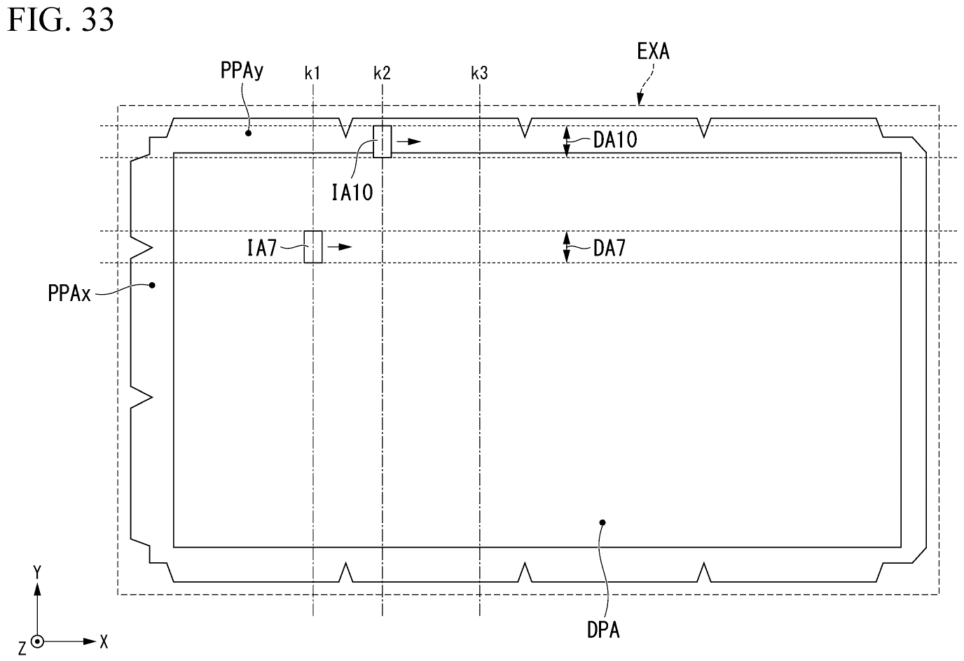

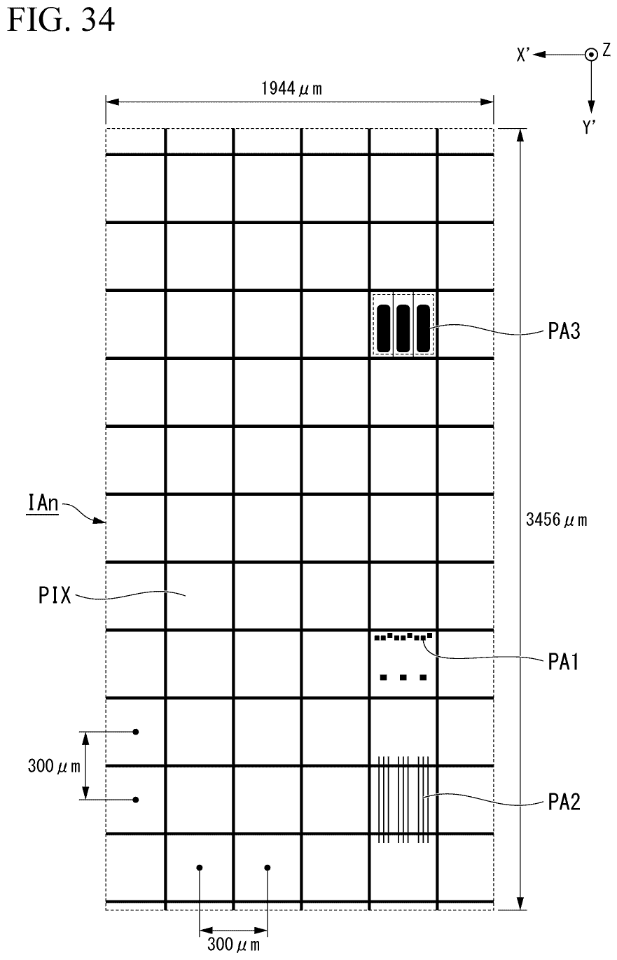

Here, an example of a main function of the angle change specifying unit (telecentric error specifying unit) 302 is described with reference to FIG. 33 and FIG. 34. FIG. 33 shows an example of an arrangement of a display region DPA for a display panel and peripheral regions PPAx and PPAy exposed on the substrate P by the exposure apparatus EX shown in FIG. 1 and FIG. 2, and a maximum exposure region EXA on an outer edge represents a range that can be exposed by the modules MU1 to MU27 by one scanning exposure of the exposure apparatus EX. The display region DPA is constituted of a large number of pixels aligned at a constant pitch in the X direction and the Y direction and has an aspect ratio of 16:9, 2:1, or the like as a whole. Here, the longitudinal direction of the display region DPA is defined as the X direction.

As an example, regions DA7 and DA10 to be scanned and exposed by the projection regions IA7 and IA10 of the modules MU7 and MU10 shown in FIG. 2 is described. As shown in FIG. 3, the actual projection regions IA7 and IA10 are inclined by an angle θk with respect to the XY coordinate system. Although the peripheral region PPAx having a narrow width in the X direction is included at an end portion in the −X direction (or +X direction) in the region DA7, the region DA7 is almost occupied by the display region DPA extending in the X direction (scanning exposure direction). In the display region DPA, as an example, pixels of about 200 μm to 300 μm square are aligned in the XY direction, and the pattern exposed in the pixel may be an isolated pattern, may be a line-and-space pattern, or may be a large land-like pattern at each step in a manufacturing process.

FIG. 33 is a view showing an example of an arrangement state of a pixel PIX in the display region DPA appearing in one projection region IAn (n=1 to 27). As described above as a numerical example, the arrangement pitch Pd of the micro mirrors Ms of the DMD 10 is 5.4 μm, 2160 micro mirrors Ms are aligned in the X′ direction, and 3840 micro mirrors Ms are aligned in the Y′ direction. In this case, the aspect ratio is 16:9 (=3840:2160), an actual size in the X′ direction of the mirror surface of the DMD 10 is 11.664 mm, and an actual size in the Y′ direction is 20.736 mm. When the projection magnification Mp by the projection unit PLU is ⅙, the size in the X′ direction of the projection region IAn on the substrate P is 1944 μm, and the size in the Y′ direction is 3456 μm. Further, a projection image of a single micro mirror Msa in the ON state has a size of about 0.9 μm square on the substrate P.

When the pitch of the pixels PIX in the X′ direction and the Y′ direction on the substrate P is 300 μm, about 6 pixels PIX appear in the X′ direction and about 11 pixels PIX appear in the Y′ direction in the projection region IAn. The pattern exposed in the pixel PIX may be an isolated pattern PA1, a line-and-space pattern PA2, or a land-like pattern PA3 at each layer. In FIG. 34, although three patterns PA1, PA2, and PA3 are collectively shown for the purpose of explanation, the pattern PA1 appears in all the pixels PIX included in the projection region IAn when the pattern PA1 is exposed, the pattern PA2 appears in all the pixels PIX included in the projection region IAn when the pattern PA2 is exposed, and the pattern PA3 appears in all the pixels PIX included in the projection region IAn when the pattern PA3 is exposed.

In FIG. 34, for ease of explanation, the vertical and horizontal arrangement of the pixels PIX in the projection region IAn coincides with the X′Y′ coordinate, but actually, as described in FIG. 3 and FIG. 5, the vertical and horizontal arrangement of the pixels PIX is set so as to be inclined by the angle θk with respect to the X′Y′ coordinate and appear to coincide with the XY coordinate system which is a movement coordinate of the substrate P.

As shown in FIG. 34, the exposure of the isolated pattern PA1 to all the pixels PIX in the display region DPA is performed, for example, in a step of forming a semiconductor layer and an electrode layer of a TFT, a via hole, or the like.

In such a case, as described in FIG. 13 to FIG. 16, a telecentric error Δθt of an acceptable range or more does not occur. That is, when using the illumination unit ILU and the projection unit PLU on which a telecentric adjustment is performed with respect to a projection image of the isolated pattern projected by the single micro mirror Msa in the ON state, the telecentric error Δθt of the acceptable range or more does not occur. However, even in the case of the isolated pattern, when the isolated pattern is exposed on the substrate P with a pixel size of about several tens μm as in a display panel for a smartphone, about several tens of micro mirrors Msa in the ON state are densely arranged in the X′ direction and the Y′ direction on the DMD 10. Therefore, even in the case of the isolated pattern, a telecentric error Δθt may occur depending on the size (pattern size).

Further, in the peripheral region PPAx in the region DA7 shown in FIG. 33, wirings extending mainly in the X direction (X′ direction) are formed in a lattice shape arranged at a constant interval in the Y direction (Y′ direction). Accordingly, the influence of the diffraction phenomenon with respect to the X′ direction is small, and even if the telecentric error Δθt occurs, the telecentric error is within the acceptable range.

Further, as shown in FIG. 34, the exposure of the line-and-space pattern PA2 to all the pixels PIX in the display region DPA is performed, for example, in a step of forming a wiring that connects electrode layers of a TFT, an electric power supply line, an earth line, a signal line, a selection line, or the like. In such a case, as described in FIG. 21 to FIG. 23, depending on the pitch or the line width of the line and space, a telecentric error Δθt of the acceptable range or more may occur. Further, as shown in FIG. 34, the exposure of the land-like pattern PA3 to all the pixels PIX in the display region DPA is performed, for example, in a step of forming a bank of a light emission portion of the pixel PIX, an electrode layer, or the like. The land-like pattern PA3 often has an area of half or more (close to 90% in some cases) of an area (about 300 μm square) of the pixel PIX, and in such a case, as described in FIG. 18 to FIG. 20, there is a high possibility that a telecentric error Δθt of the acceptable range or more occurs.

Further, in the peripheral region PPAx in the region DA7 shown in FIG. 33, wirings extending mainly in the X direction (X′ direction) are formed in a lattice shape arranged at a constant interval in the Y direction (Y′ direction). Accordingly, the influence of the diffraction phenomenon with respect to the X′ direction is small, and even if the telecentric error Δθt occurs, the telecentric error is within the acceptable range. However, when the line-and-space wiring inclined with respect to both the X′ direction and the Y′ direction as described in FIG. 31 is formed in the peripheral region PPAx, a telecentric error Δθt may occur.

As described above, the data analysis section 302A of the angle change specifying unit (telecentric error specifying unit) 302 of FIG. 32 analyzes the drawing data MD7 of the entire region DA7 transmitted to the module MU7, and generates position information of each partial region obtained by dividing the region DA7 into a plurality of partial regions with respect to the X direction and form information indicating whether the form of the pattern appearing in the partial region is the isolated pattern PA1, the line-and-space pattern PA2, or the land-like pattern PA3 as shown in FIG. 34. The telecentric error calculation section 302B of the angle change specifying unit (telecentric error specifying unit) 302 of FIG. 32 calculates a telecentric error Δθt that occurs in accordance with a line width, a pitch, or the like of the line-and-space pattern when the form information of the pattern appearing in the partial region is the line-and-space pattern PA2, and calculates a telecentric error Δθt that occurs in accordance with a size or the like of the land-like pattern when the form information of the pattern appearing in the partial region is the land-like pattern PA3.

With respect to the calculation the telecentric error Δθt by the telecentric error calculation section 302B, as a simple calculation, a ratio of an area of the substrate P irradiated with the exposure light in each of a plurality of partial regions obtained by dividing the region DA7 in the X direction to the area of the entire partial region may be obtained, and the telecentric error Δθt may be estimated in accordance with the ratio. The ratio can be an average density of the micro mirrors Msa that becomes the ON state when the partial region is exposed among all the micro mirrors Ms of the DMD 10. Accordingly, when the density is a predetermined value, that is, for example, 50% or more, the telecentric error Δθt may be estimated in accordance with the density.

The operation described above is performed similarly with respect to the region DA10 shown in FIG. 33, and the angle change specifying unit (telecentric error specifying unit) 302 of FIG. 32 calculates a telecentric error Δθt that may occur in each partial region at the time of pattern exposure by the projection region IA10 of the module MU10 based on the drawing data MD10 from the storage unit 300. The region DA10 shown in FIG. 33 includes many patterns of the peripheral region PPAy. Since a line-and-space pattern in which wirings that mainly extend in the Y direction (Y′ direction) are aligned at a constant pitch in the X direction (X′ direction) is included in the peripheral region PPAy, there is a possibility that a telecentric error Δθt of the acceptable range or more occurs.

The angle change specifying unit (telecentric error specifying unit) 302 of FIG. 32 generates information SDT (also including position information in a scanning exposure direction) relating to the telecentric error Δθt calculated (estimated) as described above for each of the modules MU1 to MU27 and transmits the information to a telecentric error correction unit 304. The telecentric error correction unit 304 selects at least one mechanism that is adequate for an adjustment amount or an adjustment accuracy from the first telecentric adjustment mechanism (the drive unit 100C or the like), the second telecentric adjustment mechanism (the micro-motion mechanism 108D or the like), and the third telecentric adjustment mechanism (the micro-motion mechanism 110C or the like) described in FIG. 26 and FIG. 27 based on the information SDT relating to the telecentric error Δθt with respect to each of the modules MU1 to MU27, and outputs adjustment command information AS1 to AS27 for each of the modules MU1 to MU27.

The adjustment command information AS1 to AS27 from the telecentric error correction unit 304 is sent to the corresponding telecentric adjustment mechanism when each of the modules MU1 to MU27 is actually performing the exposure operation, and the correction of the telecentric error Δθt is performed in real time. An exposure control unit (sequencer) 306 controls the transmission of the drawing data MD1 to MD27 from the storage unit 300 to the modules MU1 to MU27 and the transmission of the adjustment command information AS1 to AS27 from the telecentric error correction unit 304 in synchronization with the scanning exposure (movement position) of the substrate P.

According to the present embodiment as described above, in the pattern exposure apparatus that includes: the DMD 10 as the spatial light modulation element having a large number of micro mirrors Ms selectively driven based on drawing data MDn (n=1 to 27); the illumination unit ILU that irradiates the DMD 10 with illumination light ILm at a predetermined incidence angle θα; and the projection unit PLU on which reflected light Sa (image formation light flux) from a selected micro mirror Msa in an ON state of the DMD 10 is incident and which projects the reflected light Sa onto the substrate P, and projects and exposes a pattern corresponding to the drawing data MDn onto the substrate P, by providing: the angle change specifying unit (telecentric error specifying unit) 302 that specifies (estimates) in advance a telecentric error (telecentric error) Δθt which occurs in the reflected light Sa projected from the projection unit PLU onto the substrate P at the time of the projection exposure of the pattern in accordance with the distribution state (density and periodicity) of the micro mirrors Msa in the ON state of the DMD 10; and the adjustment mechanism (the drive unit 100C, the micro-motion mechanism 108D, the micro-motion mechanism 110C, or the like) that adjusts the position of part of the optical members (the mirror 100, the aperture diaphragm 108B, the condenser lens system 110, and the like) in the illumination unit ILU or the projection unit PLU in accordance with the telecentric error Δθt specified in advance, the telecentric error Δθt of the reflected light (image formation light flux) Sa′ generated by the diffraction action when the large number of micro mirrors Ms of the DMD 10 become the ON state can be constantly reduced within an acceptable range.

### First Modification Example

As described above, depending on the distribution state of the micro mirrors Msa in the ON state of the DMD 10, a telecentric error occurs in the reflected light (image formation light flux) Sa′ reflected by the DMD 10, and since the projection unit PLU is a reduction projection system, the telecentric error Δθt on the image surface side is enlarged by an inverse multiple of the projection magnification Mp. Since the magnitude of the telecentric error Δθt that actually occurs changes depending on the form of the pattern generated by the DMD 10, the degree of the telecentric error Δθt to be generated may be measured in advance for each form of several patterns.

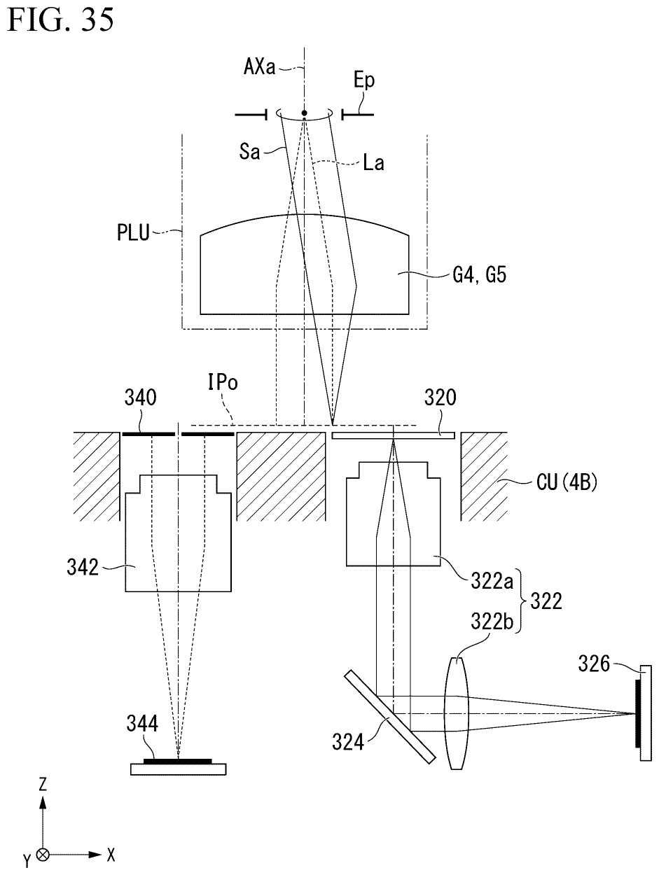

FIG. 35 is a view showing a schematic configuration of an optical measurement unit provided on the calibration reference portion CU that is attached to the end portion on the substrate holder 4B of the exposure apparatus EX shown in FIG. 1. In FIG. 35, it is assumed that the reflected light (image formation light flux) Sa from the DMD 10 is imaged on the best focus plane (best image formation plane) IPo through the lens groups G4 and G5 on the image surface side of the projection unit PLU, and the principal ray La of the reflected light Sa is parallel to the optical axis AXa. A first optical measurement unit is constituted of a quartz plate 320 that is attached to an upper surface of the calibration reference portion CU, an imaging system 322 (an objective lens 322a and a lens group 322b) that enlarges and images a pattern image by the DMD 10 projected from the projection unit PLU through the quartz plate 320, a reflection mirror 324, and an imaging element 326 by a CCD or a CMOS that images the enlarged pattern image. A surface of the quartz plate 320 and an imaging surface of the imaging element 326 are in a conjugate relation.

A second optical measurement unit is constituted of a pinhole plate 340 that is attached to the upper surface of the calibration reference portion CU, an objective lens 342 on which reflected light (image formation light flux) Sa from the DMD 10 projected from the projection unit PLU is incident through the pinhole plate 340 and which forms an image (an intensity distribution of the image formation light flux and the light source image in the pupil Ep) of the pupil Ep of the projection unit PLU, and an imaging element 344 by a CCD or a CMOS that captures the image of the pupil Ep. That is, an imaging surface of the imaging element 344 of the second optical measurement unit is in a conjugate relation with the position of the pupil Ep of the projection unit PLU.

Since the substrate holder 4B (calibration reference portion CU) can be moved two dimensionally in the XY plane by the XY stage 4A, the quartz plate 320 of the first optical measurement unit or the pinhole plate 340 of the second optical measurement unit is arranged directly below the projection unit PLU of any of the modules MU1 to MU27 to be measured, and the reflected light Sa corresponding to various test patterns for measurement is generated by the DMD 10. In the measurement of the telecentric error by the first optical measurement unit, the substrate holder 4B (calibration reference portion CU), the entire projection unit PLU, or the lens groups G4 and G5 are moved upward and downward such that the surface of the quartz plate 320 is defocused by a certain amount in each of the +Z direction and the −Z direction with respect to the best focus plane IPo.

Then, the telecentric error Δθt can be measured based on a lateral shift amount of the image of the test pattern captured by the imaging element 326 at each of the time of defocusing in the +Z direction and the time of defocusing in the −Z direction and a defocus amount (fine movement range of ±Z). The imaging element 326 of the first optical measurement unit images the mirror surface of the DMD 10 through the projection unit PLU and therefore can also be used for confirming a micro mirror Ms in which an operation failure occurs among the large number of micro mirrors Ms of the DMD 10. Further, it is also possible to generate some typical test patterns (a pattern belonging to any of an isolated pattern, a line-and-space pattern, and a land-like pattern) with which the telecentric error Δθt may occur by the DMD 10, and to measure the asymmetry property (distribution as shown in FIG. 24) of the intensity distribution of the projection image of the test pattern by the imaging element 326 of the first optical measurement unit.

### Second Modification Example

Further, in the measurement of the telecentric error by the second optical measurement unit, the eccentricity or the like of the intensity distribution in the pupil Ep of the image formation light flux (Sa, Sa′) formed on the pupil Ep of the projection unit PLU at the time of projection of the test pattern is measured by the imaging element 344. In this case, the telecentric error Δθt can be measured based on an eccentricity amount of the intensity distribution in the pupil Ep, a focal distance on the image surface side of the projection unit PLU, and the like. Further, as described in FIG. 13 to FIG. 15, only a specific single micro mirror Ms among the large number of micro mirrors Ms of the DMD 10 is set to be in the ON state, and the position relationship between the optical axis AXa and the center of gravity of the intensity distribution formed on the pupil Ep by the imaging element 344 of the second optical measurement unit is measured. When deviation in the position relationship occurs, it is determined that the inclination angle θd of the specific micro mirror Msa in the ON state has an error from a standard value (for example, 17.5°).

Although a measurement time is required, it is also possible to obtain an error (drive error) of the inclination angle θd of each micro mirror Ms by setting all the micro mirrors Ms of the DMD 10 to be in the ON state one by one in this way and performing the measurement by the imaging element 344. Although the error of the inclination angle θd of each micro mirror Ms cannot be adjusted or corrected due to the characteristic inherent to the DMD 10, when the micro mirrors Ms having a large error of the inclination angle θd are averagely distributed, a telecentric error due to the error of the inclination angle θd may also occur.

For example, in the case where a nominal value (standard value) of the inclination angle θd of the micro mirror Ms of the DMD 10 is 17.5° and the drive error of the angle is ±0.5°, when the incidence angle θα of the illumination light ILm to the DMD 10 is 35.0°, the telecentric error on the object surface side (DMD 10 side) of the projection unit PLU is ±1° at the maximum. Accordingly, when the projection magnification Mp of the projection unit PLU is ⅙, the telecentric error Δθt on the image surface side caused by the drive error of the micro mirror Ms is ±6° at the maximum. According to the present modification example, since the telecentric error Δθt caused by the drive error of the inclination angle θd of the micro mirror Ms inherent to the DMD 10 can also be measured, the adjustment (calibration) can be performed such that the telecentric error Δθt is corrected before an actual pattern is exposed.

### Third Modification Example

As described in the first modification example, before exposing the actual pattern on the substrate P, the telecentric error Δθt that may occur in some typical pattern forms (in particular, the line-and-space pattern and a pad pattern) included in the actual pattern is measured in advance by using the first optical measurement unit (imaging element 326) or the second optical system measurement unit (imaging element 344). The relationship between the measured telecentric error Δθt and the pattern form can also be learned (stored) as a database, for example, by the exposure control unit 306 shown in FIG. 32.

Commonly, the exposure apparatus EX of this type receives information of various exposure conditions, a set condition of the drive unit, an operation parameter, an operation sequence, or the like relating to an actual exposure pattern of each layer of an electronic device (a display panel or the like) formed on the substrate P as recipe information and performs a series of exposure operations. In a maskless method in which each of the plurality of modules MU1 to MU27 for drawing forms a pattern image that is dynamically changed by the DMD 10 as in the exposure apparatus EX shown in FIG. 1 to FIG. 6, each of drawing data MD1 to MD27 (refer to FIG. 32) that controls an operation of the large number of micro mirrors Ms of each DMD 10 may also be included as one of the recipe information. Such recipe information is often stored and managed by a main control unit (computer) that overall controls the entire exposure apparatus EX.

Therefore, the data analysis section 302A and the telecentric error calculation section 302B of the adjustment control system TEC described in FIG. 32 compare each of the drawing data MD1 to MD27 with the pattern form in the database learned (stored) in advance and newly generate, as one of the recipe information (corresponding to information STD in FIG. 32), information (correction position information) relating to the scanning exposure position of a portion (for example, a partial region in the X direction in the regions DA7 and DA10 of FIG. 33) where the telecentric error Δθt is equal to or more than the acceptable range and information (information relating to an inclination direction, an inclination amount, or a correction amount of inclination) relating to the telecentric error Δθt, that is, the angle change of the image formation light flux (reflected light Sa′ including diffraction light) from the telecentric state. The information (correction position information) relating to the scanning exposure position is not always necessary if there is a not change in the pattern form in the entire region in each region DAn (n=1 to 27) on the substrate P exposed by each of the projection regions IAn (n=1 to 27).

Further, an important pattern portion having a high specification value of line width accuracy, position accuracy, or superposition accuracy is extracted from drawing data relating to an actual exposure pattern included in the recipe information, and the extracted pattern portion is registered in the recipe information in advance as a test pattern for telecentric error measurement. Before an actual exposure is started by switching to the recipe information, the image of the registered test pattern may be projected by the DMD 10, the telecentric error Δθt may be measured by using the first optical measurement unit (imaging element 326) or the second optical system measurement unit (imaging element 344), and adjustment (correction) information may be generated.

As described above, according to the present modification example, in the pattern exposure apparatus including: the illumination unit ILU that irradiates, with the illumination light ILm, the DMD 10 as the spatial light modulation element having a large number of micro mirrors Ms switched between the ON state and the OFF state based on the drawing data MDn; and the projection unit PLU that causes reflected light from the micro mirrors Msa which become the ON state of the DMD 10 to be incident as the image formation light flux (Sa′) and projects the image of the pattern corresponding to the drawing data MDn onto the substrate P, by providing: the control unit that stores information relating to the angle change (telecentric error Δθt) of the image formation light flux (Sa′) which occurs in accordance with the distribution density of the micro mirrors Msa in the ON state of the DMD 10 as recipe information together with the drawing data MDn; and the adjustment mechanism (the drive unit 100C, the micro-motion mechanism 108D, the micro-motion mechanism 110C, or the like) that adjusts the position or the angle of at least one optical member (the mirrors 100, 112, the aperture diaphragm 108B, the condenser lens system 110, the DMD 10, or the like) in the illumination unit ILU (or the projection unit PLU) in accordance with the information on the angle change (Δθt) when the pattern is exposed on the substrate P by driving the DMD 10 based on the recipe information, the angle change (telecentric error) of the image formation light flux (Sa′) generated by the diffraction action when the large number of micro mirrors Ms of the DMD 10 become the ON state can be reduced within an acceptable range.

### Fourth Modification Example

As described in the third modification example, when the image of the test pattern corresponding to the important pattern portion included in the recipe information is projected by the DMD 10 and is measured by the first optical measurement unit (imaging element 326), the first optical measurement unit (imaging element 326) measures the intensity distribution of the projected image of the test pattern. Therefore, as shown in FIG. 24, an image analysis is performed on the degree of degradation (asymmetry property) of the symmetry property of the image, for example, by the exposure control unit 306 shown in FIG. 32 or the like. Then, the adjustment mechanism (the drive unit 100C, the micro-motion mechanism 108D, the micro-motion mechanism 110C, or the like) of the telecentric error in the illumination unit ILU or an eccentric micro-motion mechanism of the lens group or the lens element in the projection unit PLU may be controlled such that the asymmetry property of the image is reduced.

In this case, for example, by a learning in which adjustment of a predetermined amount by the adjustment mechanism of the telecentric error or the eccentric micro-motion mechanism and measurement of the degree of the asymmetry property of the image of the test pattern by the first optical measurement unit (imaging element 326) are repeated a plurality of times, it is possible to reduce the asymmetry property of the image. Accordingly, if the degree of the asymmetry property of the projected pattern image and an adjustment amount of the adjustment mechanism of the telecentric error and the eccentric micro-motion mechanism for reducing the degree of the asymmetry property are associated with each other and a database is formed, it is not necessary to quantitatively obtain the telecentric error Δθt or to utilize the information.

As described above, according to the present modification example, in the pattern exposure apparatus including: the illumination unit ILU that irradiates, with the illumination light ILm, the DMD 10 as the spatial light modulation element having a large number of micro mirrors Ms switched between the ON state and the OFF state based on the drawing data MDn; and the projection unit PLU that causes reflected light from the micro mirrors Msa which become the ON state of the DMD 10 to be incident as the image formation light flux (Sa′) and projects the image of the pattern corresponding to the drawing data MDn onto the substrate P, by providing: the measurement unit (imaging element 326) that measures the degree of the asymmetry property of the image of the pattern generated in response to the telecentric error of the image formation light flux (Sa′) which occurs in accordance with the distribution density of the micro mirrors Msa in the ON state of the DMD 10; and the adjustment mechanism (the drive unit 100C, the micro-motion mechanism 108D, the micro-motion mechanism 110C, or the like) that adjusts the position or the angle of at least one optical member (the mirrors 100, 112, the aperture diaphragm 108B, the condenser lens system 110, the DMD 10, or the like) in the illumination unit ILU (or the projection unit PLU) such that the measured asymmetry property is reduced when the pattern is exposed onto the substrate P by driving the DMD 10 based on the recipe information, the asymmetry property of the pattern image that occurs due to the telecentric error of the image formation light flux (Sa′) generated by the diffraction action when the large number of micro mirrors Ms of the DMD 10 become the ON state can be reduced.

In the descriptions of the first embodiment and the modification examples described above, the isolated pattern as a form of the pattern is not necessarily limited only to the case in which one or a row of all the micro mirrors Ms of the DMD 10 becomes the micro mirrors Msa in the ON state. For example, even the case where two, three (1×3), four (2×2), six (2×3), eight (2×4), or nine (3×3) micro mirrors Msa in the ON state are densely aligned, and, for example, 10 or more micro mirrors Ms around the densely aligned micro mirrors Msa in the ON state become the micro mirrors Msb in the OFF state in the X′ direction and the Y′ direction can also be regarded as the isolated pattern. On the contrary, the case where two, three (1×3), four (2×2), six (2×3), eight (2×4), or nine (3×3) micro mirrors Msb in the OFF state are densely aligned, and, for example, several or more (corresponding to a size several times or more than the isolated pattern) in the X′ direction and the Y′ direction of the micro mirrors Ms around the densely aligned micro mirrors Msb in the OFF state densely become the micro mirrors Msa in the ON state can also be regarded as the land-like pattern.

Further, the line-and-space pattern as a form of the pattern is also not necessarily limited to the form as shown in FIG. 21 in which the micro mirrors Msa in the ON state of one row and the micro mirrors Msb in the OFF state of one row are alternately aligned repeatedly. For example, the form may be a form in which the micro mirrors Msa in the ON state of two rows and the micro mirrors Msb in the OFF state of two rows are alternately aligned repeatedly, a form in which the micro mirrors Msa in the ON state of three rows and the micro mirrors Msb in the OFF state of three rows are alternately aligned repeatedly, or a form in which the micro mirrors Msa in the ON state of two rows and the micro mirrors Msb in the OFF state of four rows are alternately aligned repeatedly. Even in the case of any pattern form, when the distribution state (a density or a concentration degree) of the micro mirrors Ms in the ON state per unit area (for example, an arrangement region of 100×100 micro mirrors Ms) in all the micro mirrors Ms of the DMD 10 is determined, the telecentric error Δθt or the degree of the asymmetry property can also be easily specified by a simulation or the like.

### Second Embodiment

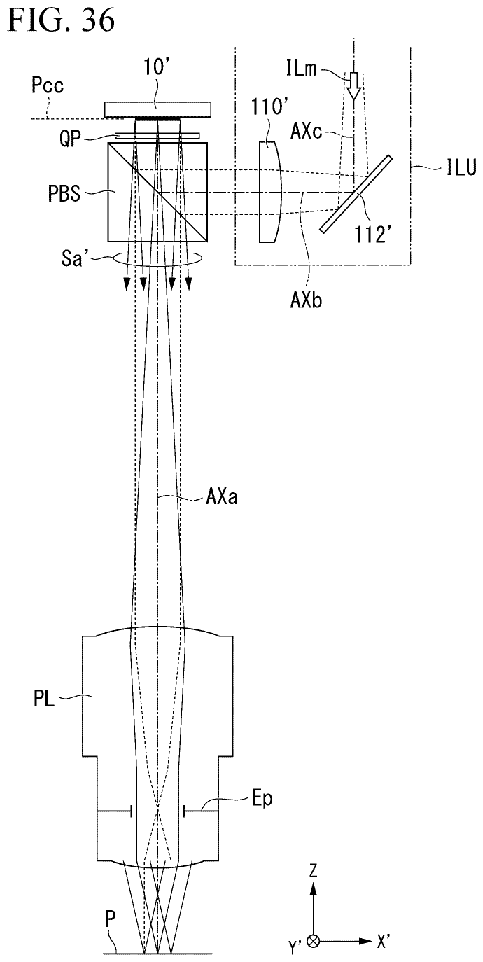

FIG. 36 is a view showing a schematic configuration of one of drawing modules provided on a pattern exposure apparatus according to a second embodiment. The orthogonal coordinate system X′Y′Z in FIG. 36 is set, for example, to be the same as the coordinate system X′Y′Z of FIG. 6. In the present embodiment, epi-illumination of the illumination light ILm irradiated from the illumination unit ILU to a digital mirror device (DMD) 10′ as the spatial light modulation element is performed via a polarization beam splitter PBS having a cube shape as a light splitter. In FIG. 36, a neutral plane Pcc of the DMD 10′ is set to be orthogonal to an optical axis AXa of a bilateral telecentric projection unit PLU, and the polarization beam splitter PBS is arranged in an optical path between the DMD 10′ and the projection unit PLU. A polarization splitting plane of the polarization beam splitter PBS is arranged to intersect the optical axis AXa at 45° and to rotate by 45° from the X′Y′ plane around a line parallel to the Y′ axis.

The illumination light ILm that enters a side surface of the polarization beam splitter PBS via a condenser lens system 110′ and a reflection mirror 112′ of the illumination unit ILU is set to S-polarized light that is linearly polarized in the Y′ direction in FIG. 36, and a component of a light amount of 95% or more is reflected in the +Z direction by the polarization splitting plane of the polarization beam splitter PBS. The illumination light ILm that advances in the +Z direction from the polarization beam splitter PBS transmits through a quarter-wave plate QP, becomes circularly polarized light, and irradiates the DMD 10′ with a uniform illuminance distribution.

A reflection surface of the micro mirror Ms of the DMD 10′ in the present embodiment is set so as to be in a flat posture parallel to the neutral plane Pcc at the time of an ON state where reflected light enters the projection unit PLU and so as to be inclined at a constant angle θd with respect to the neutral plane Pcc at the time of an OFF state where the reflected light does not enter the projection unit PLU. Accordingly, in a non-exposure period in which the DMD 10′ does not expose any pattern, all the micro mirrors Ms are in an initial state of being inclined at the angle θd. Therefore, unlike the form shown in FIG. 11 and FIG. 12, the micro mirror Msa in the ON state is in a posture parallel to the neutral plane Pcc, and the micro mirror Msb in the OFF state is in a posture inclined by the angle θd from the neutral plane Pcc.

Further, also in the configuration of FIG. 36, the illumination light ILm from a surface light source image (the aggregate of the point light sources SPF) formed on the emission surface side of a micro fly eye (MFE) lens 108A in the illumination unit ILU illuminates the DMD 10′ by Kohler illumination, and the pupil Ep of the projection unit PLU is set to be in a conjugate relation with the surface light source image on the emission surface side of the MFE lens 108A. Reflected light (image formation light flux) Sa′ from the micro mirror Msa in the ON state of the DMD 10′ advances reversely through the quarter-wave plate QP, is converted into linearly polarized light (P-polarized light) in the X′ direction, transmits through the polarization splitting plane of the polarization beam splitter PBS, and enters the projection unit PLU. In the present embodiment, since the principal ray of the illumination light ILm is set to be orthogonal to the neutral plane Pcc of the DMD 10′, the principal ray of the reflected light (image formation light flux) Sa′ from the micro mirror Msa in the ON state becomes parallel to the optical axis AXa geometrically and optically, and it is conceivable that a large telecentric error Δθt does not occur.

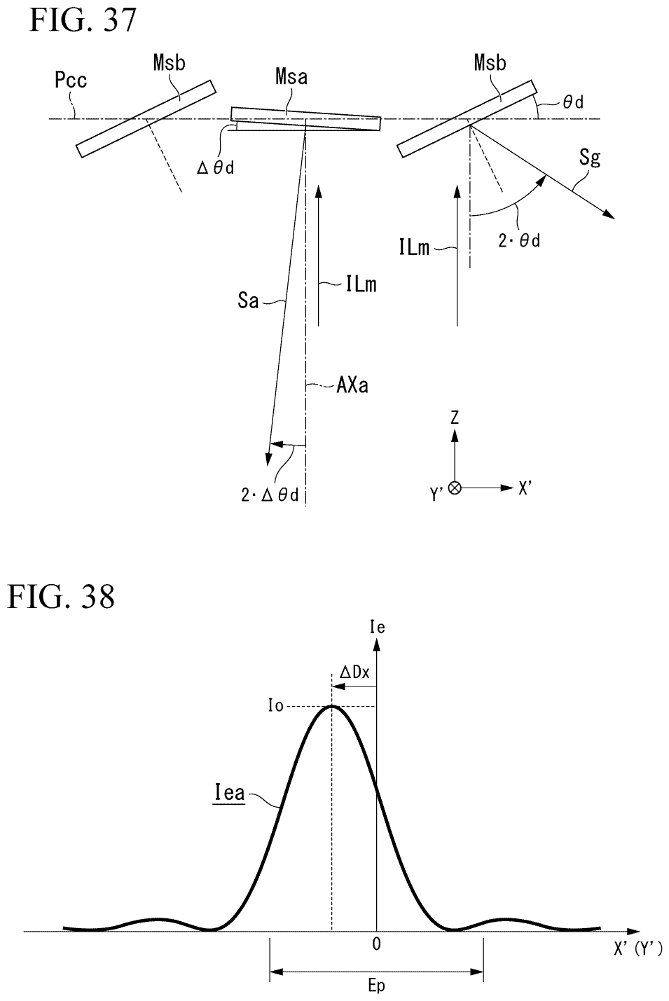

However, since a predetermined error may occur in a drive angle of the micro mirror Ms of the DMD 10′, a telecentric error Δθt may occur accordingly. FIG. 37 is an exaggerated view showing the state of the micro mirror Ms when projecting an isolated pattern having a minimum line width by the DMD 10′. In FIG. 37, the micro mirror Msb in the OFF state when seen in the X′Z plane is inclined at an angle θd in the initial state, and the reflected light Sg by the irradiation of the illumination light ILm is reflected at an angle 2θd which is a double angle relative to the optical axis AXa. On the other hand, the micro mirror Msa in the ON state is inclined by an angle θd from the posture in the initial state and is driven such that the reflection surface becomes parallel to the neutral plane Pcc. At that time, if there is a drive error Δθd, the micro mirror Msa in the ON state is inclined by θd+Δθd from the posture in the initial state.

Therefore, the principal ray of the reflected light (image formation light flux) Sa from the isolated micro mirror Msa in the ON state is generated to be inclined by an angle 2·Δθd of the double angle relative to the optical axis AXa. As shown in the embodiment described above, the pitches Pdx and Pdy of the micro mirrors Ms of the DMD 10′ are 5.4 μm, the angle θd in the initial state is 17.5°, the projection magnification Mp of the projection unit PLU is ⅙, and the drive error Δθd is =0.5° at the maximum. In that case, the telecentric error on the object surface side of the reflected light (image formation light flux) Sa is ±1° at the maximum, and the telecentric error Δθt on the image surface side is ±6° at the maximum. In general, the drive error Δθd is not often varied among a large number of micro mirrors Ms of the DMD 10′ and usually becomes a specific value (average value) averagely within a maximum error range. Since the maximum value (±0.5°) of the drive error Δθd is within the acceptable range in the product specification of the DMD 10′, it is also possible to select a micro mirror Msa, for example, having an average drive error Δθd of ±0.25° or less in the ON state from among several production lots. In any case, due to the influence of the drive error Δθd, the point image intensity distribution of the reflected light (image formation light flux) Sa in the pupil Ep of the projection unit PLU becomes a distribution of a sinc2 function as shown in FIG. 16.

FIG. 38 is a graph schematically showing the point image intensity distribution Iea of the diffraction image in the pupil Ep of the reflected light Sa from the isolated micro mirror Msa in the ON state as shown in FIG. 37. As shown in FIG. 38, the center position of the point image intensity distribution lea is shifted laterally by ΔDx in the X′ direction from the position of the optical axis AXa in the pupil Ep. The lateral shift ΔDx corresponds to the magnitude of the drive error Δθd of the micro mirror Msa in the ON state. Therefore, the telecentric error Δθt that occurs due to the drive error Δθd of the micro mirror Msa in the ON state of the actual DMD 10′ is measured by the first optical measurement unit (imaging element 326) or the second optical measurement unit (imaging element 344) described in FIG. 35 and is corrected by the adjustment mechanism of the telecentric error, and thereby, it is possible to reduce the telecentric error Δθt by the drive error Δθd.

Such a telecentric error Δθt caused by the drive error Δθd of the micro mirror Ms similarly occurs also in the case of the DMD 10 in the first embodiment. For example, at the time of projection of the isolated pattern described in FIG. 13 and FIG. 14, the telecentric error Δθd by the diffraction action does not occur, but the telecentric error Δθt caused by the drive error Δθd may occur. Accordingly, even at the time of projection of the isolated pattern by the DMD 10 of the first embodiment, the adjustment mechanism of the telecentric error can be desirably controlled such that the telecentric error Δθt on the image surface side caused by the drive error Δθd is reduced within an acceptable range (for example, within ±2°, desirably within ±1°).

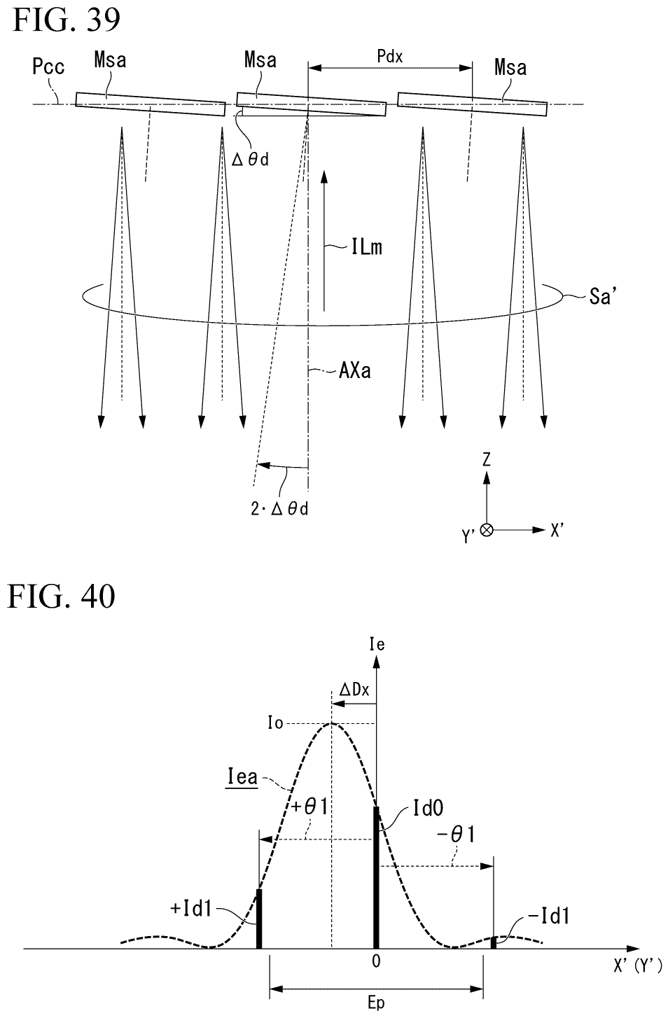

Next, the case where many of the micro mirrors Ms of the DMD 10′ are densely arranged and become the micro mirrors Msa in the ON state is described with reference to FIG. 39. FIG. 39 is an exaggerated view showing a state of the micro mirror Ms when a large land-like pattern is projected by the DMD 10′. In FIG. 39, the micro mirrors Msa in the ON state when seen in the X′Z plane ideally act as a planar diffraction grating aligned at a pitch Pdx in the X′ direction. Also in this case, too, it is assumed that there is a drive error Δθd in each of the micro mirrors Msa in the ON state.

Also in the case of FIG. 39, the diffraction angle θj of j-th order diffraction light Idj can be obtained based on Equation (2) described in FIG. 19.

$$\begin{matrix}[ Equation 5 ] & \\ sin θ j = j ( λ / Pdx ) - sin θα & ( 5 )\end{matrix}$$

When the pitch Pdx of the micro mirrors Msa in the ON state is 5.4 μm, the wavelength λ is 343.333 nm, and the incidence angle θα of the illumination light ILm is 0°, the diffraction angle θ0 (an angle from the optical axis AXa) of zero order diffraction light Id0 included in the reflected light (image formation light flux) Sa′ from the DMD 10′ is naturally 0°. Further, the diffraction angle θ1 of the ±first order diffraction light (−Id1, +Id1) included in the reflected light (image formation light flux) Sa′ is about ±3.645° on the object surface side of the projection unit PLU across the optical axis AXa.

FIG. 40 is a view schematically showing an example of a generation direction of a center ray of zero order diffraction light Id0 and ±first order diffraction light (−Id1, +Id1) included in the reflected light (image formation light flux) Sa′ in the state of FIG. 39 in a plane of the pupil Ep of the projection unit PLU. Similarly to FIG. 38, the point image intensity distribution Iea is laterally shifted by ΔDx from the optical axis AXa by the drive error Δθd of the micro mirror Msa in the ON state. The actual intensity distribution of the zero order diffraction light Id0 and the ±first order diffraction light (−Id1, +Id1) formed at the pupil Ep is obtained by the convolution integration (convolution calculation) between Equation (2) and the point image intensity distribution Iea (sinc2 function) laterally shifted by ΔDx in consideration of the size (σ value) of the surface light source (the light source image Ips shown in FIG. 9) that may be formed at the pupil Ep.

As shown in FIG. 40, the point image intensity distribution Iea is laterally shifted by ΔDx from the optical axis AXa, but the zero order diffraction light Id0 becomes parallel to the optical axis AXa, and the ±first order diffraction light (−Id1, +Id1) are generated symmetrically with respect to the zero order diffraction light Id0. As a result, the actual intensity distribution of the zero order diffraction light Id0 obtained by the convolution integration is located at the center of the pupil Ep, and therefore, the telecentric error Δθt does not occur. However, the peak value of the actual intensity distribution (substantially circular shape) of the zero order diffraction light Id0 is decreased from a peak value Io of the point image intensity distribution Iea. Further, the peak value of the actual intensity distribution (substantially circular shape) of each of the ±first order diffraction light (−Id1, +Id1) is also greatly reduced. The light amount change of the zero order diffraction light Id0 or the ±first order diffraction light (−Id1, +Id1) can be specified by a simulation or can be also specified by measuring a projection image of a test pattern or the like by the first optical measurement unit (imaging element 326) shown in FIG. 35.

The diffraction angle±θ1′ on the image surface side of the diffraction angle±θ1 (≈3.645°) of the ±first order diffraction light (−Id1, +Id1) on the object surface side becomes a multiple of the reciprocal number of the projection magnification Mp (⅙) and reaches θ1′=θ1/Mp≈±21.87°. This angle θ1′ corresponds to about 0.37 when converted into a numerical aperture NAi on the image surface side of the projection unit PLU. When the numerical aperture NAi on the image surface side is, for example, in the degree of NAi=0.30, about half of the actual intensity distribution (circular shape) of each of the ±first order diffraction light (−Id1, +Id1) does not transmit through the pupil Ep. Further, when the numerical aperture NAi on the image surface side of the projection unit PLU is about 0.25, most of the actual intensity distribution of the ±first order diffraction light (−Id1, +Id1) is located on the outside of the opening of the pupil Ep, and the reflected light (image formation light flux) Sa′ projected onto the substrate P is exclusively the component of the zero order diffraction light Id0.

As described above, in an epi-illumination system as in the present embodiment, when a large number of micro mirrors Msa in the ON state are densely arranged corresponding to a large land-like pattern among a large number of micro mirrors Ms of the DMD 10′, a significant telecentric error Δθt on the image surface side by the diffraction action does not occur. However, the light amount of the reflected light (image formation light flux) Sa′ that becomes the land-like pattern is reduced in accordance with the magnitude of the drive error Δθd (lateral shift ΔDx) of the micro mirrors Msa in the ON state. When the reduction of the light amount is increased, defects such as an increase in a size error of a resist image of a land-like pattern that appears after the substrate P is developed or a deterioration in penetration occur.

Accordingly, as shown in FIG. 39, at the time of exposure of the land-like pattern in which a large number of micro mirrors Msa in the ON state are densely arranged, not for the purpose of correction of the telecentric error Δθt but for the purpose of correction of a light amount decrease of the reflected light (image formation light flux) Sa′ due to the drive error Δθd, the adjustment mechanism (the drive unit 100C, the micro-motion mechanism 108D, the micro-motion mechanism 110C, or the like) of the telecentric error in the illumination unit ILU may be adjusted, and the incidence angle θα (0° by design) of the illumination light ILm to the DMD 10′ may be finely adjusted.

Since such a light amount variation error of the reflected light (image formation light flux) Sa′ caused by the drive error Δθd of the micro mirror Msa in the ON state may similarly occur in the case where the DMD 10 is irradiated with the illumination light ILm by an inclination illumination method as in the first embodiment, the telecentric error Δθ may be corrected in consideration of the drive error Δθd. Further, when the light amount variation error of the reflected light (image formation light flux) Sa′ becomes equal to or more than an acceptable range (for example, 10%) by the correction of the telecentric error Δθt, the illuminance adjustment filter 106 shown in FIG. 26 may be adjusted such that the transmittance of the illumination light ILm is increased. Accordingly, in order to perform the adjustment, information relating to the light amount variation error of the reflected light (image formation light flux) Sa′ caused by the drive error Δθd of the micro mirror Msa in the ON state can also be generated as one of the recipe information and be stored in the main control unit (computer).

Further, since the light amount variation error of the reflected light (image formation light flux) Sa′ occurs in a decreasing direction, the power of the beams LB1 to LB4 from the laser light sources FL1 to FL4 described in FIG. 29 can be increased for responding to the problem. However, in order to maximize the productivity (tact time), in many cases, each of the laser light sources FL1 to FL4 oscillates and emits the beams LB1 to LB4 at substantially full power, and it may be impossible to expect a further increase in the power. The same applies to the illuminance adjustment filter 106, and it may be impossible to further increase the transmittance. In such a case, by decreasing the scanning speed (the movement speed of the XY stage 4A in FIG. 1) in the X direction of the substrate P at the time of scanning exposure, it is possible to compensate for the decrease in the exposure amount (dose) given to the resist layer of the substrate P. At this time, the switching cycle (frequency) of the OFF state/ON state of the micro mirror of the DMD 10′ (or the DMD 10) is also adjusted in accordance with the scanning speed of the substrate P.

Further, at least one error that exhibits a particularly predominant error may be specified among the telecentric error Δθt of the reflected light (image formation light flux) Sa′ projected onto the substrate P, an asymmetry error (refer to FIG. 24) of the pattern image caused by the telecentric error Δθt, and the light amount variation error of the reflected light (image formation light flux) Sa′ caused by the drive error Δθd of the micro mirror Msa in the ON state, and two-dimensional inclination of the DMD 10′ (or the DMD 10) or at least one of the and the optical members in the illumination unit ILU or the projection unit PLU may be adjusted such that the error is reduced.

As is apparent from the state of FIG. 40, depending on not only the influence by the drive error 40d but also the telecentric error Δθt caused by the diffraction phenomenon by the form (isolated, L&S, land-like, or the like) of the pattern, the lateral shift amount of the diffraction light Id0 corresponding to the zero order light on the distribution of the Sinc2 function also varies, and the intensity of the diffraction light Id0 decreases. In this case, even if the adjustment member in the illumination optical system, the posture (inclination) of the DMD 10′ or the DMD 10, and the like are adjusted such that the telecentric error Δθt including the drive error Δθd becomes zero, the intensity of the diffraction light Id0 remains low. Therefore, illuminance correction can be desirably performed at the time of actual exposure by performing predictive calculation (simulation) of the total light amount variation (mainly, the illuminance decrease) that may occur in association with the telecentric error Δθt corresponding to the form of the pattern to be exposed in advance or by actually measuring a projection state of the test pattern by the first optical measurement unit (imaging element 326).

As described above, according to the present embodiment, in a device manufacturing method that forms a device pattern on a substrate P by projecting an image of the device pattern corresponding to drawing data MDn onto the substrate P by the projection unit PLU that irradiates, with the illumination light ILm from the illumination unit ILU, the DMD 10′ (or the DMD 10) as the spatial light modulation element having a large number of micro mirrors Ms switched between an ON state and an OFF state based on drawing data MDn and causes reflected light from micro mirrors Msa which become the ON state of the DMD 10′ (or the DMD 10) to be incident as the image formation light flux (Sa′), by performing: a step of specifying a telecentric error of the image formation light flux (Sa′) that occurs in accordance with the distribution state of the micro mirrors Msa in the ON state of the DMD 10′ (or the DMD 10) or a light amount change of the image formation light flux (Sa′) that occurs due to a drive error Δθd of the micro mirrors Msa in the ON state; and a step of adjusting the installation state (the position or the angle) of at least one optical member (the mirrors 100, 112, the aperture diaphragm 108B, the condenser lens system 110, the illuminance adjustment filter 106, or DMD 10, or may be the DMD 10′) in the illumination unit ILU (or projection unit PLU) such that the specified telecentric error or the specified light amount change is reduced when the device pattern is exposed on the substrate P by driving the DMD 10′ (or the DMD 10) based on recipe information (drawing data MDn), a device manufacturing method that reduces the light amount change or the telecentric error which occurs by the drive error Δθd or the diffraction action when the micro mirrors Ms of the DMD 10′ (or the DMD 10) become the ON state and forms a faithful pattern based on the drawing data is obtained.

Further, according to the present embodiment, in a device manufacturing method that forms an electronic device on a substrate P by projecting a pattern image of the electronic device corresponding to drawing data MDn onto the substrate P by the projection unit PLU that irradiates, with the illumination light ILm from the illumination unit ILU, the DMD 10′ (the DMD 10) as the spatial light modulation element having a large number of micro mirrors Ms switched between an ON state and an OFF state based on the drawing data MDn and causes reflected light Sa′ from micro mirrors Msa which become the ON state of the DMD 10′ (the DMD 10) to be incident as the image formation light flux, by performing a step of specifying at least one error that exhibits a particularly predominant error or two errors (for example, a telecentric error and a light amount variation error, or a telecentric error and an asymmetry error) that occur in combination among a telecentric error Δθt of the reflected light (image formation light flux) Sa′ that occurs by a diffraction action in accordance with the distribution state of the micro mirrors Msa in the ON state of the DMD 10′ (the DMD 10), an asymmetry error of the pattern image that occurs due to the telecentric error Δθt, and a light amount variation error or a telecentric error of the reflected light (image formation light flux) Sa′ that occurs due to a drive error Δθd of the micro mirrors Msa in the ON state, and performing a step of adjusting the installation state (the position or the angle) of at least one optical member in the illumination unit ILU or the projection unit PLU such that the specified one or more errors are reduced when the pattern image is exposed on the substrate P by driving the DMD 10′ (the DMD 10), a device manufacturing method that reduces the telecentric error which occurs by the drive error Δθd or the diffraction action when the micro mirrors Ms of the DMD 10′ (or the DMD 10) become the ON state, the asymmetry error, or the light amount variation error and realizes faithful pattern formation based on the drawing data is obtained.

### (Calibration of Image Formation State)

As described above, in the projection exposure using the DMD 10, while switching each of the large number of micro mirrors Ms included in the DMD 10 between the inclination in the ON state and the inclination in the OFF state based on the pattern data (drawing data) at a high speed, the substrate P is scanned and moved in the X direction at a speed corresponding to the switching speed, and a pattern exposure is performed. In this case, the telecentric state of the image formation light flux projected from the projection unit PLU to the substrate P may be changed depending on the fineness, the concentration degree, or the periodicity of the projected pattern. This is because the mirror surface of the DMD 10 acts as a reflection-type diffraction grating (blazed diffraction grating) depending on an inclination state of the large number of micro mirrors Ms of the DMD 10.

In the following description, the diffraction light generated as a result of the mirror surface of the DMD 10 acting as a blazed diffraction grating is also simply referred to as blazed diffraction light.

The state (that is, an image formation state on the substrate P) of the blazed diffraction light by the DMD 10 is determined by a roll angle and a tilt angle of the micro mirror Ms of the DMD 10, a distance (that is, a pitch) between the micro mirrors Ms in the ON state, an inclination angle of the micro-motion stage for finely adjusting the position and the posture of the DMD 10, and the like.

The exposure apparatus EX of the present embodiment includes a plurality of modules MU, for example, as shown in FIG. 2. Each module MU includes the illumination unit ILU, the DMD 10, and the projection unit PLU. That is, the exposure apparatus EX includes the DMD 10 in each module MU.

There may be cases in which variations in the state of blazed diffraction light occur among the modules MU by various factors such as product variations caused by the manufacturing process of the DMD 10, variations in an attachment state of the DMD 10 to the module MU, or variations in the operation environment of each module MU.

Accordingly, in the case where a plurality of modules MU are provided as in the exposure apparatus EX of the present embodiment, it is preferable that the variation in the image formation state on the substrate P caused by the variation in the state of the blazed diffraction light can be corrected for each module MU.

The exposure apparatus EX of the present embodiment corrects the state of the blazed diffraction light for each module MU and can thereby uniform the image formation states among the plurality of modules MU. Hereinafter, a state correction of the blazed diffraction light for each module MU by the exposure apparatus EX is described. In the following description, the state correction of the blazed diffraction light is also referred to as the calibration of the image formation state.

The exposure apparatus EX of the present embodiment performs the calibration of the image formation state by correcting the shift amount ΔDx (refer to FIG. 10 and the like) of the center of an intensity distribution Hpa and the illuminance of the illumination light on the substrate P. In the following description, the center of the intensity distribution Hpa is also referred to as the center of gravity of the illumination light (or simply referred to as the center of gravity).

As described with reference to FIG. 26 and the like, the exposure apparatus EX measures each of the shift amount ΔDx of the center of gravity of the illumination light and the illuminance of the illumination light, for example, by the optical measurement unit described above. The exposure apparatus EX performs the calibration of the image formation state by adjusting each of the center of gravity and the illuminance based on a measurement result of the center of gravity and the illuminance of the illumination light.

Specifically, the exposure apparatus EX adjusts the position of the MFE lens 108A in the illumination unit ILU and thereby adjusts the shift amount ΔDx of the center of gravity of the illumination light. The exposure apparatus EX adjusts the transmittance of the illuminance adjustment filter 106 and thereby adjusts the illuminance of the illumination light on the substrate P. Various methods are conceivable for the calibration of these image formation states.

Hereinafter, a specific example of a calibration procedure performed by an exposure control device (for example, the exposure control device shown in FIG. 32) included in the exposure apparatus EX of the present embodiment is described below.

The exposure control device of the present embodiment can also correct the error of illuminance in addition to the error (the telecentric error described above) of the center of gravity.

### (1) Calibration Method Based on Reference Illumination Pattern

(Step S11) The exposure control device acquires recipe information from the storage unit 300 for each module MU. The exposure control device acquires the ON state/OFF state of the micro mirror Ms of the DMD 10 indicated by the acquired recipe information as a specific pattern of the DMD 10 for each module MU. The specific pattern here is an isolated pattern, a line-and-space pattern, a large land-like pattern, or the like.

(Step S12) The exposure control device measures the center of gravity and the illuminance in a reference illumination pattern of the DMD 10 for each module MU. The reference illumination pattern here is, as an example, a pattern in which all the micro mirrors Ms of the DMD 10 are in the ON state (that is, ALL-ON). The reference illumination pattern may be any pattern as long as the pattern can be a reference for the correction of the center of gravity and the illuminance and is not limited to the ALL-ON pattern described above.

(Step S13) The exposure control device corrects the center of gravity and the illuminance for each module MU such that both the center of gravity and the illuminance in the reference illumination pattern become predetermined values, respectively. As described above, correction of the center of gravity is performed by adjusting the position of the MFE lens 108A. Correction of the illuminance is performed by adjusting the transmittance of the illuminance adjustment filter 106.

As a result, the center of gravity and the illuminance in the reference illumination pattern are uniformed among all the modules MU included in the exposure apparatus EX. That is, the variations in the center of gravity and the illuminance among the modules MU in the reference illumination pattern are reduced.

(Step S14) The exposure control device performs a simulation calculation (or an experimental value) based on the roll angle and the tilt angle of the micro mirror Ms of the DMD 10 measured in advance and thereby calculates the center of gravity and the illuminance by the specific pattern acquired in Step S11.

That is, the exposure control device understands the relationship among the roll angle and the tilt angle of the micro mirror Ms, the center of gravity, and the illuminance based on the simulation calculation (or the experimental value) and thereby calculates a correction amount of the center of gravity and the illuminance.

(Step S15) The exposure control device corrects the center of gravity and the illuminance such that both the center of gravity and the illuminance in the specific pattern become predetermined states, respectively, based on the center of gravity and the illuminance by the specific pattern calculated in Step S14.

In the case of the calibration method based on the reference illumination pattern described above, the difference in the state of the blazed diffraction light between the reference illumination pattern and the specific pattern is finely corrected in a state where the variation in the center of gravity and the illuminance among the modules MU in the reference illumination pattern are reduced.

That is, according to the calibration method based on the reference illumination pattern, the correction procedure can be divided into correction (that is, coarse correction) that reduces the variation in the center of gravity and the illuminance among the modules MU in the reference illumination pattern by Step S10 to Step S13 and correction (that is, fine correction) that reduces the variation in the center of gravity and the illuminance among the modules MU in the specific pattern by Step S14 and Step S15.

According to the calibration method constituted in this way, the work frequency (for example, once a week or the like) of the coarse correction can be decreased to be smaller than the work frequency (for example, every time the recipe is changed or the like) of the fine correction. Therefore, according to the calibration method constituted in this way, the work frequency of the coarse correction can be reduced, and productivity can be improved.

The angle of the micro mirror Ms of the DMD 10 may change with time. In this case, the simulation condition of the simulation operation used in the Step S14 described above may be updated in accordance with the change with time.

### (2) Calibration Method Based on Predetermined Pattern

(Step S21) The exposure control device acquires recipe information from the storage unit 300 for each module MU. The exposure control device acquires the ON state and the OFF state of the micro mirror Ms of the DMD 10 indicated by the acquired recipe information as a specific pattern of the DMD 10 for each module MU.

(Step S22) The exposure control device selects a predetermined pattern for calibration for each module MU based on the specific pattern acquired in Step S21. The predetermined pattern here is a pattern (for example, an isolated pattern, a line-and-space pattern, a large land-like pattern, or the like) prepared in advance as a pattern which is likely to be present in the specific pattern based on the recipe information.

The predetermined pattern may be exactly the specific pattern based on the recipe information acquired in Step S21.

(Step S23) The exposure control device calculates the center of gravity and the illuminance by the predetermined pattern selected in Step S22 for each module MU.

(Step S24) The exposure control device corrects the center of gravity and the illuminance such that both the center of gravity and the illuminance in the predetermined pattern become predetermined states, respectively, based on the center of gravity and the illuminance by the predetermined pattern calculated in Step S24.

In the case of the calibration method based on the predetermined pattern described above, since the correction is performed in one step instead of two steps by the coarse correction and the fine correction described above, the configuration can be simplified, and it is possible to reduce the time required for the correction and to improve the productivity.

### Modification Example

The exposure control device may give a plurality of specific patterns different from each other in the correction of the center of gravity and the illuminance in Step S15 and Step S24 described above and understand the change in the center of gravity and the illuminance for each specific pattern. For example, when the specific pattern is a line-and-space pattern, the exposure control device may change the cycle (pitch) of the line variously and understand the change in the center of gravity and the illuminance.

According to such a configuration, the exposure control device can further accurately understand the degree of variation in the center of gravity and the illuminance and can improve the accuracy of correction.

Further, the exposure control device may individually perform each of the correction of the center of gravity and the illuminance in the X direction of the substrate P and the correction of the center of gravity and the illuminance in the Y direction of the substrate P.

Further, the exposure control device may set a correction order and perform the correction of the center of gravity and the illuminance such that correction of the center of gravity is performed in a first step, and correction of the illuminance is performed in the next second step. According to such a configuration, the exposure control device can perform the correction while distinguishing the vignetting of the light flux by the deviation of the center of gravity at the pupil position from illuminance insufficiency.

Further, there may be cases in which the specific pattern based on the recipe information is a pattern in which the number of micro mirrors Ms in the ON state is extremely small compared to the number of micro mirrors Ms in the OFF state. When the number of the micro mirrors Ms in the ON state is extremely small in this way, the illuminance becomes insufficient, and the measurement accuracy of the center of gravity and the illuminance may be decreased.

In such a case, the exposure control device may operate such that the insufficiency of illuminance is resolved and improve the measurement accuracy by temporally or spatially dividing the specific pattern in which the number of micro mirrors Ms in the ON state is extremely small and performing an exposure (performing a so-called multiple exposure).

Further, when scanning and exposing the substrate P, at each scanning, the exposure control device may perform the correction of the center of gravity and the illuminance corresponding to the actual exposure pattern in each scanning. As described above, the movement position in the X direction of the substrate P and the movement position in the Y-axis direction of the substrate P are measured by the interferometers IFY (for example, the interferometers IFY1 to IFY4). Therefore, according to the exposure control device of the present embodiment, even when correction of the center of gravity and the illuminance is performed at each scanning, the alignment of the exposure can is possible by the accuracy of the interferometer.

Further, as described above, the exposure control device extracts an important pattern portion having a high specification value of line width accuracy, position accuracy, or superposition accuracy from the drawing data relating to the actual exposure pattern included in the recipe information and registers the extracted pattern portion as a test pattern in the recipe information in advance.

The exposure control device may switch the test pattern in a portion (for example, a boundary between a bezel portion and a pixel portion in a liquid crystal display panel) where the actual exposure pattern registered in the recipe information changes abruptly in each scanning and thereby perform the correction of the center of gravity and the illuminance corresponding to the actual exposure pattern.

Further, in a portion where the test patterns registered in the recipe information are mixed on the substrate P, the center of gravity and the illuminance may be corrected by setting a correction amount of the center of gravity and the illuminance for each test pattern to a value (for example, an average value) obtained by statistically calculating the correction amount of each test pattern.

In the above description, the exposure control device performs the correction of the illuminance by adjusting the transmittance of the illuminance adjustment filter 106; however, the present embodiment is not limited thereto. The exposure control device may correct the substantial illuminance on the substrate P by changing the line width of the actual exposure pattern projected onto the substrate P instead of (or in addition to) the adjustment of the illuminance adjustment filter 106.

Further, the exposure control device may measure the line width of the actual exposure pattern on the substrate P based on the result of measurement by an exposure amount measurement device (for example, the photoelectric element 109D) and thereby perform the correction of the center of gravity and the illuminance.

Further, the exposure control device may store the relationship between the illuminance in the actual exposure pattern and the line width on the substrate P in advance and correct the line width on the substrate P while estimating the line width of the actual exposure pattern based on the result of the illuminance measurement.

Further, the exposure control device may store, as the recipe information, the drawing data and an illuminance difference by the pattern of the image formation light flux that occurs in accordance with the drive error Δθd (angle error) as information relating to the illuminance.

When a pattern is exposed on the substrate P by driving the spatial light modulation element (DMD) based on the recipe information, the exposure control device controls an adjustment mechanism that adjusts the position or the angle of at least one optical member in the illumination unit or the projection unit or the angle of the spatial light modulation element in accordance with the information relating to the illuminance.

Further, the exposure control device may include: a mechanism that measures the illuminance difference of the plurality of modules by the pattern of the image formation light flux which occurs in accordance with the distribution density of the micro mirrors in the ON state of the spatial light modulation element (DMD) and the drive error Δθd (angle error) in the inclination of the micro mirrors and stores the measured illuminance difference as the information relating to the illuminance; and a mechanism that adjusts the illuminance by adjusting the position or the angle of at least one optical member in the illumination unit or the projection unit or the angle of the spatial light modulation element in accordance with the stored information relating to the illuminance when the pattern is exposed onto the substrate P by driving the spatial light modulation element based on the recipe information based on the measured illuminance difference.

Further, the exposure control device may include a pattern line width correction calculation unit that substantially obtains the illuminance difference of the plurality of modules by the pattern of the image formation light flux which occurs in accordance with the distribution density of the micro mirrors in the ON state of the spatial light modulation element (DMD) and the drive error Δθd (angle error) in the inclination of the micro mirrors and a line width error which occurs at the time of exposure due to the image formation state, and substantially adds correction to the line width of the drawing data when the pattern is exposed on the substrate P.

As described above, according to the present embodiment, in the pattern exposure apparatus including a plurality of modules MU including the DMD 10 as the spatial light modulation element, by correcting the state of the image formation light flux corresponding to the exposure pattern for each module MU, it is possible to reduce the telecentric error or the light amount change for each module MU and form a faithful pattern based on the drawing data.

Although the embodiments of the present invention have been described in detail with reference to the drawings, the configurations in the embodiments described above are examples, and various design changes and the like can be made without departing from the scope of the present invention.

A pattern exposure apparatus according to an embodiment is a pattern exposure apparatus that includes a plurality of modules including: an illumination unit that irradiates, with illumination light, a spatial light modulation element having a large number of micro mirrors driven to be switched between an ON state and an OFF state based on drawing data; and a projection unit that causes reflected light from micro mirrors which become the ON state of the spatial light modulation element to be incident as an image formation light flux and projects an image of a pattern corresponding to the drawing data onto a substrate. The pattern exposure apparatus includes: a control unit that stores, for each of the modules, information relating to an angle change of the image formation light flux which occurs in accordance with a distribution density of micro mirrors in the ON state of the spatial light modulation element together with the drawing data as recipe information, and stores correction information which corrects a state of the image formation light flux corresponding to the pattern for each of the modules; and an adjustment mechanism that adjusts, for each of the modules, a position or an angle of at least one optical member in the illumination unit or the projection unit or an angle of the spatial light modulation element based on the information relating to the angle change and the correction information when the pattern is exposed onto the substrate by driving the spatial light modulation element based on the recipe information.

In an example, the projection unit has an exit pupil through which the image formation light flux passes at a predetermined aperture diameter, and the adjustment mechanism performs an adjustment such that an eccentric state of a distribution in the exit pupil of the image formation light flux defined from the information relating to the angle change is reduced.

In an example, the pattern exposure apparatus further includes: a stage device that supports and moves the substrate on an image surface side of the projection unit, and the stage device has an optical measurement unit that measures a distribution of the image formation light flux formed in the exit pupil of the projection unit.

In an example, the control unit generates the information relating to the angle change as a telecentric error amount based on the drawing data and determines whether or not the telecentric error amount is equal to or more than a predetermined acceptable range defined in accordance with the distribution density of the micro mirror in the ON state in advance, and the adjustment mechanism performs an adjustment operation at a time of pattern exposure in which the telecentric error amount is equal to or more than the predetermined acceptable range.

In an example, the control unit stores drawing data for a test pattern corresponding to a pattern form in which the telecentric error amount is likely to be equal to or more than the predetermined acceptable range, and the optical measurement unit measures the distribution in the exit pupil of the image formation light flux from the spatial light modulation element driven by the drawing data for the test pattern and confirms the telecentric error amount.

In an example, the illumination unit includes an optical integrator which a beam from a light source device enters and a condenser lens system that performs Kohler illumination of illumination light from a surface light source generated by the optical integrator toward a mirror surface of the spatial light modulation element, and the projection unit has an exit pupil having an optically conjugate relation with a position of the surface light source generated by the optical integrator and performs reduction projection of an image of a pattern generated by the micro mirror in the ON state of the spatial light modulation element.

In an example, the adjustment mechanism is constituted of an adjustment mechanism that adjusts an incidence position or an incidence angle of the beam which enters the optical integrator or an adjustment mechanism that adjusts a relative position relationship relating to an eccentric direction between the optical integrator and the condenser lens system such that an incidence angle of the illumination light irradiated to the spatial light modulation element is changed.

In an example, the control unit further stores, as one of the recipe information, information relating to illuminance variation of the image formation light flux that occurs in accordance with a density distribution of the micro mirror in the ON state of the spatial light modulation element.

In an example, the illumination unit includes an illuminance adjustment filter that changes illuminance of the illumination light irradiated to the spatial light modulation element, and the adjustment mechanism further includes a mechanism that controls the illuminance adjustment filter based on the information relating to the illuminance variation.

In an example, the control unit further stores, as one of the recipe information, information relating to illuminance variation of the image formation light flux that occurs in accordance with a density distribution of micro mirrors in the ON state of the spatial light modulation element, and the stage device adjusts, based on the information relating to the illuminance variation, a movement speed when a projection image by the projection unit of the pattern generated by the micro mirror in the ON state is scanned and exposed on the substrate.

In an example, the projection unit includes: a plurality of lenses arranged in front of and behind the exit pupil; and an optical member that corrects an image surface inclination which occurs when the angle of the spatial light modulation element is adjusted by the adjustment mechanism.

In an example, the projection unit has a plurality of lenses arranged in front of and behind the exit pupil, and a position adjustment in an eccentric direction of part of the plurality of lenses is performed such that an image surface inclination which occurs when the angle of the spatial light modulation element is adjusted is corrected by the adjustment mechanism.

A pattern exposure apparatus according to an embodiment is a pattern exposure apparatus which includes a plurality of modules that include: a spatial light modulation element having a large number of micro mirrors selectively driven based on drawing data; an illumination unit that irradiates the spatial light modulation element with illumination light at a predetermined incidence angle; and a projection unit that causes reflected light from selected micro mirrors in an ON state of the spatial light modulation element to be incident as an image formation light flux and be projected onto a substrate, and projects and exposes a pattern corresponding to the drawing data onto the substrate. The pattern exposure apparatus includes: a control unit that stores correction information which corrects a state of the image formation light flux corresponding to the pattern for each of the modules; and an adjustment mechanism that adjusts a position or an angle of an optical member of part of the illumination unit or the projection unit for each of the modules based on the correction information.

In an example, the control unit analyzes a density of the micro mirrors in the ON state in accordance with the pattern based on the drawing data and determines a magnitude of a telecentric error.

In an example, the control unit determines a magnitude of a telecentric error based on the drawing data when half or more of all of the micro mirrors of the spatial light modulation element become the micro mirrors in the ON state.

In an example, when a reflection surface that becomes flat at a time of non-driving is a neutral plane, the large number of micro mirrors of the spatial light modulation element are two-dimensionally arranged along each of a first direction and a second direction that are orthogonal to each other in the neutral plane, and the control unit determines a magnitude of a telecentric error based on the drawing data when several or more micro mirrors adjacent to each other in both the first direction and the second direction become the micro mirrors in the ON state.

In an example, when a pattern to be exposed is a line-and-space pattern, based on the drawing data, the control unit determines a magnitude of a telecentric error based on a periodicity and a periodicity direction of an arrangement of the micro mirrors in the ON state among the micro mirrors of the spatial light modulation element.

In an example, the adjustment mechanism adjusts the position or the angle of the optical member when the magnitude of the telecentric error determined by the control unit exceeds a predetermined acceptable range.

In an example, the predetermined acceptable range is set to be within ±2° as an inclination angle with respect to an optical axis of a principal ray of the image formation light flux that is directed from the projection unit to the substrate.

In an example, the illumination unit includes: a surface light source member on which a beam from a laser light source device enters and which generates a surface light source of the illumination light; and a condenser lens system on which the illumination light from the surface light source enters and which illuminates a reflection surface of the spatial light modulation element by Kohler illumination, and the adjustment mechanism adjusts a relative position relationship relating to an eccentric direction between the surface light source and the condenser lens system.

In an example, the adjustment mechanism includes a first telecentric adjustment mechanism that shifts a position of the beam from the laser light source device which enters the surface light source member in an eccentric direction.

In an example, the adjustment mechanism includes a second telecentric adjustment mechanism that shifts a position of the surface light source member in an eccentric direction with respect to the beam from the laser light source device.

In an example, the adjustment mechanism includes a third telecentric adjustment mechanism that shifts a position of the condenser lens system in an eccentric direction with respect to a position of the surface light source generated by the surface light source member.

In an example, the illumination unit includes, as the optical member, a mirror that reflects the illumination light at a predetermined angle, and the adjustment mechanism changes an angle of the mirror and adjusts the incidence angle of the illumination light irradiated to the spatial light modulation element.

In an example, when a reflection surface of a micro mirror in the ON state of the spatial light modulation element is inclined by an angle θd (θd >0°) by a design relative to a surface that is orthogonal to an optical axis of the projection unit, the illumination unit is set to be in an inclination illumination method in which an incidence angle θα of the illumination light from the condenser lens system to the spatial light modulation element becomes θα=2·θd by a design, and the incidence angle θα is adjusted by the adjustment mechanism.

In an example, the pattern exposure apparatus includes a light splitter arranged in an optical path between the spatial light modulation element and the projection unit, and when a reflection surface of a micro mirror in the ON state of the spatial light modulation element is set to an angle θd=0° by a design relative to a surface that is orthogonal to an optical axis of the projection unit, the illumination unit is set to be in an epi-illumination system in which the illumination light from the condenser lens system is irradiated at an incidence angle θα=0° to the spatial light modulation element via the light splitter, and the incidence angle θα is adjusted by the adjustment mechanism.

A pattern exposure apparatus according to an embodiment is a pattern exposure apparatus including: an illumination unit that irradiates, with illumination light, a spatial light modulation element having a large number of micro mirrors switched between an ON state and an OFF state based on drawing data for pattern exposure; and a projection unit that causes reflected light from micro mirrors which become the ON state of the spatial light modulation element to be incident as an image formation light flux and projects a pattern image corresponding to the drawing data onto a substrate. The pattern exposure apparatus includes: a measurement unit that measures a degree of an asymmetry property of the pattern image occurring due to a telecentric error of the image formation light flux which occurs in accordance with a distribution density of the micro mirrors in the ON state of the spatial light modulation element; and an adjustment mechanism that adjusts a position or an angle of at least one optical member in the illumination unit or the projection unit or an angle of the spatial light modulation element such that the measured asymmetry property is reduced when the pattern image is exposed onto the substrate by driving the spatial light modulation element based on the drawing data.

In an example, the pattern exposure apparatus further includes: a stage device that supports the substrate on an image surface side of the projection unit and is movable along the image surface, and the measurement unit is provided on part of the stage device, measures an intensity distribution of the pattern image, and measures a degree of the asymmetry property.

In an example, the adjustment mechanism adjusts the position or the angle of at least one optical member in the illumination unit such that an incidence angle of the illumination light irradiated to the spatial light modulation element is changed.

In an example, the illumination unit includes: a surface light source member on which a beam from a laser light source device enters and which generates a surface light source of the illumination light; and a condenser lens system on which the illumination light from the surface light source enters and which illuminates a reflection surface of the spatial light modulation element by Kohler illumination, and the adjustment mechanism adjusts a relative position relationship relating to an eccentric direction between the surface light source and the condenser lens system.

In an example, the surface light source member has a fly eye lens that forms the surface light source on an emission surface side of a large number of lens elements which are two-dimensionally arranged and an aperture diaphragm arranged on an emission surface side of the fly eye lens, and the adjustment mechanism adjusts a relative position relationship relating to an eccentric direction between the condenser lens system and an aperture of the aperture diaphragm.

In an example, the surface light source member has a fly eye lens that forms the surface light source on an emission surface side of a large number of lens elements which are two-dimensionally arranged, and the adjustment mechanism adjusts an incidence angle of the beam from the light source device to the fly eye lens.

In an example, the projection unit is a reduction projection optical system that is constituted of a plurality of lenses and projects a reduction image of a pattern generated by a micro mirror in the ON state of the spatial light modulation element onto the substrate, and when the angle of the spatial light modulation element is adjusted by the adjustment mechanism, a position of part of the lenses of the reduction projection optical system is adjusted in an eccentric direction such that inclination of an image surface of the reduction projection optical system is corrected.

In an example, data of a test pattern in which the micro mirrors in the ON state are arranged at a distribution density at which a telecentric error occurs in the image formation light flux is included in the drawing data, and the measurement unit measures the asymmetry property of a projection image by the projection unit of the test pattern generated by the spatial light modulation element.

In an example, a reflection surface of a micro mirror in the ON state of the spatial light modulation element is set to be inclined by an angle θd (θd >0°) by a design relative to a surface that is orthogonal to an optical axis of the projection unit, an inclination illumination method in which an incidence angle θα of the illumination light from the illumination unit to the spatial light modulation element becomes θα=2·θd by a design is set, and the adjustment mechanism adjusts the incidence angle θα.

In an example, the pattern exposure apparatus further includes a light splitter arranged between the spatial light modulation element and the projection unit, a reflection surface of a micro mirror in the ON state of the spatial light modulation element is set to an angle θd=0° by a design relative to a surface that is orthogonal to an optical axis of the projection unit, an epi-illumination system in which an incidence angle θα of the illumination light irradiated to the spatial light modulation element via the light splitter becomes θα=0° by a design is set, and the incidence angle θα is adjusted by the adjustment mechanism.

A device manufacturing method according to an embodiment is a device manufacturing method that forms a device pattern on a substrate by projecting an image of the device pattern corresponding to drawing data onto the substrate by a projection unit that irradiates, with illumination light from an illumination unit, a spatial light modulation element having a large number of micro mirrors switched between an ON state and an OFF state based on the drawing data and causes reflected light from micro mirrors which become the ON state of the spatial light modulation element to be incident as an image formation light flux. The device manufacturing method includes: a step of specifying a telecentric error of the image formation light flux that occurs in accordance with a distribution state of the micro mirrors in the ON state of the spatial light modulation element or a light amount variation error of the image formation light flux that occurs due to a drive error of the micro mirrors in the ON state; a step of storing correction information that corrects a state of the image formation light flux corresponding to the pattern based on the light amount variation error for each module including the illumination unit, the spatial light modulation element, and the projection unit; and a step of adjusting an installation state of the spatial light modulation element for each module based on the correction information when the image of the device pattern is exposed onto the substrate by driving the spatial light modulation element based on the drawing data.

In an example, the specifying step specifies the telecentric error of the image formation light flux or the light amount variation error based on a generation state of diffraction light defined in accordance with the distribution state in each of an isolated pattern in which one or a row of several micro mirrors in the ON state are arranged independently or to form a row, a line-and-space pattern in which the micro mirrors in the ON state are arranged such that the isolated pattern is aligned at a constant cycle, and a land-like pattern in which the micro mirrors in the ON state are densely arranged such that a size is several times or more larger than that of the isolated pattern.

An example is the device manufacturing method, wherein a reflection surface of a micro mirror in the ON state of the spatial light modulation element is set to be inclined by an angle θd (θd ≥0°) by a design relative to a surface that is orthogonal to an optical axis of the projection unit, and an incidence angle θα of the illumination light from the illumination unit to the spatial light modulation element is set to become θα=2·θd by a design.

In an example, when an arrangement pitch of the micro mirrors is Pdx, n is a real number, a wavelength of the illumination light is λ, and an angle of each order j (j=0, 1, 2, . . . ) of the diffraction light is θj, the telecentric error of the image formation light flux is defined by an angle of j-th order diffraction light having a small inclination from the optical axis of the projection unit among a plurality of orders of diffraction light defined by sin θj=j·(λ/(n·Pdx))−sin θα.

In an example, the adjusting step adjusts the incidence angle θα of the illumination light by adjusting a position or an angle of an optical member in the illumination unit or an angle of the spatial light modulation element such that an inclination angle of the j-th order diffraction light from the optical axis of the projection unit is within a predetermined acceptable range.

In an example, in the specifying step, when an angle error of ±Δθd with respect to the inclination angle θd is included as the drive error of the micro mirrors in the ON state, the light amount variation error of the image formation light flux is specified based on a degree to which a point image intensity distribution in an exit pupil of the projection unit of reflected light from a single micro mirror in the ON state is eccentric corresponding to the angle error±Δθd.

In an example, in the adjusting step, in accordance with the specified light amount variation error, adjustment of a beam intensity from a light source device that is a source of the illumination light or adjustment of a transmittance of the illumination light by an illuminance adjustment filter provided on the illumination unit is performed.

A device manufacturing method according to an embodiment is a device manufacturing method that forms an electronic device on a substrate by projecting a pattern image of the electronic device corresponding to drawing data onto the substrate by a projection unit that irradiates, with illumination light from an illumination unit, a spatial light modulation element having a large number of micro mirrors switched between an ON state and an OFF state based on the drawing data and causes reflected light from micro mirrors which become the ON state of the spatial light modulation element to be incident as an image formation light flux. The device manufacturing method includes: a step of storing correction information that corrects a state of the image formation light flux corresponding to the pattern for each module including the illumination unit, the spatial light modulation element, and the projection unit; and a step of adjusting, for each module, a position or an angle of at least one optical member in the illumination unit or the projection unit or an angle of the spatial light modulation element based on the correction information when the pattern image is exposed onto the substrate by driving the spatial light modulation element.

In an example, the correction information changes a line width of an actual exposure pattern projected onto the substrate and thereby corrects substantial illuminance on the substrate.

An example includes a specifying step that specifies a telecentric error, an asymmetry error, or a light amount variation error based on a generation state of diffraction light defined in accordance with a distribution state in each of an isolated pattern in which one or a row of several micro mirrors in the ON state are arranged independently or to form a row, a line-and-space pattern in which the micro mirrors in the ON state are arranged such that the isolated pattern is aligned at a constant cycle, and a land-like pattern in which the micro mirrors in the ON state are densely arranged such that a size is several times or more larger than that of the isolated pattern.

In an example, a reflection surface of a micro mirror in the ON state of the spatial light modulation element is set to be inclined by an angle θd (θd ≥0°) by a design relative to a surface that is orthogonal to an optical axis of the projection unit and includes an angle error of ±Δθd as a drive error of the micro mirror in the ON state, and an incidence angle θα of the illumination light from the illumination unit to the spatial light modulation element is set to become θα=2·θd by a design.

In an example, in the specifying step, the telecentric error of the image formation light flux when the micro mirror in the ON state generates the isolated pattern is specified as the angle error±Δθd.

In an example, when an arrangement pitch of the micro mirrors is Pdx, n is a real number, a wavelength of the illumination light is λ, and an angle of each order j (j=0, 1, 2, . . . ) of the diffraction light is θj, in the specifying step, the telecentric error of the image formation light flux when the micro mirror in the ON state generates the land-like pattern is defined by an angle of j-th order diffraction light having a small inclination from the optical axis of the projection unit among a plurality of orders of diffraction light defined by sin θj=j·(λ/(n·Pdx))−sin θα.

In an example, in the specifying step, the light amount variation error of the image formation light flux is specified based on a degree to which a point image intensity distribution in an exit pupil of the projection unit of reflected light from a single micro mirror in the ON state is eccentric corresponding to the angle error±Δθd.

In an example, in the specifying step, a test pattern that belongs to any one of the isolated pattern, the line-and-space pattern, and the land-like pattern is generated by the spatial light modulation element, and the asymmetry error is specified based on an intensity distribution of a projection image of the test pattern projected via the projection unit.

In an example, in the specifying step, the telecentric error is specified by measuring a deviation of an intensity distribution of the image formation light flux formed on an exit pupil of the projection unit in a state where the image formation light flux corresponding to any one of the isolated pattern, the line-and-space pattern, and the land-like pattern generated by the spatial light modulation element is projected by the projection unit.

A control method according to an embodiment is a control method of an exposure apparatus that includes: an illumination unit that irradiates, with illumination light, a spatial light modulation element having a plurality of micro mirrors driven to be switched between an ON state and an OFF state based on drawing data; and a projection unit that causes reflected light from micro mirrors which become the ON state of the spatial light modulation element to be incident as an image formation light flux and projects the reflected light to a substrate. The control method includes: adjusting an angle change of the image formation light flux that occurs based on a distribution of the micro mirrors in the ON state of the spatial light modulation element; and adjusting, by correcting the drawing data, a line width change of an exposure pattern that occurs by the adjusting.

In an example, the adjusting of the angle change is performed by an adjustment of an angle of the spatial light modulation element or a position or an angle of an optical member in the illumination unit or the projection unit.

In an example, a plurality of modules including the spatial light modulation element, the illumination unit, and the projection unit are provided, and the adjusting of the angle change and the adjusting of the line width change are performed for each of the plurality of modules.

A pattern exposure apparatus according to an embodiment is a pattern exposure apparatus that includes: an illumination unit that irradiates, with illumination light, a spatial light modulation element having a large number of micro mirrors driven to be switched between an ON state and an OFF state based on drawing data; and a projection unit that causes reflected light from micro mirrors which become the ON state of the spatial light modulation element to be incident as an image formation light flux and projects an image of a pattern corresponding to the drawing data onto a substrate. The pattern exposure apparatus includes: a control unit that stores, as recipe information, the drawing data and an illuminance difference, as information relating to an illuminance, by a pattern of the image formation light flux which occurs in accordance with an angle error in an inclination of a micro mirror and a distribution density of the micro mirrors in the ON state of the spatial light modulation element; and an adjustment mechanism that adjusts a position or an angle of at least one optical member in the illumination unit or the projection unit or an angle of the spatial light modulation element in accordance with the information relating to the illuminance when the pattern is exposed onto the substrate by driving the spatial light modulation element based on the recipe information.

A pattern exposure apparatus according to an embodiment is a pattern exposure apparatus that includes: an illumination unit that irradiates, with illumination light, a spatial light modulation element having a large number of micro mirrors driven to be switched between an ON state and an OFF state based on drawing data; and a projection unit that causes reflected light from micro mirrors which become the ON state of the spatial light modulation element to be incident as an image formation light flux and projects an image of a pattern corresponding to the drawing data onto a substrate. The pattern exposure apparatus has a plurality of spatial light modulation elements, a plurality of illumination units, and a plurality of projection units and includes: a mechanism that measures an illuminance difference of a plurality of modules by a pattern of the image formation light flux which occurs in accordance with an angle error in an inclination of a micro mirror and a distribution density of the micro mirrors in the ON state of the spatial light modulation element; and a mechanism that adjusts a position or an angle of at least one optical member in the illumination unit or the projection unit or an angle of the spatial light modulation element in accordance with information relating to an illuminance when the pattern is exposed onto the substrate by driving the spatial light modulation element based on recipe information including the information relating to the illuminance indicating the measured illuminance difference, and adjusts the illuminance.

A pattern exposure apparatus according to an embodiment is a pattern exposure apparatus that includes: an illumination unit that irradiates, with illumination light, a spatial light modulation element having a large number of micro mirrors driven to be switched between an ON state and an OFF state based on drawing data; and a projection unit that causes reflected light from micro mirrors which become the ON state of the spatial light modulation element to be incident as an image formation light flux and projects an image of a pattern corresponding to the drawing data onto a substrate. The pattern exposure apparatus has a plurality of spatial light modulation elements, a plurality of illumination units, and a plurality of projection units and includes a pattern line width correction calculation unit that substantially obtains a line width error which occurs at a time of exposure due to an image formation state and an illuminance difference of a plurality of modules by the pattern of the image formation light flux which occurs in accordance with a distribution density of the micro mirrors in the ON state of the spatial light modulation element and an angle error in an inclination of a micro mirror, and substantially adds correction to a line width of the drawing data when the pattern is exposed on the substrate.

An exposure apparatus according to an embodiment includes: a plurality of modules that include a spatial light modulation element including a plurality of micro mirrors driven to be switched between an ON state and an OFF state based on drawing data, an illumination unit that irradiates the spatial light modulation element with illumination light, and a projection unit that causes reflected light from micro mirrors in the ON state in the spatial light modulation element to be incident on a substrate as an image formation light flux; a control unit that stores correction information which corrects a state of the image formation light flux for each of the modules; and an adjustment mechanism that adjusts a position or an angle of an optical member in the illumination unit or the projection unit or an angle of the spatial light modulation element for each of the modules based on the correction information.

In an example, the control unit stores information relating to an angle change of the image formation light flux that occurs in accordance with a distribution density of the micro mirrors in the ON state in the spatial light modulation element for each of the modules, and the adjustment mechanism adjusts the position or the angle of the optical member in the illumination unit or the projection unit or the angle of the spatial light modulation element for each of the modules based on the correction information and the information relating to the angle change.

In an example, the exposure apparatus includes: a measurement unit that measures a degree of an asymmetry property of a device pattern corresponding to the drawing data projected onto the substrate, which occurs due to a telecentric error of the image formation light flux that occurs in accordance with a distribution density of the micro mirrors in the ON state in the spatial light modulation element, and the adjustment mechanism adjusts the position or the angle of the optical member in the illumination unit or the projection unit or the angle of the spatial light modulation element for each of the modules such that the asymmetry property is reduced.

In an example, the projection unit includes an aperture diaphragm that sets an exit pupil through which the image formation light flux passes at a predetermined aperture diameter, and the adjustment mechanism performs an adjustment such that an eccentricity of an intensity distribution of the image formation light flux in the exit pupil defined from the information relating to the angle change is reduced.

In an embodiment, the exposure apparatus further includes: a stage device that supports and moves the substrate on an image surface side of the projection unit, and the stage device includes an optical measurement unit that measures the intensity distribution.

In an example, the information relating to the angle change includes a telecentric error generated based on the drawing data, the control unit determines that the telecentric error exceeds an acceptable range, and the adjustment mechanism performs the adjustment based on the telecentric error.

In an example, the control unit stores drawing data for a test pattern corresponding to a pattern form in which the telecentric error exceeds the acceptable range, and the optical measurement unit measures an intensity distribution in the exit pupil of the image formation light flux from the spatial light modulation element driven based on the drawing data for the test pattern and thereby confirms the telecentric error.

In an example, the illumination unit includes an optical integrator which a beam from a light source device enters and a condenser lens system that performs Kohler illumination of light from a surface light source generated by the optical integrator toward a mirror surface of the spatial light modulation element, the surface light source and the exit pupil are optically conjugate, and the projection unit performs reduction projection of a pattern generated by a micro mirror in an ON state of the spatial light modulation element.

In an example, the adjustment mechanism includes an adjustment mechanism that adjusts an incidence position or an incidence angle of the beam which enters the optical integrator or an adjustment mechanism that adjusts a relative position relationship relating to an eccentric direction between the optical integrator and the condenser lens system such that an incidence angle of the illumination light irradiated to the spatial light modulation element is changed.

In an example, the control unit stores information relating to illuminance variation of the image formation light flux that occurs in accordance with a density distribution of the micro mirrors in the ON state of the spatial light modulation element.

In an example, the illumination unit includes an illuminance adjustment filter that changes illuminance of the illumination light irradiated to the spatial light modulation element, and the adjustment mechanism includes a mechanism that controls the illuminance adjustment filter based on the information relating to the illuminance variation.

In an example, the control unit stores information relating to illuminance variation of the image formation light flux that occurs in accordance with a density distribution of the micro mirrors in the ON state of the spatial light modulation element, and a movement speed of the stage device when the image formation light flux is projected onto the substrate is adjusted based on the information relating to the illuminance variation.

In an example, the projection unit includes: a plurality of lenses arranged in front of and behind the exit pupil; and an optical member that corrects an image surface inclination which occurs by the angle of the spatial light modulation element being adjusted by the adjustment mechanism.

In an example, the projection unit includes a plurality of lenses arranged in front of and behind the exit pupil, and a position adjustment in an eccentric direction of part of the plurality of lenses is performed such that an image surface inclination which occurs when the angle of the spatial light modulation element is adjusted is corrected by the adjustment mechanism.

In an example, the control unit determines a magnitude of a telecentric error of the image formation light flux based on the drawing data when half or more of all of the micro mirrors of the spatial light modulation element become an ON state.

In an example, when a reflection surface that becomes flat at a time of non-driving is a neutral plane, the plurality of micro mirrors of the spatial light modulation element are two-dimensionally arranged along each of a first direction and a second direction that are orthogonal to each other in the neutral plane, and the control unit determines a magnitude of a telecentric error based on the drawing data when several or more micro mirrors adjacent to each other in both the first direction and the second direction become the micro mirrors in the ON state.

In an example, when a pattern to be exposed is a line-and-space pattern, based on the drawing data, the control unit determines a magnitude of a telecentric error based on a periodicity and a periodicity direction of an arrangement of the micro mirrors in the ON state among the micro mirrors of the spatial light modulation element.

In an example, the adjustment mechanism adjusts the position or the angle of the optical member when the magnitude of the telecentric error determined by the control unit exceeds an acceptable range.

In an example, the acceptable range is set to be within ±2° as an inclination angle with respect to an optical axis of a principal ray of the image formation light flux that is directed from the projection unit to the substrate.

In an example, the illumination unit includes: a surface light source member which a beam from a laser light source device enters and which generates a surface light source of the illumination light; and a condenser lens system which the illumination light from the surface light source enters and which illuminates a reflection surface of the spatial light modulation element by Kohler illumination, and the adjustment mechanism adjusts a relative position relationship relating to an eccentric direction between the surface light source and the condenser lens system.

In an example, the adjustment mechanism includes: a first telecentric adjustment mechanism that shifts a position of the beam from the laser light source device which enters the surface light source member in the eccentric direction; a second telecentric adjustment mechanism that shifts a position of the surface light source member in the eccentric direction with respect to the beam from the laser light source device; and a third telecentric adjustment mechanism that shifts a position of the condenser lens system in the eccentric direction with respect to a position of the surface light source generated by the surface light source member.

In an example, the illumination unit includes, as the optical member, a mirror that reflects the illumination light at a predetermined angle, and the adjustment mechanism changes an angle of the mirror and adjusts an incidence angle of the illumination light irradiated to the spatial light modulation element.

In an example, when a reflection surface of a micro mirror in the ON state of the spatial light modulation element is inclined by an angle θd (θd>0°) by a design relative to a surface that is orthogonal to an optical axis of the projection unit, the illumination unit is set to be in an inclination illumination method in which an incidence angle θα of the illumination light from the condenser lens system to the spatial light modulation element becomes θα=2·θd by a design, and the incidence angle θα is adjusted by the adjustment mechanism.

In an example, the exposure apparatus includes: a light splitter arranged in an optical path between the spatial light modulation element and the projection unit, and when a reflection surface of a micro mirror in the ON state of the spatial light modulation element is set to an angle θd=0° by a design relative to a surface that is orthogonal to an optical axis of the projection unit, the illumination unit is set to be in an epi-illumination system in which the illumination light from the condenser lens system is irradiated at an incidence angle θα=0° to the spatial light modulation element via the light splitter, and the incidence angle θα is adjusted by the adjustment mechanism.

A device manufacturing method according to an embodiment includes: a step of specifying a telecentric error of the image formation light flux that occurs in accordance with a distribution state of micro mirrors in an ON state of the spatial light modulation element or a light amount variation error of the image formation light flux that occurs due to a drive error of micro mirrors in an ON state; and a step of adjusting an installation state of the spatial light modulation element for each of the modules based on the correction information when the image formation light flux is incident on the substrate by using the exposure apparatus described above wherein the correction information includes information that corrects a state of the image formation light flux based on the light amount variation error.

A device manufacturing method according to an embodiment includes: exposing the substrate by using the exposure apparatus described above.

In an example, the correction information changes a line width of an actual exposure pattern projected onto the substrate and thereby corrects substantial illuminance on the substrate.

In an example, the device manufacturing method includes: a specifying step that specifies a telecentric error, an asymmetry error, or a light amount variation error based on a generation state of diffraction light defined in accordance with a distribution state in each of an isolated pattern in which one or a row of several micro mirrors in the ON state are arranged independently or to form a row, a line-and-space pattern in which the micro mirrors in the ON state are arranged such that the isolated pattern is aligned at a constant cycle, and a land-like pattern in which the micro mirrors in the ON state are densely arranged such that a size is several times or more larger than that of the isolated pattern, a reflection surface of a micro mirror in the ON state of the spatial light modulation element is set to be inclined by an angle θd (θd ≥0°) by a design relative to a surface that is orthogonal to an optical axis of the projection unit and includes an angle error of ±Δθd as a drive error of the micro mirror in the ON state, and an incidence angle θα of the illumination light from the illumination unit to the spatial light modulation element is set to become θα=2·θd by a design.

In an example, in the specifying step, the telecentric error of the image formation light flux when the micro mirror in the ON state generates the isolated pattern is specified as the angle error±Δθd.

In an example, when an arrangement pitch of the micro mirrors is Pdx, n is a real number, a wavelength of the illumination light is λ, and an angle of each order j (j=0, 1, 2, . . . ) of the diffraction light is θj, in the specifying step, the telecentric error of the image formation light flux when the micro mirror in the ON state generates the land-like pattern is defined by an angle of j-th order diffraction light having a small inclination from the optical axis of the projection unit among a plurality of orders of diffraction light defined by sin θj=j·(λ/(n·Pdx))−sin θα.

In an example, in the specifying step, the light amount variation error of the image formation light flux is specified based on a degree to which a point image intensity distribution in an exit pupil of the projection unit of reflected light from a single micro mirror in the ON state is eccentric corresponding to the angle error±Δθd, a test pattern that belongs to any one of the isolated pattern, the line-and-space pattern, and the land-like pattern is generated by the spatial light modulation element, the asymmetry error is specified based on an intensity distribution of a projection image of the test pattern projected via the projection unit, and the telecentric error is specified by measuring a deviation of an intensity distribution of the image formation light flux formed on an exit pupil of the projection unit in a state where the image formation light flux corresponding to any one of the isolated pattern, the line-and-space pattern, and the land-like pattern generated by the spatial light modulation element is projected by the projection unit.

A control method according to an embodiment is a control method of an exposure apparatus that includes a module including: an illumination unit that irradiates, with illumination light, a spatial light modulation element including a plurality of micro mirrors driven to be switched between an ON state and an OFF state based on drawing data; and a projection unit that causes reflected light from micro mirrors which become the ON state of the spatial light modulation element to be incident on a substrate as an image formation light flux and projects a device pattern corresponding to the drawing data onto the substrate. The control method includes: adjusting an angle change of the image formation light flux that occurs based on a distribution of the micro mirrors in the ON state of the spatial light modulation element; and adjusting, by correcting the drawing data, a line width change of the device pattern that occurs by adjusting the angle change.

In an example, the adjusting of the angle change includes adjusting an angle of the spatial light modulation element or a position or an angle of an optical member in the illumination unit or the projection unit.

In an example, the correcting of the drawing data includes correcting a line width of pattern data included in the drawing data.

In an example, a plurality of modules are provided, and the adjusting of the angle change and the adjusting of the line width change are performed for each of the modules.

An exposure apparatus according to an embodiment includes: a module that includes a spatial light modulation element including a plurality of micro mirrors driven to be switched between an ON state and an OFF state based on drawing data, an illumination unit that irradiates the spatial light modulation element with illumination light, and a projection unit that projects reflected light from micro mirrors in the ON state in the spatial light modulation element onto a substrate as an image formation light flux; a control unit that stores illumination-related information including an illuminance difference of the image formation light flux generated in accordance with a distribution density of the micro mirrors in the ON state of the spatial light modulation element and an angle error of an inclination angle of the micro mirrors in the ON state; and an adjustment mechanism that adjusts a position or an angle of an optical member in the illumination unit or the projection unit or an angle of the spatial light modulation element in accordance with the illumination-related information when driving the spatial light modulation element based on the drawing data and projecting the image formation light flux onto the substrate.

In an example, the exposure apparatus includes: a plurality of modules; and a measurement mechanism that measures an illuminance difference between the plurality of modules of the image formation light flux which occurs in accordance with the angle error and the distribution density, and when the image formation light flux is projected to the substrate, in accordance with the illumination-related information including the measured illuminance difference, the adjustment mechanism adjusts a position or an angle of an optical member in the illumination unit or the projection unit or an angle of the spatial light modulation element and adjusts an illuminance of the image formation light flux.

In an example, the exposure apparatus includes: a plurality of modules; and a calculation unit that substantially obtains a line width error which occurs due to an image formation state of the image formation light flux and an illuminance difference between the plurality of modules of the image formation light flux which occurs in accordance with the distribution density and the angle error, and adds correction to a line width of the drawing data.

1.-48. (canceled)

49. An exposure apparatus includes:
a plurality of modules that include:
a spatial light modulation element including a plurality of micro mirrors driven to be switched between an ON state and an OFF state based on drawing data;
an illumination unit that irradiates the spatial light modulation element with illumination light; and
a projection unit that causes light reflected from micro mirrors in the ON state in the spatial light modulation element to be incident on a substrate as an image formation light flux;
a control unit that stores correction information, which corrects a state of the image formation light flux, for each of the plurality of modules; and
an adjustment mechanism that adjusts a position or an angle of an optical member in the illumination unit or the projection unit or an angle of a plane including a center of each of the micro mirrors of the spatial light modulation element, for each of the modules based on the correction information.

50. The exposure apparatus according to claim 49,
wherein the control unit stores information relating to an angle change of the image formation light flux that occurs in accordance with a distribution density of the micro mirrors in the ON state in the spatial light modulation element for each of the modules, and
the adjustment mechanism adjusts the position or the angle of the optical member in the illumination unit or the projection unit or the angle of the spatial light modulation element for each of the modules based on the correction information and the information relating to the angle change.

51. The exposure apparatus according to claim 49, including:
a measurement unit that measures a degree of an asymmetry property of a device pattern corresponding to the drawing data projected onto the substrate, which occurs due to a telecentric error of the image formation light flux that occurs in accordance with a distribution density of the micro mirrors in the ON state in the spatial light modulation element,
wherein the adjustment mechanism adjusts the position or the angle of the optical member in the illumination unit or the projection unit or the angle of the spatial light modulation element for each of the modules such that the asymmetry property is reduced.

52. The exposure apparatus according to claim 50, further including:
a stage device that supports and moves the substrate on an image surface side of the projection unit,
wherein the projection unit includes an aperture diaphragm that sets an exit pupil through which the image formation light flux passes at a predetermined aperture diameter,
the adjustment mechanism performs an adjustment such that an eccentricity of an intensity distribution of the image formation light flux in the exit pupil defined from the information relating to the angle change is reduced,
the stage device includes an optical measurement unit that measures the intensity distribution,
the information relating to the angle change includes a telecentric error generated based on the drawing data,
the control unit determines that the telecentric error exceeds an acceptable range,
the adjustment mechanism performs the adjustment based on the telecentric error,
the control unit stores drawing data for a test pattern corresponding to a pattern form in which the telecentric error exceeds the acceptable range,
the optical measurement unit measures an intensity distribution in the exit pupil of the image formation light flux from the spatial light modulation element driven based on the drawing data for the test pattern and thereby confirms the telecentric error,
the control unit stores information relating to illuminance variation of the image formation light flux that occurs in accordance with a density distribution of the micro mirrors in the ON state of the spatial light modulation element, and
a movement speed of the stage device when the image formation light flux is projected onto the substrate is adjusted based on the information relating to the illuminance variation.

53. The exposure apparatus according to claim 51,
wherein the illumination unit includes an optical integrator which a beam from a light source device enters and a condenser lens system that performs Kohler illumination of light from a surface light source generated by the optical integrator toward a mirror surface of the spatial light modulation element,
the surface light source and the exit pupil are optically conjugate, and
the projection unit performs reduction projection of a pattern generated by a micro mirror in an ON state of the spatial light modulation element, and
the adjustment mechanism includes an adjustment mechanism that adjusts an incidence position or an incidence angle of the beam which enters the optical integrator or an adjustment mechanism that adjusts a relative position relationship relating to an eccentric direction between the optical integrator and the condenser lens system such that an incidence angle of the illumination light irradiated to the spatial light modulation element is changed,
wherein the projection unit includes: a plurality of lenses arranged in front of and behind the exit pupil; and an optical member that corrects an image surface inclination which occurs by the angle of the spatial light modulation element being adjusted by the adjustment mechanism, or
wherein the projection unit includes a plurality of lenses arranged in front of and behind the exit pupil, and
a position adjustment in an eccentric direction of part of the plurality of lenses is performed such that an image surface inclination which occurs when the angle of the spatial light modulation element is adjusted is corrected by the adjustment mechanism.

54. The exposure apparatus according to claim 49,
wherein the control unit stores information relating to illuminance variation of the image formation light flux, illuminance variation occurring in accordance with a density distribution of the micro mirrors in the ON state of the spatial light modulation element,
the illumination unit includes an illuminance adjustment filter that changes illuminance of the illumination light irradiated to the spatial light modulation element, and
the adjustment mechanism includes a mechanism that controls the illuminance adjustment filter based on the information relating to the illuminance variation.

55. The exposure apparatus according to claim 49,
wherein the control unit determines a magnitude of a telecentric error of the image formation light flux based on the drawing data when half or more of all of the micro mirrors of the spatial light modulation element become an ON state,
wherein when a reflection surface that becomes flat at a time of non-driving is a neutral plane, the plurality of micro mirrors of the spatial light modulation element are two-dimensionally arranged along each of a first direction and a second direction that are orthogonal to each other in the neutral plane, and
the control unit determines a magnitude of a telecentric error based on the drawing data when several or more micro mirrors adjacent to each other in both the first direction and the second direction become the micro mirrors in the ON state, or
wherein when a pattern to be exposed is a line-and-space pattern, based on the drawing data, the control unit determines a magnitude of a telecentric error based on a periodicity and a periodicity direction of an arrangement of the micro mirrors in the ON state among the micro mirrors of the spatial light modulation element.

56. The exposure apparatus according to claim 55,
wherein the adjustment mechanism adjusts the position or the angle of the optical member when the magnitude of the telecentric error determined by the control unit exceeds an acceptable range, and
the acceptable range is set to be within ±2° as an inclination angle with respect to an optical axis of a principal ray of the image formation light flux that is directed from the projection unit to the substrate.

57. The exposure apparatus according to claim 49,
wherein the illumination unit includes: a surface light source member which a beam from a laser light source device enters and which generates a surface light source of the illumination light; and a condenser lens system which the illumination light from the surface light source enters and which illuminates a reflection surface of the spatial light modulation element by Kohler illumination, and
the adjustment mechanism adjusts a relative position relationship relating to an eccentric direction between the surface light source and the condenser lens system,
wherein the adjustment mechanism includes: a first telecentric adjustment mechanism that shifts a position of the beam from the laser light source device which enters the surface light source member in the eccentric direction; a second telecentric adjustment mechanism that shifts a position of the surface light source member in the eccentric direction with respect to the beam from the laser light source device; and a third telecentric adjustment mechanism that shifts a position of the condenser lens system in the eccentric direction with respect to a position of the surface light source generated by the surface light source member,
wherein the illumination unit includes, as the optical member, a mirror that reflects the illumination light at a predetermined angle, and
the adjustment mechanism changes an angle of the mirror and adjusts an incidence angle of the illumination light irradiated to the spatial light modulation element,
wherein when a reflection surface of a micro mirror in the ON state of the spatial light modulation element is inclined by an angle θd (θd>0°) by a design relative to a surface that is orthogonal to an optical axis of the projection unit, the illumination unit is set to be in an inclination illumination method in which an incidence angle θα of the illumination light from the condenser lens system to the spatial light modulation element becomes θα=2·θd by a design, and the incidence angle θα is adjusted by the adjustment mechanism, or including:
a light splitter arranged in an optical path between the spatial light modulation element and the projection unit, and
wherein when a reflection surface of a micro mirror in the ON state of the spatial light modulation element is set to an angle θd=0° by a design relative to a surface that is orthogonal to an optical axis of the projection unit, the illumination unit is set to be in an epi-illumination system in which the illumination light from the condenser lens system is irradiated at an incidence angle θα=0° to the spatial light modulation element via the light splitter, and the incidence angle θα is adjusted by the adjustment mechanism.

58. A device manufacturing method including:
a step of specifying a telecentric error of the image formation light flux that occurs in accordance with a distribution state of micro mirrors in an ON state of the spatial light modulation element or a light amount variation error of the image formation light flux that occurs due to a drive error of micro mirrors in an ON state; and
a step of adjusting an installation state of the spatial light modulation element for each of the modules based on the correction information when the image formation light flux is incident on the substrate by using an exposure apparatus according to claim 49 wherein the correction information includes information that corrects a state of the image formation light flux based on the light amount variation error.

59. The device manufacturing method according to claim 58,
wherein the correction information changes a line width of an actual exposure pattern projected onto the substrate and thereby corrects substantial illuminance on the substrate.

60. The device manufacturing method according to claim 58, including:
a specifying step that specifies a telecentric error, an asymmetry error, or a light amount variation error based on a generation state of diffraction light defined in accordance with a distribution state in each of an isolated pattern in which one or a row of several micro mirrors in the ON state are arranged independently or to form a row, a line-and-space pattern in which the micro mirrors in the ON state are arranged such that the isolated pattern is aligned at a constant cycle, and a land-like pattern in which the micro mirrors in the ON state are densely arranged such that a size is several times or more larger than that of the isolated pattern,
wherein a reflection surface of a micro mirror in the ON state of the spatial light modulation element is set to be inclined by an angle θd (θd≥0°) by a design relative to a surface that is orthogonal to an optical axis of the projection unit and includes an angle error of ±Δθd as a drive error of the micro mirror in the ON state, and
an incidence angle θα of the illumination light from the illumination unit to the spatial light modulation element is set to become θα=2·θd by a design, and
wherein in the specifying step, the telecentric error of the image formation light flux when the micro mirror in the ON state generates the isolated pattern is specified as the angle error±Δθd,
when an arrangement pitch of the micro mirrors is Pdx, n is a real number, a wavelength of the illumination light is λ, and an angle of each order j (j=0, 1, 2, . . . ) of the diffraction light is θj,
in the specifying step, the telecentric error of the image formation light flux when the micro mirror in the ON state generates the land-like pattern is defined by an angle of j-th order diffraction light having a small inclination from the optical axis of the projection unit among a plurality of orders of diffraction light defined by
$$sin θ j = j \cdot ( λ / ( n \cdot Pdx ) ) - sin θα ,$$
or
wherein in the specifying step,
the light amount variation error of the image formation light flux is specified based on a degree to which a point image intensity distribution in an exit pupil of the projection unit of reflected light from a single micro mirror in the ON state is eccentric corresponding to the angle error±Δθd,
a test pattern that belongs to any one of the isolated pattern, the line-and-space pattern, and the land-like pattern is generated by the spatial light modulation element, the asymmetry error is specified based on an intensity distribution of a projection image of the test pattern projected via the projection unit, and
the telecentric error is specified by measuring a deviation of an intensity distribution of the image formation light flux formed on an exit pupil of the projection unit in a state where the image formation light flux corresponding to any one of the isolated pattern, the line-and-space pattern, and the land-like pattern generated by the spatial light modulation element is projected by the projection unit.

61. A control method of an exposure apparatus that includes a module including: an illumination unit that irradiates, with illumination light, a spatial light modulation element including a plurality of micro mirrors driven to be switched between an ON state and an OFF state based on drawing data; and a projection unit that causes reflected light from micro mirrors in the ON state of the spatial light modulation element to be incident on a substrate as an image formation light flux and projects a device pattern corresponding to the drawing data onto the substrate, the control method including:
adjusting an angle change of the image formation light flux that occurs based on a distribution of the micro mirrors in the ON state of the spatial light modulation element; and
adjusting, by correcting the drawing data, a line width change of the device pattern that occurs by adjusting the angle change.

62. The control method according to claim 61,
wherein the adjusting of the angle change includes adjusting an angle of the spatial light modulation element or a position or an angle of an optical member in the illumination unit or the projection unit.

63. The control method according to claim 61,
wherein the correcting of the drawing data includes correcting a line width of pattern data included in the drawing data.

64. The control method according to claim 61,
wherein a plurality of modules are provided, and
the adjusting of the angle change and the adjusting of the line width change are performed for each of the modules.

65. An exposure apparatus including:
a module that includes:
a spatial light modulation element including a plurality of micro mirrors driven to be switched between an ON state and an OFF state based on drawing data;
an illumination unit that irradiates the spatial light modulation element with illumination light; and
a projection unit that projects reflected light from micro mirrors in the ON state in the spatial light modulation element onto a substrate as an image formation light flux;
a control unit that stores illumination-related information including an illuminance difference of the image formation light flux generated in accordance with a distribution density of the micro mirrors in the ON state of the spatial light modulation element and an angle error of an inclination angle of the micro mirrors in the ON state; and
an adjustment mechanism that adjusts a position or an angle of an optical member in the illumination unit or the projection unit or an angle of the spatial light modulation element in accordance with the illumination-related information when driving the spatial light modulation element based on the drawing data and projecting the image formation light flux onto the substrate.

66. The exposure apparatus according to claim 65, including:
a plurality of modules; and
a measurement mechanism that measures an illuminance difference between the plurality of modules of the image formation light flux which occurs in accordance with the angle error and the distribution density,
wherein when the image formation light flux is projected to the substrate, in accordance with the illumination-related information including the measured illuminance difference, the adjustment mechanism adjusts a position or an angle of an optical member in the illumination unit or the projection unit or an angle of the spatial light modulation element and adjusts an illuminance of the image formation light flux.

67. The exposure apparatus according to claim 65, including:
a plurality of modules; and
a calculation unit that substantially obtains a line width error which occurs due to an image formation state of the image formation light flux and an illuminance difference between the plurality of modules of the image formation light flux which occurs in accordance with the distribution density and the angle error, and adds correction to a line width of the drawing data.

68. An adjustment method comprising:
acquiring, for each of the plurality of modules, information including an angle at which a principal ray of light from a module among the plurality of modules is inclined with respect to an optical axis of the module or a value corresponding to the angle in the case where a first pattern is projected onto a projection region by using the plurality of modules each including a spatial light modulation element; and
adjusting the plurality of modules based on the information.

69. The adjustment method according to claim 68,
wherein the adjusting of the plurality of modules includes:
adjusting the plurality of modules based on the information such that a difference of the angle between the plurality of modules is reduced.

70. The adjustment method according to claim 68, comprising:
selecting the first pattern from a plurality of different patterns.

71. The adjustment method according to claim 68,
wherein each of the plurality of modules includes a projection unit that projects light from the corresponding spatial light modulation element to the projection region, and
the value corresponding to the angle includes a position of a center of an intensity distribution of the light from the spatial light modulation element at a pupil position of the projection unit.

72. The adjustment method according to claim 71, comprising:
acquiring the position of the center of the intensity distribution by measuring the pupil position.

73. The adjustment method according to claim 68, comprising:
calculating the information based on the first pattern and a state change amount of a mirror in each of the plurality of modules or a difference of the state change amount between the plurality of modules when the mirror included in the spatial light modulation element changes from a first state to a second state.

74. The adjustment method according to claim 73,
wherein in the first state, light from the mirror enters a portion other than a projection unit included in the module,
in the second state, the light from the mirror enters the projection unit included in the module, and
the state change amount includes an inclination angle.

75. The adjustment method according to claim 68,
wherein each of the plurality of modules includes:
an illumination unit that irradiates the spatial light modulation element with light; and
a projection unit that projects light from the spatial light modulation element to the projection region, and
the adjusting of the plurality of modules includes:
adjusting a position or an angle of an optical member in the illumination unit or the projection unit or an angle of a plane including a center of each of mirrors of the spatial light modulation element, for each of the plurality of modules.

76. An exposure apparatus that comprises the plurality of modules and performs an adjustment method according to claim 68.

77. A manufacturing method comprising:
performing an adjustment method according to claim 68; and
exposing a device pattern to a substrate arranged in the projection region by using an exposure apparatus including the plurality of modules adjusted by the adjustment method.
